(19) United States
(12) Patent Application Publication
(10) Pub. No.: US 2026/0362975 A1
(43) Pub. Date: Nov. 12, 2026

(54) MATERIALS AND METHODS OF USE THEREOF

(71) Applicant: OHIO STATE INNOVATION FOUNDATION, Columbus, OH (US)

(72) Inventors: Xiaoguang WANG, Powell, OH (US); Hualiang LYU, Shanghai (CN)

(21) Appl. No.: 19/117,762

(22) PCT Filed: Oct. 3, 2023
(86) PCT No.: PCT/US2023/034347

§ 371 Date: Apr. 2, 2025

Related U.S. Application Data
(60) Provisional application No. 63/412,615, filed on Oct. 3, 2022.

(51) Int. Cl. H10N 10/17; H10N 10/855

(52) U.S. Cl. CPC H10N 10/17; H10N 10/855

(57) ABSTRACT

Disclosed herein are compositions, devices, and methods of use thereof, for example, for harvesting electromagnetic waves and generating electricity. For example, disclosed herein are materials for converting electromagnetic radiation directly into electricity, wherein the material absorbs electromagnetic radiation, converts the absorbed electromagnetic radiation into thermal energy, and subsequently converts the thermal energy into electric energy via a thermoelectric effect. In some examples, the material comprises one or more porous layers, wherein each porous layer comprises a two-dimensional material layer permeated by a plurality of pores.

### CROSS-REFERENCE TO RELATED APPLICATIONS

This application claims the benefit of priority to U.S. Provisional Application No. 63/412,615, filed Oct. 3, 2022, which is hereby incorporated herein by reference in its entirety.

### BACKGROUND

Harvesting largely ignored and wasted electromagnetic (EM) energy released by electronic devices and converting it into direct current (DC) electricity is an attractive strategy to not only reduce EM pollution but also address the ever-increasing energy crisis. To date, no single-component material system can convert EM waves to DC electricity because of contradictory material requirements. The compositions, devices, and methods discussed herein address these and other needs.

### SUMMARY

In accordance with the purposes of the disclosed compositions, devices, and methods as embodied and broadly described herein, the disclosed subject matter relates to compositions, devices, and methods of use thereof. For example, disclosed herein are compositions, devices, and methods of use thereof for harvesting electromagnetic waves and generating electricity.

For example, disclosed herein are materials for converting electromagnetic radiation directly into electricity, wherein the material absorbs electromagnetic radiation, converts the absorbed electromagnetic radiation into thermal energy, and subsequently converts the thermal energy into electric energy via a thermoelectric effect. In some examples, the material comprises one or more porous layers, wherein each porous layer comprises a two-dimensional material layer permeated by a plurality of pores.

Also disclosed herein are materials comprising one or more porous layers, wherein each porous layer comprises a two-dimensional material layer permeated by a plurality of pores.

Also disclosed herein are methods of making any of the porous materials disclosed herein. For example, the methods can comprise: depositing a plurality of particles on the two-dimensional material layer, thereby forming an initial material; annealing the initial material to form an intermediate material; and removing the plurality of particles from the intermediate material, thereby forming the material.

Also disclosed herein are methods of use of any of the materials disclosed herein.

Additional advantages of the disclosed compositions, devices, and methods will be set forth in part in the description which follows, and in part will be obvious from the description. The advantages of the disclosed compositions, devices, and methods will be realized and attained by means of the elements and combinations particularly pointed out in the appended claims. It is to be understood that both the foregoing general description and the following detailed description are exemplary and explanatory only and are not restrictive of the disclosed compositions, devices, and methods, as claimed.

The details of one or more embodiments of the invention are set forth in the accompanying drawings and the description below. Other features, objects, and advantages of the invention will be apparent from the description and drawings, and from the claims.

### BRIEF DESCRIPTION OF THE FIGURES

The accompanying figures, which are incorporated in and constitute a part of this specification, illustrate several aspects of the disclosure, and together with the description, serve to explain the principles of the disclosure.

FIG. 1. Schematic illustration of the synthesis of graphene with staggered and ordered nanopores. (I) In-situ growth of monodisperse Fe₃O₄ nanoparticles on a graphene surface (green and orange spheres represent iron and oxygen atoms, respectively). (II) In-situ etching of graphene templated by Fe₃O₄ nanoparticles. (III) Formation of nanometer-sized pores on graphene after removing Fe₃O₄ nanoparticles (red color highlights the carbon atoms at the edge of the nanopores). The nanopores on different graphene layers are staggered in graphene with more than one layer.

FIG. 2a-FIG. 2f. Morphology of graphene with staggered, ordered nanometer-sized pores. Representative TEM images of (FIG. 2a, FIG. 2b) monolayer graphene with circular pores with a diameter of 6±1 nm, (FIG. 2c) monolayer graphene with square nanopores with an edge length of 7±1 nm, (FIG. 2d) bilayer, (FIG. 2e) trilayer, and (FIG. 2f) multilayer graphene with circular nanopores. Inset in (a) shows the representative TEM images of spherical Fe₃O₄ nanoparticles. Inset in (FIG. 2c) shows a magnified TEM image of square nanopores on monolayer graphene. The staggered nanoporous structure was observed on graphene with more than one layer. The top and bottom layers in the bilayer nanoporous graphene in the inset in (FIG. 2d) were labeled in red and blue color, respectively.

FIG. 3a-FIG. 3f. Effect of staggered, ordered nanopores on the EM dissipation and thermal conductivity of graphene. (FIG. 3a) EM frequency-dependent EM dissipation factor (η) of bilayer graphene with and without ordered circular nanopores. (FIG. 3b) Thermal conductivity (κ_{T}) of bilayer graphene with and without ordered circular nanopores as a function of temperature. Error bars represent standard deviations from three independent measurements. Error bars represent standard deviations from three independent measurements. (FIG. 3c, FIG. 3d) Molecular dynamics simulation of the phonon density of states of (FIG. 3c) monolayer and (FIG. 3d) bilayer graphene with ordered circular nanopores. (FIG. 3e) ΔT of graphene with ordered circular nanopores as a function of time. EM radiation is applied from 0 to 300 s. (FIG. 3f) Finite-element simulation of ΔT of graphene with ordered circular nanopores during EM radiation. The staggered, ordered nanopores induce a dipole relaxation polarization at low EM frequencies and thus increase the η of graphene, weaken the phonon coupling behavior, and decrease the κ_{T} of graphene.

FIG. 4a-FIG. 4b. Effect of staggered, ordered nanopores on the Seebeck effect of graphene. (FIG. 4a) Temperature-dependent Seebeck coefficient of bilayer graphene with and without circular nanopores. Error bars represent standard deviations from three independent measurements. (FIG. 4b) Density functional theory calculation of the band structure and projected density of state of bilayer graphene with circular nanopores. The staggered, ordered nanoporous structure confines the electron transport by splitting the Dirac point and breaking up the Fermi energy surfaces, significantly enhancing the Seebeck effect of graphene. The diameter of the nanopores in the calculation is 1.2 nm.

FIG. 5a-FIG. 5e. Electric energy output performance of bilayer graphene with circular nanopores. (FIG. 5a) Open-circuit voltage as a function of time. The EM radiation is applied from 0 to 180 s. In the red curve, the ΔT is applied by using an external thermal source instead of EM radiation. (FIG. 5b) Output power (Pₒᵤₜ) as a function of resistance load. (FIG. 5c) Power density (P_{density}) as a function of time. A typical 360 s-cycle includes a 180 s radiation period. (FIG. 5d) Output power (Pₒᵤₜ) as a function of time at 25 °C (FIG. 5e) Effect of temperature on the output work (Wₒᵤₜ). The resistance load in (FIG. 5d, FIG. 5e) was 60Ω. Error bars represent standard deviations from three independent measurements.

FIG. 6a-FIG. 6d—In-situ growth of spherical Fe₃O₄ nanoparticles on graphene. (FIG. 6a-FIG. 6c) Representative TEM images of spherical Fe₃O₄ nanoparticles on graphene. (FIG. 6d) Diameter distribution of Fe₃O₄ nanoparticles grown on graphene.

FIG. 7a-FIG. 7b—Crystal phase and composition evolution of Fe₃O₄ nanoparticle-coated graphene upon annealing. (FIG. 7a) X-ray diffraction (XRD) patterns and (FIG. 7b) Fe 2p XPS spectrum of Fe₃O₄-coated graphene before and after annealing at 900 °C. The appearance of a diffraction peak at 2θ=44.4° in the annealed Fe₃O₄-coated graphene is attributed to the (110) crystal plane of α-Fe. The shifting of the Fe 2p_{3/2} peak to low binding energy upon annealing is attributed to the reduction of Fe by carbonization.

FIG. 8a-FIG. 8c—Morphological evolution of nanoparticle-templated pore creation on wrinkled reduced graphene oxide. TEM images of (a) pristine reduced graphene oxide, (FIG. 8b) Fe₃O₄ nanoparticle-coated reduced graphene oxide, and (FIG. 8c) porous reduced graphene oxide. Insets in (FIG. 8a) and (FIG. 8b) are magnified images. Ordered nanoporous structures cannot be obtained on wrinkled reduced graphene oxide.

FIG. 9a-FIG. 9e—Effect of Fe₃O₄ nanoparticle density on the structure of nanoporous graphene. TEM images of graphene coated with Fe₃O₄ nanoparticles which were obtained with Fe precursor concentrations of (FIG. 9a) 0.025 g/mL, (FIG. 9b) 0.05 g/mL, (FIG. 9c) 0.075 g/mL, and (FIG. 9d) 0.125 g/mL. (FIG. 9e) TEM images of porous graphene created with a 0.125 g/mL concentration Fe precursor. Below 0.125 g/mL, a monolayer of Fe₃O₄ nanoparticles was observed to form on the graphene. Above 0.125 g/mL, Fe₃O₄ nanoparticles were observed to form a bilayer on the graphene, resulting in polydisperse pores with diameters of tens of nanometers.

FIG. 10a-FIG. 10c—In-situ growth of cubic Fe₃O₄ nanoparticles on graphene. (FIG. 10a, FIG. 10b) Representative TEM images of cubic Fe₃O₄ nanoparticles on graphene. (FIG. 10c) Size distribution of cubic Fe₃O₄ nanoparticles grown on graphene.

FIG. 11a-FIG. 11c—Morphology of nanoporous graphene templated by hexagonal Fe₃O₄ nanoparticles. (FIG. 11a, FIG. 11b) Representative TEM images of nanoporous graphene templated by hexagonal Fe₃O₄ nanoparticles. Inset in (FIG. 11a) is a TEM image of hexagonal Fe₃O₄ nanoparticles. (FIG. 11c) Size distribution of hexagonal Fe₃O₄ nanoparticles grown on graphene.

FIG. 12a-FIG. 12f—Morphology and crystal structures of nonporous graphene with different numbers of layers. Representative TEM images of graphene with (FIG. 12a) 1, (FIG. 12b) 2, (FIG. 12c) 3 and (FIG. 12d) 6 layers. (FIG. 12e) FT-IR and (FIG. 12f) Raman spectra of graphene with different layer numbers. Inset in f shows the enlarged region between 1,500 and 1,600 cm⁻¹. 1 L, 2 L, 3 L and 6 L′ represent the number of graphene layers and ‘GN’ represents graphene.

FIG. 13a-FIG. 13d—AFM measurement of the thickness of graphene with different layers. AFM image and thickness profile of graphene with (FIG. 13a) 1, (FIG. 13b) 2, (FIG. 13c) 3, and (FIG. 13d) 6 layers.

FIG. 14—Frequency-dependent permittivity of graphene with different numbers of layers and pore shapes. ‘Square, circle and hexagon’ represent the pore shapes. ε′ and ε″ represent the real part and imaginary part of the permittivity, respectively.

FIG. 15a-FIG. 15d—Calculated EM dissipation factor of graphene with different pore shapes and numbers of layers. EM frequency-dependent EM dissipation factor of graphene with different pore shapes and (FIG. 15a) 1, (FIG. 15b) 2, (FIG. 15c) 3, and (FIG. 15d) 6 layers. The presence of nanoporous structures enables efficient EM dissipation within the EM frequency range of 2-5 GHz.

FIG. 16—XRD spectra of common transition metal oxide-based EM dissipating materials. These transition metal oxides mainly include Fe-, Co- or Ni-based oxides.

FIG. 17—Permittivity and calculated EM dissipation factor of transition metal oxide-based EM absorbing materials as a function of EM frequency. The calculated EM dissipation factors of common transition metal oxide-based EM absorbing materials are smaller than 20, indicating weak EM dissipation.

FIG. 18—XRD patterns of common transition metal-sulfide or semiconducting metal alloy-based EM absorbing materials. In the above materials, transition metal sulfide and semiconducting metal alloys have been shown to possess a desirable Seebeck coefficient and moderate thermal conductivity creating an exceptional thermoelectric effect.

FIG. 19—Permittivity and calculated EM dissipation factor of transition metal sulfide or semiconducting metal alloy-based EM absorbing materials as a function of EM frequency. Although some transition metal sulfide and semiconducting alloys such as SnS and Bi₂Te₃ exhibit a high absolute Seebeck coefficient and a moderate thermal conductivity for EM-electricity conversion, their low EM dissipation factor (typically between 10 and 90) prevent efficient EM dissipation.

FIG. 20—XRD spectra, EM frequency-dependent permittivity, and EM dissipation factor of common metals. Although the EM dissipation factor of metals is comparable to those of transition metal oxides or transition metal sulfides, it is much smaller than that of the ordered nanoporous graphene reported in this work.

FIG. 21—XRD spectra of common EM absorbing composite materials. The combination of two or more materials and the creation of material-material interfaces has been demonstrated as an efficient way to induce a polarization relaxation behavior and promote EM dissipation.

FIG. 22—EM frequency-dependent permittivity and calculated EM dissipation factors of common EM absorbing composite materials. The q values of these EM absorbing composite materials range between 20 and 60 because of a weak conductive loss and the absence of a polarization relaxation loss.

FIG. 23—Polarization relaxation behavior (Cole-Cole curve) of graphene with different pore shapes and numbers of layers. The Cole-Cole curves were plotted using ε′ and ε″. The presence of semi-circles in the Cole-Cole curves suggests the existence of a polarization relaxation behavior in the ordered nanoporous graphene.

FIG. 24a-FIG. 24f—X-ray absorption near-edge structure (XANES) analysis of the structure of ordered nanoporous graphene. XANES of C1s of graphene with (FIG. 24a-FIG. 24c) different numbers of layers and (FIG. 24d-FIG. 24f) different pore shapes.

FIG. 25a-FIG. 25d—Analysis of elements and dipole bonds in ordered nanoporous graphene. (FIG. 25a) TEM element mapping of bilayer graphene with circular nanopores. (FIG. 25b) FT-IR spectra of bilayer graphene with different pore shapes. XPS of (FIG. 25c) C1s and (FIG. 25d) O1s spectra of bilayer graphene with different pore shapes.

FIG. 26a-FIG. 26l—Low frequency (2-5 GHz) dipole relaxation of porous graphene and element-doped graphene. (FIG. 26a, FIG. 26b, FIG. 26e, FIG. 26f, FIG. 26i, FIG. 26j) TEM images, (FIG. 26c) Raman spectra, (FIG. 26g, FIG. 26k) FT-IR spectra and (FIG. 26d, FIG. 26h, FIG. 26l) EM frequency-dependent permittivity of (FIG. 26a-FIG. 26d) graphene with pore sizes exceeding 20 nm, (FIG. 26e-FIG. 26h) graphene with pore sizes less than 3 nm, and (FIG. 26i-FIG. 26l) N or S-doped graphene.

FIG. 27a-FIG. 27g—Effect of dipoles at the pore edge on the permittivity of ordered nanoporous graphene. (FIG. 27a) Schematic illustration of the temperature-dependent decomposition of dipoles in graphene with circular pores. (FIG. 27b) Raman spectrum of bilayer graphene with circular pores annealed at 600 °C. FT-IR spectra of bilayer graphene with circular pores annealed at (FIG. 27d) 800 and (FIG. 27f) 1,200 °C. EM frequency-dependent permittivity of bilayer graphene with circular pores annealed at (FIG. 27c) 600 °C, (FIG. 27e) 800 °C, and (FIG. 27g) 1,200 °C. Excess H₂ is required to remove C—O—C bonds completely.

FIG. 28a-FIG. 28j—Synthesis of EM absorbers based on transition metal oxide nanoparticles. (FIG. 28a, FIG. 28b) Schematic illustration of the multiple-dispersion method for synthesizing of transition metal oxide nanoparticle-based EM absorbers. TEM images of (FIG. 28c, FIG. 28d) cubic Fe₃O₄, (FIG. 28e, FIG. 28f) spherical Fe₃O₄, (FIG. 28g, FIG. 28h) tetrahedral Fe₃O₄, and (FIG. 28i, FIG. 28j) irregular-shaped Fe₃O₄ nanoparticles.

FIG. 29a-FIG. 29e—ε″ of EM absorbers prepared using the multiple dispersion method. EM frequency-dependent ε″ of (FIG. 29a) cubic, (FIG. 29b) tetrahedron, (FIG. 29c) sphere and (FIG. 29d) non-regular shaped Fe₃O₄ nanoparticles. (FIG. 29e) Schematic illustration of EM incident angle-dependent ε″ of nanoparticles with different shapes.

FIG. 30—EM dissipation factor of graphene at evaluated temperatures. Compared with pristine graphene, ordered nanoporous graphene exhibits an enhanced EM dissipation at elevated temperatures.

FIG. 31—Temperature dependence of ε″ of graphene with different numbers of layers and pore shapes. As temperature increases from 300 to 500 K, the ε″ of pristine graphene decreases and the ε″ of ordered nanoporous graphene shifts into the low-frequency region.

FIG. 32a-FIG. 32d—Thermal conductivity of graphene with different numbers of layers and pore shapes. Thermal conductivity (κ_{T}) of porous graphene with (FIG. 32a) 1, (FIG. 32b) 2, (FIG. 32c) 3, and (FIG. 32d) 6 layers as a function of temperature. Compared with pristine graphene, a significant reduction in κ_{T} is observed in all porous graphenes.

FIG. 33a-FIG. 33d—Electrical conductivity of graphene with different numbers of layers and pore shapes. Electrical conductivity (σ) of porous graphene with (FIG. 33a) 1, (FIG. 33b) 2, (FIG. 33c) 3, and (FIG. 33d) 6 layers as a function of temperature.

FIG. 34a-FIG. 34d—Lorenz number of graphene with different numbers of layers and pore shapes. Lorenz number (L) of porous graphene with (FIG. 34a) 1, (FIG. 34b) 2, (FIG. 34c) 3, and (FIG. 34d) 6 layers as a function of temperature.

FIG. 35—Temperature-dependent electron thermal conductivity (κₑ) and lattice thermal conductivity (κ_{L}) of graphene with different number of layers and pore shapes. The presence of nanopores significantly decreases κ_{L}.

FIG. 36a-FIG. 36d—Effect of the pore structure on the interlayer spacing of graphene. XRD (002) pattern of porous and nonporous graphene with (FIG. 36a) 2, (FIG. 36b) 3, and (FIG. 36c) 6 layers. (FIG. 36d) The reduction ratio of the interlayer spacing of porous graphene over nonporous graphene with the same graphene layer number. Based on the diffraction angle, the spacing distance was calculated based on Bragg's law. Error bars represent standard deviations from three independent measurements.

FIG. 37a-FIG. 37h—Molecular dynamics simulation of the effect of pore structure on thermal conductivity. (FIG. 37a) Molecular model for the simulation of the thermal conductivity, κ_{T}, of monolayer graphene with different pore shapes. (FIG. 37b) Atomic configurations of monolayer graphene with square, hexagonal, and circular nanopores. Kr of ordered porous graphene with different (FIG. 37c-FIG. 37e) pore sizes (with a fixed nanoribbon width, ω, of 1.5 nm) and (FIG. 37f-FIG. 37h) nanoribbon widths between adjacent nanopores (with a fixed nanopore size, d, of 4 nm). Error bars represent standard deviations from three independent measurements.

FIG. 38—Phonon intensity of carbon atoms in graphene nanoribbons with zigzag-shaped edges. The phonon intensity of carbon atoms at the pore edges and in the framework of the graphene nanoribbon (away from the edges). The nanoribbon width is 5 nm.

FIG. 39—Spatial distribution of the heat flux of porous graphene nanosheets with different pore shapes. Vector arrows indicate the heat flux on each atom of porous graphene. The black arrows in the enlarged image of the square pore show the global heat flux transport pathways.

FIG. 40—Ratio of the thermal conductivity, κ_{T}, of nanoporous graphene over nonporous graphene with the same number of layers. The pore size, d, was set at 4 nm and the nanoribbon width, ω, was set at 2.5 nm. Error bars represent standard deviations from three independent measurements.

FIG. 41a-FIG. 41b—Molecular dynamics simulation of the effect of the overlap ratio of pores on the thermal conductivity of graphene. (FIG. 41a) Scheme of a 3-layer graphene structure with a square pore in the middle graphene layer. (FIG. 41b) Phonon density of the states of carbon atoms in a 3-layer graphene structure with an overlap ratio of 0 and 1.

FIG. 42a-FIG. 42b—The effect of overlap ratio on the thermal conductivity of ordered porous graphene. (FIG. 42a) Atomic configuration of a graphene layer with square nanopores covered by a defect-free graphene nanoribbon. (FIG. 42b) Thermal conductivity, κ_{T}, of a nanoporous nanoribbon as a function of overlap ratio defined as w₁/w₂. Error bars represent standard deviations from three independent measurements.

FIG. 43—Photograph and scheme of ordered porous graphene-based strip. 5 mm of graphene strip was covered with a layer of parylene-c.

FIG. 44a-FIG. 44b—Characterization of the morphology of the parylene-c layer surface. (FIG. 44a) Optical micrograph of parylene-c coated on Si/SiOₓ substrate. Inset shows a photograph of the parylene-c coated on Si/SiOₓ substrate. (FIG. 44b) Representative scanning electron microscope (SEM) and AFM images of the parylene-c layer before and after deposition on graphene film.

FIG. 45—AFM images of the surface morphology of parylene-c as a function of deposition time. The deposition time is listed on top of the images.

FIG. 46a-FIG. 46h—Effect of parylene-c thickness on the calculated η value. (FIG. 46a) Thickness and root mean square (RMS) of the surface roughness of parylene-c as a function of deposition time. Error bars represent standard deviations from three independent measurements. (FIG. 46b) η of parylene-c as a function of EM frequency. (FIG. 46c-FIG. 46h) The ratio of η of graphene-coated with different parylene-c thickness over bare graphene.

FIG. 47—Photograph of a homemade microwave cavity and apparatus for the determination of the EM-electricity generation using ordered porous graphene. The circuitry was changed to use the microwave while open. In addition, a magnetron with a power of ~100 W was used.

FIG. 48—Spatial and temporal temperature profile of nonporous graphene and ordered porous graphene upon EM wave irradiation using IR camera. The graphene strip width is 5 mm.

FIG. 49a-FIG. 49b—Effect of pore structure on the temperature evolution dynamics in graphene. (FIG. 49a) Time required for graphene film to achieve a maximum temperature gradient upon EM radiation. The number labeled next to each data point represents the maximum temperature gradient in Kelvin. (FIG. 49b) Time required for graphene film to relax to a uniform temperature profile (no temperature gradient) after the removal of EM radiation.

FIG. 50—Finite-element simulation of the temperature profile of nonporous bilayer graphene upon EM radiation.

FIG. 51—Finite-element simulation of the temperature profile of bilayer graphene with circular nanopores as a function of EM radiation time. The generated temperature differences between two ends of graphene are ~28, 47, 61, 46 and 37 °C at a radiation time of 60, 120, 180, 240 and 300 s, respectively.

FIG. 52a-FIG. 52d—Temperature-dependent Seebeck coefficient of graphene with different numbers of layers and pore shapes. Seebeck coefficient, S, of nonporous and porous graphene with (FIG. 52a) 1, (FIG. 52b) 2, (FIG. 52c) 3, and (FIG. 52d) 6 layers.

FIG. 53a-FIG. 53h—Carrier density and carrier mobility of graphene as a function of temperature. (FIG. 53a-FIG. 53d) Carrier density (n) and (FIG. 53e-FIG. 53h) mobility (μH) of porous and nonporous graphene with (FIG. 53a, FIG. 53e) 1, (FIG. 53b, FIG. 53f) 2, (FIG. 53c, FIG. 53g) 3, and (FIG. 53d, FIG. 53h) 6 layers.

FIG. 54a-FIG. 54f—Converted UV-visible diffuse reflectance curves of graphene with different numbers of layers and pore shapes. Bandgap E_{g} is indicated in the curves.

FIG. 55—Carrier density (n) and mobility (μH) of different graphene structures as a function of the Seebeck coefficient (S). The graphene structures include etched graphene, reduced graphene oxide, polydisperse porous graphene, graphene oxide, and S or N-doped graphene. The absolute Seebeck coefficients of the above graphene structures are measured to be less than 30 μV/K.

FIG. 56a-FIG. 56c—Density functional theory (DFT) calculations of the band structures and projected density of state of bilayer graphene with different pore structures. Bandgap (E_{g}) and zero density of state are indicated by black and red double-headed arrows, respectively. The diameter of the nanopores is 1.2 nm.

FIG. 57—DFT calculation of the Fermi surface of bilayer graphene with different pore structures and overlap ratio. The diameter of the nanopores is 1.2 nm. Compared to nonporous bilayer graphene, the Fermi surface of bilayer nanoporous graphene with different overlap ratios exhibits a remarkable splitting behavior.

FIG. 58—DFT calculation of the Seebeck coefficient of bilayer graphene with different pore structures and overlap ratio as a function of temperature and chemical potential. The color scale indicates the value of the Seebeck coefficient. The diameter of the nanopores is 1.2 nm. The calculated Seebeck coefficient of porous graphene with an overlap ratio of ⅓ is significantly higher than that of nonporous graphene and porous graphene with other overlap ratios.

FIG. 59a-FIG. 59b—Effect of nanopores on the electron structure and Seebeck coefficient of graphene. (FIG. 59a) Calculated band structure and projected density of state and (FIG. 59b) Seebeck coefficient of trilayer graphene with circular nanopores (overlap ratio is ⅓). The diameter of the nanopores is 1.2 nm.

FIG. 60a-FIG. 60d—DFT calculation of band structure, projected electron density of state, and phonon density of state of monolayer graphene with different pore shapes. Black double-headed arrows indicate bandgap (E_{g}). The diameter of the nanopores is 1.2 nm.

FIG. 61a-FIG. 61b—Calculated Seebeck coefficient of monolayer graphene with different pore shapes as a function of temperature and chemical potential. The diameter of the nanopores is 1.2 nm.

FIG. 62—Photographs of a flexible device assembled with ordered porous graphene strips.

FIG. 63a-FIG. 63b—Open-circuit voltage of bilayer nonporous graphene-based device. (FIG. 63a) Theoretical and experimental open-circuit voltage (U_{oc}) of bilayer nonporous graphene using EM and thermal fields. (FIG. 63b) The ratio of U_{oc} of nonporous graphene under an EM field over the theoretical U_{oc}.

FIG. 64—Finite-element simulation of bilayer graphene's temperature profile and electricity output with and without circular pores. The EM radiation time is listed on top of each simulation result.

FIG. 65a-FIG. 65b—Schematic illustration of transport of electrons in a graphene layer with and without circular pores. The presence of nanopores will confine/guide the transport of electrons in graphene nanoribbons between the pores.

FIG. 66a-FIG. 66c—Finite-element simulation of the EM field interference behavior in graphene with different structures. Temperature and electrical potential profile of bilayer graphene (FIG. 66a) with circular nanopores and (FIG. 66b) without nanopores using an EM field or thermal field. (FIG. 66c) Effect of EM radiation direction on the electrical potential profile of bilayer nonporous graphene.

FIG. 67a-FIG. 67b—Output voltage and power of ordered porous graphene upon EM radiation. (FIG. 67a) Output voltage (V_{L})-current (I) curve of bilayer graphene with circular nanopores with a load resistance of 0-150Ω. (FIG. 67b) Output power (P) of bilayer graphene with circular nanopores upon different EM wave radiation times as a function of load resistance.

FIG. 68—Temporal temperature change at the hot and cold ends of the graphene-based devices at different temperatures. The black and red color curves represent the temperature at the graphene strip's hot (Tₕ) and cold (T_{c}) end.

FIG. 69—Output power (Pₒᵤₜ) of a bilayer porous graphene-based device as a function of EM radiation at different temperatures.

FIG. 70a-FIG. 70b—Power output by a flexible ordered porous graphene device during bending. Maximum output power (Pmax) as a function of (FIG. 70a) the number of times and (FIG. 70b) the angle of bending of the ordered porous graphene-based flexible device. Error bars represent standard deviations from three independent measurements.

FIG. 71a-FIG. 71b—Electrical resistance of ordered porous graphene-based devices upon bending. The electric resistance (Rₛ) as a function of (FIG. 71a) the number of times and (FIG. 71b) the angle of bending of ordered porous graphene-based flexible devices. R₀ is the resistance of the graphene-based device without bending. Error bars represent standard deviations from three independent measurements.

FIG. 72a-FIG. 72c—Molecular dynamics simulation of the thermal conductivity of graphene-based devices under bending deformation. Thermal conductivity ratio of (FIG. 72a) nonporous graphene and graphene with (FIG. 72b) partially overlapped nanopores and (FIG. 72c) completely overlapped nanopores upon different bending deformations. The compressive strain is defined as the ratio of the projection length of graphene upon bending over the initial length of the non-deformed graphene. Error bars represent standard deviations from three independent measurements.

FIG. 73a-FIG. 73g. Synthesis and structural characterization of element-doped porous graphene superlattice. FIG. 73a, Schematic representation of the synthesis process for graphene superlattice. FIG. 73b-FIG. 73e, Transmission electron micrographs showing (FIG. 73b) monolayer graphene sublattice with monodisperse square-shaped nanopores, bilayer graphene superlattice with (FIG. 73c) partially and (FIG. 73e) overlapped square nanopores. The top and bottom layers in the graphene superlattice in (FIG. 73d) are highlighted in red and green, respectively. The inset in (FIG. 73d) illustrates the periodic arrangement of carbon atoms in (FIG. 73b) monolayer graphene sublattice and (FIG. 73c) bilayer graphene superlattice. FIG. 73f, Fitted EXAFS spectra of Te foil and Te-doped graphene superlattice. FIG. 73g. DFT calculation of the energy of diffusion for doped Te atoms towards either a pore edge or a framework.

FIG. 74a-FIG. 74e. DFT calculation of electronic and phonon structure of graphene superlattice. FIG. 74a, Band structure and projected density of states of pristine graphene and graphene superlattice. ε_{F} represents the Fermi level. FIG. 74b, Charge density difference between the overlapped and exposed carbon atoms in graphene superlattice. FIG. 74c-FIG. 74e, Phonon density of states, phonon band structure, and phonon group velocity of graphene superlattice. The overlap ratio of nanopores in graphene superlattice, defined by the ratio of the pore area covered by a neighboring graphene layer to the total pore area, was set to 0.5. The graphene superlattice was Te-doped.

FIG. 75a-FIG. 75g. Permittivity and EM wave modulation of graphene superlattice. FIG. 75a, Frequency-dependent permittivity of graphene superlattice. FIG. 75b, Thickness-dependent EM absorption efficiency of pristine bilayer graphene and graphene superlattice. FIG. 75c, Comparison of EM shielding effectiveness (SE_{T}) and EM absorption efficiency (A %) averaged by EM absorbing material thickness (d) of graphene superlattice with carbon nanotubes (CNTs) and other 2D materials. d, Experimental setup of graphene superlattice-based EM-electricity converter. FIG. 75e, FIG. 75f, (FIG. 75e) Open circuit voltage (U_{oc}) and (FIG. 75f) EM-electivity conversion of pristine graphene and graphene superlattice-based EM-electricity converter as a function of EM emission power. The EM-to-electricity conversion efficiency is defined as the ratio of power generated by a graphene device, which converts input electromagnetic energy into direct current, to the input EM power. Error bars represent standard deviations from three independent measurements. FIG. 75g, Photographs of EM-electricity conversion by graphene superlattice-based EM-electricity converter from a 5G cell phone, a Wi-Fi router, a telecommunication tower, and a microwave. The output DC electricity can be used to power electronic devices such as a digital hygro-thermometer and a collection of LEDs arranged in a pattern. The graphene superlattice was Te-doped.

FIG. 76a-FIG. 76e Expanded applications of graphene superlattice. FIG. 76a, Tunable EM transmission of a graphene superlattice-based smart window via applied voltage. FIG. 76b, Photoluminescence intensity comparison between pristine graphene and graphene superlattice. FIG. 76c, FIG. 76d, Temperature-dependent thermal conductivity (κ_{T}) and Seebeck coefficient of pristine graphene and graphene superlattice. Error bars indicate standard deviations from three independent measurements. FIG. 76e, Comparison of ZT values of graphene superlattice with state-of-the-art thermoelectric materials. The graphene superlattice was Te-doped.

FIG. 77a-FIG. 77d—In-situ growth of cubic Fe₃O₄ nanoparticles on graphene. FIG. 77a, FIG. 77b, Representative TEM images of cubic Fe₃O₄ nanoparticles. Inset in (FIG. 77b) shows the size distribution of Fe₃O₄ nanoparticles. FIG. 77c, FIG. 77d, TEM images of cubic Fe₃O₄ nanoparticles grown on graphene.

FIG. 78—X-ray diffraction (XRD) patterns revealing the crystal phase and composition evolution of cubic Fe₃O₄ nanoparticle-coated graphene upon annealing. The appearance of a diffraction peak at 2θ=44.4° in the annealed Fe₃O₄ nanoparticle-coated graphene is attributed to the (110) crystal plane of α-Fe.

FIG. 79a-FIG. 79h—Morphology of reduced graphene oxide and porous graphene. FIG. 79a-FIG. 79h, Representative TEM images of (FIG. 79a) wrinkled pristine reduced graphene oxide, (FIG. 79b) porous reduced graphene oxide nanosheets obtained by annealing cubic Fe₃O₄ nanoparticle-coated reduced graphene oxide, (FIG. 79c, FIG. 79d) porous graphene annealed at 650 °C for (FIG. 79c) 15 minutes and (FIG. 79d) 1 hour, (FIG. 79e-FIG. 79g) porous graphene annealed at (FIG. 79e, FIG. 79f) 1,000 °C and (FIG. 79g) 800 °C for 30 minutes, and (FIG. 79h) porous graphene obtained by incorporating an excessive quantity of cubic Fe₃O₄ nanoparticles (the loading amount of Fe₃O₄ nanoparticles is approximately 1.2 times greater than the amount used during the production of graphene superlattice). The observations reveal that insufficient annealing time results in incomplete reduction between the cubic Fe₃O₄ nanoparticle template and carbon atoms, hindering the formation of monodisperse nanopores on the graphene surface. Prolonged reaction time leads to excessive reduction and polydisperse and distorted pores, as the cubic Fe₃O₄ nanoparticle template continues to react with carbon on the second layer. High annealing temperature or excessive loading amounts causes cubic Fe₃O₄ nanoparticle template recrystallization and agglomeration, resulting in polydisperse and distorted pores. Precise control of reaction time, temperature and loaded amount is crucial for achieving monodisperse, square nanopores.

FIG. 80a-FIG. 80d—Morphology of bilayer graphene with overlapped nanopores. FIG. 80a, FIG. 80b, TEM images of cubic Fe₃O₄ nanoparticle coated-graphene. The average size of cubic Fe₃O₄ nanoparticles was approximately 7.1±0.8 nm. FIG. 80c, Bilayer graphene with completely overlapped nanopores. Inset in (FIG. 80c) shows the size distribution of cubic Fe₃O₄ nanoparticles. FIG. 80d, Raman spectrum of the bilayer graphene with overlapped pores. The Raman spectrum exhibits three prominent peaks: two peaks at ~1,580 cm⁻¹ (G-band) and ~1,350 cm⁻¹ (D-band) corresponding to the in-plane vibration of sp² carbon atoms in a 2D hexagonal lattice and the vibration of sp³ carbon atoms in disordered graphite, respectively, and a 2D peak at ~2,680 cm⁻¹. The low intensity ratio of the D-band peak to the G-band peak (less than 0.1) confirm the high crystallinity of the graphene structure. Furthermore, the graphene is estimated to be approximately two layers, as indicated by the proximity of 2D peaks to the G-band.

FIG. 81a-FIG. 81b—Morphology of multilayer porous graphene. FIG. 81a, FIG. 81b, TEM images of trilayer and multilayer graphene with 5 or 6 layers. Inset in (FIG. 81b) shows the magnified TEM image of porous multilayer graphene.

FIG. 82a-FIG. 82e—Composition and crystal structure of graphene superlattice. FIG. 82a, TEM element mapping of graphene superlattice. FIG. 82b, FT-IR spectra of graphene superlattice and pristine bilayer graphene. FIG. 82c, X-ray photoelectric energy survey spectrum of graphene superlattice. FIG. 82d, FIG. 82e, X-ray photoelectron energy spectrum (XPS) of C Is and O Is spectra of graphene superlattice.

FIG. 83a-FIG. 83b—FT-IR spectra of annealed graphene superlattice. FIG. 83a, FIG. 83b, The FT-IR spectra of graphene superlattice annealed at 800 °C in nitrogen and 1,200 °C in hydrogen. Upon annealing, the peaks attributed to —C—O— and —C═O bonds disappear from the spectra, indicating the removal or decomposition of oxygen-containing functional groups.

FIG. 84a-FIG. 84b—EXAFS analysis of graphene superlattice. FIG. 84a, Normalized Te K-edge EXAFS spectra of Te foil and Te-doped graphene superlattice. FIG. 84b, First-shell model EXAFS fit of the Fourier transform at Te K-edge for Te-doped graphene superlattice. The EXAFS data were analyzed using the Athena modules within the IFEFFIT software packages. The preprocessing of the raw EXAFS spectra involved subtracting the pre-edge background absorption and normalizing the post-edge to a unity value. The data were then transformed from energy space to photoelectron momentum vector k space, employing a k³-weighted method to compensate for oscillatory decay. Fourier transformation of the k³-weighted χ^{(k)} function with a Hanning window was performed to generate the R-space spectra, representing bond distances (R) in real space. The Artemis module was utilized for extracting local structural information through least-square curve parameter fitting, where theoretical models were fitted to the experimental data to determine the characteristic features of the local atomic arrangement.

FIG. 85a-FIG. 85b—DFT calculation of Te-carbon bond length in Te-doped graphene and graphene superlattice. FIG. 85a, Te-doped graphene superlattice. FIG. 85b, Te-doped pristine graphene. The computational results reveal that Te doping at the pore edge of a graphene superlattice leads to the formation of Te—C bonds with lengths of 1.73 Å and 2.03 Å, consistent with experimental observations. In contrast, Te incorporation into the graphene framework results in Te bonding to three neighboring carbon atoms with a uniform bond length of 1.53 Å.

FIG. 86—Fourier transformed EXAFS spectra of the Te K-edge for the Te-doped pristine graphene. A prominent peak was observed at 1.53 Å, indicating the presence of Te and C atoms and the absence of any significant peaks in the bond range of 3-8 Å. This absence suggests that Te has successfully integrated into the carbon framework, indicating successful doping within the graphene lattice.

FIG. 87—Effect of annealing temperature on element doping in pristine graphene and graphene superlattice. At lower temperatures ranging from 600 °C to 650 °C, the doping content of Te in pristine graphene was found to be less than 1.0 wt %, indicating unsuccessful doping of Te into the graphene framework. However, a significant increase in Te signals was observed at 675 °C, with the doping content further increasing from 2.1 wt % to 4.5 wt % as the temperature was raised to 700 °C. In contrast to pristine graphene, Te signals were detected in graphene superlattice throughout the entire temperature range of 600-700 °C. Moreover, within the lower temperature range of 600-650 °C, the Te atoms predominantly localized at the edges of the pores. As the temperature increased, the Te atoms began to distribute more uniformly within the graphene framework. These findings suggest that at lower temperatures, Te demonstrates a preference for doping at the edges of the pores.

FIG. 88a-FIG. 88d—EXAFS analysis of Te-doped pristine graphene and graphene superlattice with varying annealing temperatures. FIG. 88a-FIG. 88d, (FIG. 88a-FIG. 88c) Normalized Te K-edge EXAFS spectra and (FIG. 88b, FIG. 88d) first-shell model fit of the Fourier transform of the Te K-edge for (FIG. 88a, FIG. 88b) Te-doped graphene superlattice annealed at 625 °C and 700 °C and (FIG. 88c, FIG. 88d) Te-doped pristine graphene annealed at 675 °C and 700 °C.

FIG. 89—DFT simulations of Te atoms bonded to carbon atom in the framework and at the edge. DFT simulations were conducted to investigate the binding energy (Er) when Te atoms are bonded to carbon atoms in different configurations. Three models were considered: i) porous monolayer sublattice, ii) graphene superlattice, and iii) bilayer graphene with completely overlapped pores. For each model, Er associated with Te doping in the graphene framework and at the pore edge was calculated. The results reveal that Er of Te atoms bonded to carbon atoms at the pore edge is lower compared to doping in the framework. This finding indicates that successful incorporation of Te atoms through edge-doping requires a relatively lower temperature.

FIG. 90a-FIG. 90f—Analysis of crystal structure of graphene superlattice. FIG. 90a-FIG. 90c, NEXAFS of C K-edge of pristine graphene, bilayer graphene with complete overlapped nanopores, and graphene superlattice. FIG. 90d-FIG. 90f, NEXAFS of C K-edge of graphene superlattice and Te-doped graphene superlattice.

FIG. 91—Temperature-dependent carrier mobility of pristine graphene and porous graphene. Temperature-dependent carrier mobility (μH) and Hall carrier density (ne) of pristine bilayer graphene, bilayer graphene with overlapped nanopores and graphene superlattice.

FIG. 92a-FIG. 92d—DFT simulation of the band structure and projected density of states of graphene with different pore overlap ratios. FIG. 92a, Pristine graphene. FIG. 92b-FIG. 92d, Bilayer graphene with completely overlapped pores with an overlap ratio of 1, partially overlapped pores with an overlap ratio of 0.5, and no overlapped pores with an overlap ratio of 0. Zero density of states (ε_{F}) are indicated by the horizontal black dashed line. The size of the nanopores is 1.0 nm.

FIG. 93a-FIG. 93e—DFT simulation of the band structure and projected density of states of graphene superlattice with varying Te doping levels. FIG. 93a-FIG. 93e, Graphene superlattice (FIG. 93a) without Te doping (carbon atoms at the pore edge were saturated with —H, —OH, ═O and —O—) and with (FIG. 93b) two, (FIG. 93c) four, (FIG. 93d) six and (FIG. 93e) ten carbon atoms at the pore edge bonded with Te atoms for one layer. Zero density of states (EF) are indicated by the horizontal black dashed line. The size of the nanopores is 1.0 nm.

FIG. 94a-FIG. 94c—DFT simulation of the band structure and projected density of states of graphene superlattice with various types of dopant elements. FIG. 94a-FIG. 94c, Graphene superlattice doped with N, P, and S. Eight carbon atoms at the pore edge were bonded with the above-mentioned atoms for one layer, while the remaining carbon atoms at the pore edge were saturated with H atoms. Zero density of states (ε_{F}) are indicated by the horizontal black dashed line. The size of the nanopores is 1.0 nm.

FIG. 95—DFT simulation of the band structure and projected density of states of bilayer graphene with circular pores. The overlap ratio is 0.5. Eight carbon atoms at the pore edge were bonded with Te for one layer, while the remaining carbon atoms at the pore edge were saturated with H atoms. Zero density of states (ε_{F}) are indicated by the horizontal black dashed line. The diameter of the nanopores is 1.0 nm.

FIG. 96a-FIG. 96c—DFT simulation of the band structure and projected density of states of graphene with varying defect structure. FIG. 96a-FIG. 96c, Te-doped pristine graphene, graphene with vacancy defects (i.e., a removed carbon atom), and an armchair graphene nanoribbon with 3.2 nm in length and 1.1 nm in width. The edges of the graphene nanoribbon were saturated with H atoms.

FIG. 97a-FIG. 97b—DFT simulation of the vibrational density of states in Te-doped graphene superlattice. FIG. 97a, Vibrational density of states of carbon atom in the framework and at the pore edge. FIG. 97b, Vibrational density of states of overlapped carbon atoms and exposed carbon atoms.

FIG. 98a-FIG. 98b—DFT simulation of the phonon band structure of graphene. FIG. 98a, Pristine bilayer graphene. FIG. 98b, Te-doped graphene superlattice.

FIG. 99a-FIG. 99b—DFT simulation of the phonon participation ratio of graphene. FIG. 99a, Pristine bilayer graphene. FIG. 99b, Te-doped graphene superlattice. The reduction in phonon energy stems from a decrease in the atomic participation ratio (PR), which can be calculated by

$${PR}_{λ}^{- 1} = n {\sum }_{j} {( {\sum }_{α} {ε}_{j α , λ}^{*} {ε}_{j α , λ} )}^{2}$$

(Liu J P et al. Nat. Rev. Phys. 2021, 3, 367), where n is the total number of atoms, j sums over all atoms, a denotes a Cartesian direction, ε*_{ja,λ} and ε_{ja,λ}represent the conjugated vibrational eigenvector component corresponding to the λ-th normal mode (Cui L et al. Int. J. Heal. Mass. Tran. 2021, 165, 120685).

FIG. 100a-FIG. 100h—Frequency-dependent permittivity of pristine graphene and graphene superlattice. FIG. 100a, Pristine bilayer graphene. FIG. 100b-FIG. 100h, Graphene superlattice doped with H, B, N, O, P, S, and Se.

FIG. 101a-FIG. 101i—Cole-Cole curves of pristine graphene and graphene superlattice. FIG. 101a, Pristine bilayer graphene. FIG. 101b-FIG. 101i, Graphene superlattice doped with H, B, N, O, P, S, Se, and Te.

FIG. 102a-FIG. 102b—EM shielding performance of pristine graphene and Te-doped graphene superlattice. FIG. 102a, FIG. 102b, EM shielding percentage and (FIG. 102b) EM shielding effectiveness (SE_{T}) as a function thickness of pristine graphene and graphene superlattice. Error bars represent standard deviations from three independent measurements.

FIG. 103—Doped element-dependent EM absorption of graphene superlattice. The maximum absorption frequencies for different dopants in graphene superlattice were determined as follows: H-doped (3.2 GHz), B-doped (3.9 GHz), N-doped (4.3 GHz), S-doped (2.9 GHz), O-doped (3.5 GHz), P-doped (4.6 GHz), and Se-doped (2.8 GHz). Notably, all of these dopants exhibited EM absorption efficiencies exceeding 60%. This remarkable feature enables the graphene superlattice to selectively absorb EM waves at a specific wavelength while allowing the transmission of other frequency bands, thereby minimizing unnecessary signal loss. Error bars represent standard deviations from three independent measurements.

FIG. 104—Dimensions of graphene superlattice-based device designed for absorbing low-frequency EM waves. The optimal geometric shape, which allows for absorption in multiple lower-frequency bands, was determined using Computer Simulation Technology Microwave Studio software.

FIG. 105—Layout of rectifier for multiple low-frequency bands. The proposed layout for accommodating multiple low-frequency bands involves a rectifier with three parallel rectification branches. Each branch is constructed with a series connection of a diode, a DC-pass filter, a diode front-end transmission line, and an impedance matching network. The specific dimensions and geometric shapes of the rectifier are determined through calculations using the Advanced Design System software.

FIG. 106—Open circuit voltage as a function of distance between an EM wave emission source and a graphene-based device. The open circuit voltage (U_{oc}) of the Te-doped graphene superlattice-based device was consistently maintained at approximately 30 mV, even at a distance of 10 m from a 10 W EM source. In contrast, the U_{oc} of the Te-doped pristine graphene-based device rapidly decreased to below 0.01 mV at a distance of only 4 m. Error bars represent standard deviations from three independent measurements.

FIG. 107a-FIG. 107b—Output voltage and output power of graphene superlattice-based device upon EM radiation. FIG. 107a, Output voltage (V_{L})-current (I) curve of Te-doped graphene superlattice-based device with a load resistance ranging from 0Ω to 40Ω. FIG. 107b, Output power (Pₒᵤₜ) of Te-doped graphene superlattice-based device as a function of load resistance, under different levels of EM wave radiation power (ranging from 0.05 W to 10 W).

FIG. 108a-FIG. 108b—Open circuit voltage of pristine graphene and graphene superlattice-based device after bending. FIG. 108a, FIG. 108b, The open circuit voltage of the Te-doped graphene superlattice-based device before (U_{oc}) and after (U′_{oc}) after subjecting it to different degrees of bending and varying bending cycles. Error bars represent standard deviations from three independent measurements.

FIG. 109—Infrared emissivity of pristine graphene and graphene superlattice as a function of infrared wavelength. The results show that the Te-doped graphene superlattice exhibits an infrared emissivity of ~30%. This value was significantly lower compared to the infrared emissivity of pristine graphene. The lower infrared emissivity of the Te-doped graphene superlattice suggests that it has enhanced stealth capabilities in the infrared range.

### DETAILED DESCRIPTION

The compositions, devices, and methods described herein may be understood more readily by reference to the following detailed description of specific aspects of the disclosed subject matter and the Examples included therein.

Before the present compositions, devices, and methods are disclosed and described, it is to be understood that the aspects described below are not limited to specific synthetic methods or specific reagents, as such may, of course, vary. It is also to be understood that the terminology used herein is for the purpose of describing particular aspects only and is not intended to be limiting.

Also, throughout this specification, various publications are referenced. The disclosures of these publications in their entireties are hereby incorporated by reference into this application in order to more fully describe the state of the art to which the disclosed matter pertains. The references disclosed are also individually and specifically incorporated by reference herein for the material contained in them that is discussed in the sentence in which the reference is relied upon.

In this specification and in the claims that follow, reference will be made to a number of terms, which shall be defined to have the following meanings.

Throughout the description and claims of this specification the word “comprise” and other forms of the word, such as “comprising” and “comprises,” means including but not limited to, and is not intended to exclude, for example, other additives, components, integers, or steps.

As used in the description and the appended claims, the singular forms “a,” “an,” and “the” include plural referents unless the context clearly dictates otherwise. Thus, for example, reference to “a composition” includes mixtures of two or more such compositions, reference to “an agent” includes mixtures of two or more such agents, reference to “the component” includes mixtures of two or more such components, and the like.

“Optional” or “optionally” means that the subsequently described event or circumstance can or cannot occur, and that the description includes instances where the event or circumstance occurs and instances where it does not.

Ranges can be expressed herein as from “about” one particular value, and/or to “about” another particular value. By “about” is meant within 5% of the value, e.g., within 4, 3, 2, or 1% of the value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

“Exemplary” means “an example of” and is not intended to convey an indication of a preferred or ideal embodiment. “Such as” is not used in a restrictive sense, but for explanatory purposes.

Values can be expressed herein as an “average” value. “Average” generally refers to the statistical mean value.

By “substantially” is meant within 5%, e.g., within 4%, 3%, 2%, or 1%.

It is understood that throughout this specification the identifiers “first” and “second” are used solely to aid in distinguishing the various components and steps of the disclosed subject matter. The identifiers “first” and “second” are not intended to imply any particular order, amount, preference, or importance to the components or steps modified by these terms.

As used herein the term “plurality” means 2 or more (e.g., 3 or more; 4 or more; 5 or more; 10 or more; 15 or more; 20 or more; 25 or more; 30 or more; 40 or more; 50 or more; 75 or more; 100 or more; 150 or more; 200 or more; 250 or more; 300 or more; 400 or more; 500 or more; 750 or more; 1000 or more; 1500 or more; 2000 or more; 2500 or more; 3000 or more; 4000 or more; or 5000 or more).

As used herein, by a “subject” is meant an individual. Thus, the “subject” can include domesticated animals (e.g., cats, dogs, etc.), livestock (e.g., cattle, horses, pigs, sheep, goats, etc.), laboratory animals (e.g., mouse, rabbit, rat, guinea pig, etc.), and birds. “Subject” can also include a mammal, such as a primate or a human. Thus, the subject can be a human or veterinary patient. The term “patient” refers to a subject under the treatment of a clinician, e.g., physician.

“Phase,” as used herein, generally refers to a region of a material having a substantially uniform composition which is a distinct and physically separate portion of a heterogeneous system. The term “phase” does not imply that the material making up a phase is a chemically pure substance, but merely that the chemical and/or physical properties of the material making up the phase are essentially uniform throughout the material, and that these chemical and/or physical properties differ significantly from the chemical and/or physical properties of another phase within the material. Examples of physical properties include density, thickness, aspect ratio, specific surface area, porosity, and dimensionality. Examples of chemical properties include chemical composition.

By “continuous” is meant a phase such that all points within the phase are directly connected, so that for any two points within a continuous phase there exists a path which connects the two points and does not leave the phase.

### Materials

Disclosed herein are compositions, devices, and methods of use thereof, for example, for harvesting electromagnetic waves and generating electricity.

For example, disclosed herein are materials for converting electromagnetic (EM) radiation directly into electricity, wherein the material absorbs electromagnetic radiation, converts the absorbed electromagnetic radiation into thermal energy, and subsequently converts the thermal energy into electric energy via a thermoelectric effect.

For example, the material can absorb electromagnetic radiation at one or more frequencies of 1 GHz or more (e.g., 1.25 GHz or more, 1.5 GHz or more, 1.75 GHz or more, 2 GHz or more, 2.25 GHz or more, 2.5 GHz or more, 2.75 GHz or more, 3 GHz or more, 3.25 GHz or more, 3.5 GHz or more, 3.75 GHz or more, 4 GHz or more, 4.25 GHz or more, 4.5 GHz or more, or 4.75 GHz or more). In some examples, the material can absorb electromagnetic radiation at one or more frequencies of 5 GHz or less (e.g., 4.75 GHz or less, 4.5 GHz or less, 4.25 GHz or less, 4 GHz or less, 3.75 GHz or less, 3.5 GHz or less, 3.25 GHz or less, 3 GHz or less, 2.75 GHz or less, 2.5 GHz or less, 2.25 GHz or less, 2 GHz or less, 1.75 GHz or less, 1.5 GHz or less, or 1.25 GHz or less). The one or more frequencies of electromagnetic radiation that the material can absorb can range from any of the minimum values described above to any of the maximum values described above. For example, the material can absorb electromagnetic radiation at one or more frequencies of from 1 GHz to 5 GHz (e.g., from 1 GHz to 3 GHz, from 3 GHz to 5 GHz, from 1 GHz to 2 GHz, from 2 GHz to 3 GHz, from 3 GHz to 4 GHz, from 4 GHz to 5 GHz, from 1 GHz to 4.5 GHz, from 1 GHz to 4 GHz, from 1 GHz to 3.5 GHz, from 1 GHz to 2.5 GHz, from 1.5 GHz to 5 GHz, from 2 GHz to 5 GHz, from 2.5 GHz to 5 GHz, from 3.5 GHz to 5 GHz, from 1.5 GHz to 4.5 GHz, or from 2 GHz to 4 GHz).

In some examples, the material can comprise one or more porous layers, wherein each porous layer comprises a two-dimensional material layer permeated by a plurality of pores, for example, such that each of the plurality of pores traverses the average thickness of the two-dimensional material.

Also disclosed herein are materials comprising one or more porous layers, wherein each porous layer comprises a two-dimensional material layer permeated by a plurality of pores, for example, such that each of the plurality of pores traverses the average thickness of the two-dimensional material.

The two-dimensional material can, for example, comprise a carbonaceous or graphitic material, a nitride material, or a combination thereof. In some examples, the two-dimensional material can comprise a carbonaceous or graphitic material. Examples of carbon materials include, but are not limited to, graphitic carbon and graphites, including pyrolytic graphite (e.g., highly ordered pyrolytic graphite (HOPG)) and isotropic graphite, amorphous carbon, carbon black, single- or multi-walled carbon nanotubes, graphene (e.g., graphene platelets), glassy carbon, diamond-like carbon (DLC) or doped DLC, such as boron-doped diamond, pyrolyzed photoresist films, and others known in the art. In some examples, the two-dimensional material comprises graphene.

In some examples, each two-dimensional material layer is a continuous phase with said layer.

In some examples, each two-dimensional material layer further comprises a dopant. Examples of dopants include, but are not limited to, C, H, B, N, O, P, S, Se, Te, and combinations thereof. In some examples, the dopant is located around the perimeter of the pores. In some examples the identity and/or location of the dopant within each two-dimensional material layer can be selected based on the desired properties of the material.

In some examples, the plurality of pores can be arranged in a random or disordered array. In some examples, the plurality of pores are arranged in an ordered array.

Each of the plurality of pores can have a cross-sectional shape in the plane of the two-dimensional material layer, wherein the shape can be any shape, such as a regular shape, an irregular shape, an isotropic shape, or an anisotropic shape. In some examples, the cross-sectional shape of each of the plurality of pores can be substantially circular, ovate, ovoid, elliptic, triangular, rectangular, polygonal, etc. In some examples, the cross-sectional shape of each of the plurality of pores can be substantially circular, square, or hexagonal. In some examples, the cross-sectional shape of each of the plurality of pores can be substantially circular.

The plurality of pores can have an average pore size. As used herein “pore size” refers to the largest cross-sectional dimension of a pore in the plane of the two-dimensional material layer. For example, in the case of a pore with a substantially circular cross-sectional shape, the pore size would be the diameter of the pore. The average pore size can be determined, for example, using electron microscopy (e.g., scanning electron microscopy (SEM), scanning transmission electron microscopy (STEM)).

For example, the plurality of pores can have an average pore size of 0.5 nanometers (nm) or more (e.g., 0.75 nm or more, 1 nm or more, 1.25 nm or more, 1.5 nm or more, 1.75 nm or more, 2 nm or more, 2.25 nm or more, 2.5 nm or more, 3 nm or more, 3.5 nm or more, 4 nm or more, 4.5 nm or more, 5 nm or more, 6 nm or more, 7 nm or more, 8 nm or more, 9 nm or more, 10 nm or more, 11 nm or more, 12 nm or more, 13 nm or more, 14 nm or more, 15 nm or more, 16 nm or more, 17 nm or more, 18 nm or more, 19 nm or more, 20 nm or more, 21 nm or more, 22 nm or more, 23 nm or more, or 24 nm or more). In some examples, the plurality of pores can have an average pore size of 25 nm or less (e.g., 24 nm or less, 23 nm or less, 22 nm or less, 21 nm or less, 20 nm or less, 19 nm or less, 18 nm or less, 17 nm or less, 16 nm or less, 15 nm or less, 14 nm or less, 13 nm or less, 12 nm or less, 11 nm or less, 10 nm or less, 9 nm or less, 8 nm or less, 7 nm or less, 6 nm or less, 5 nm or less, 4.5 nm or less, 4 nm or less, 3.5 nm or less, 3 nm or less, 2.5 nm or less, 2.25 nm or less, 2 nm or less, 1.75 nm or less, 1.5 nm or less, 1.25 nm or less, 1 nm or less, or 0.75 nm or less). The average pore size can range from any of the minimum values described above to any of the maximum values described above. For example, the plurality of pores can have an average pore size of from 0.5 nanometers (nm) to 25 nm (e.g., from 0.5 nm to 12 nm, from 12 nm to 25 nm, from 0.5 nm to 5 nm, from 5 nm to 10 nm, from 10 nm to 15 nm, from 15 nm to 20 nm, from 20 nm to 25 nm, from 0.5 nm to 20 nm, from 0.5 nm to 15 nm, from 0.5 nm to 10 nm, from 1 nm to 25 nm, from 5 nm to 25 nm, from 10 nm to 25 nm, from 15 nm to 25 nm, from 1 nm to 20 nm, or from 1 nm to 10 nm).

In some examples, the plurality of pores can be substantially monodisperse. “Monodisperse” and “homogeneous size distribution,” as used herein, and generally describe a population of pores where all of the pores are the same or nearly the same size. As used herein, a monodisperse distribution refers to pore distributions in which 80% of the distribution (e.g., 85% of the distribution, 90% of the distribution, or 95% of the distribution) lies within 25% of the median pore size (e.g., within 20% of the median pore size, within 15% of the median pore size, within 10% c of the median pore size, or within 5% of the median pore size).

The material can comprise any suitable number of layers. In some examples, the total number of layers is 1 or more (e.g., 2 or more, 3 or more, 4 or more, 5 or more, 6 or more, 7 or more, 8 or more, 9 or more, 10 or more, 11 or more, 12 or more, 13 or more, 14 or more, 15 or more, 16 or more, 17 or more, 18 or more, or 19 or more). In some examples, the total number of layers is 20 or less (e.g., 19 or less, 18 or less, 17 or less, 16 or less, 15 or less, 14 or less, 13 or less, 12 or less, 11 or less, 10 or less, 9 or less, 8 or less, 7 or less, 6 or less, 5 or less, 4 or less, 3 or less, or 2 or less). The total number of layers can range from any of the minimum values described above to any of the maximum values described above. For example, the total number of layers can be from 1 to 20 (e.g., from 1 to 10, from 10 to 20, from 1 to 4, from 4 to 8, from 8 to 12, from 12 to 16, from 16 to 20, from 1 to 19, from 1 to 15, from 1 to 8, from 1 to 6, from 1 to 5, from 2 to 20, from 3 to 20, from 4 to 20, from 5 to 20, from 6 to 20, from 7 to 20, from 8 to 20, from 12 to 20, from 2 to 19, or from 3 to 18).

In some examples, when the material includes 2 or more layers, the plurality of pores in a given layer are offset relative to the plurality of pores in a neighboring layer.

For example, when the material includes 2 or more layers, the plurality of pores in a given layer have an overlap ratio of from 0 to 1 relative to the plurality of pores in a neighboring layer, wherein a ratio of 1 means that the pores are substantially aligned.

For example, the overlap ratio can be 0 or more (e.g., 0.1 or more, 0.2 or more, 0.3 or more, 0.4 or more, 0.5 or more, 0.7 or more, 0.8 or more, or 0.9 or more). In some examples, the overlap ratio can be 1 or less (e.g., 0.9 or less, 0.8 or less, 0.7 or less, 0.6 or less, 0.5 or less, 0.4 or less, 0.3 or less, 0.2 or less, or 0.1 or less). The overlap ratio can range from any of the minimum values described above to any of the maximum values described above. For example, the overlap ratio can be from 0 to 1 (e.g., from 0 to 0.5, from 0.5 to 1, from 0 to 0.2, from 0.2 to 0.4, from 0.4 to 0.6, from 0.6 to 0.8, from 0.8 to 1, from 0 to 0.9, from 0 to 0.8, from 0 to 0.7, from 0 to 0.6, from 0 to 0.4, from 0 to 0.3, from 0.1 to 1, from 0.2 to 1, from 0.3 to 1, from 0.4 to 1, from 0.6 to 1, from 0.7 to 1, from 0.1 to 0.9, or from 0.2 to 0.8).

In some examples, the material has an EM dissipation factor of 50 or more at a frequency of from 1 GHz to 5 GHz (e.g., 55 or more, 60 or more, 65 or more, 70 or more, 75 or more, 80 or more, 85 or more, 90 or more, 95 or more, 100 or more, 110 or more, 120 or more, 130 or more, 140 or more, 150 or more, 160 or more, 170 or more, 180 or more, 190 or more, 200 or more, 225 or more, 250 or more, 275 or more, 300 or more, 325 or more, 350 or more, or 375 or more).

In some examples, the material has an EM dissipation factor of 400 or less at a frequency of from 1 GHz to 5 GHz (e.g., 375 or less, 350 or less, 325 or less, 300 or less, 275 or less, 250 or less, 225 or less, 200 or less, 190 or less, 180 or less, 170 or less, 160 or less, 150 or less, 140 or less, 130 or less, 120 or less, 110 or less, 100 or less, 95 or less, 90 or less, 85 or less, 80 or less, 75 or less, 70 or less, 65 or less, 60 or less, or 55 or less). The EM dissipation factor can range from any of the minimum values described above to any of the maximum values described above. For example, the material can have an EM dissipation factor of from 50 to 400 at a frequency of from 1 GHz to 5 GHz (e.g., from 50 to 225, from 225 to 400, from 50 to 100, from 100 to 150, from 150 to 200, from 200 to 250, from 250 to 300, from 300 to 350, from 350 to 400, from 75 to 400, from 100 to 400, from 125 to 400, from 150 to 400, from 200 to 400, from 300 to 400, from 50 to 375, from 50 to 350, from 50 to 300, from 50 to 250, from 50 to 200, from 50 to 150, from 75 to 375, or from 100 to 350).

In some examples, the material has a thermal conductivity of 0.1 Wm⁻¹K⁻¹ or more at a temperature of from 300-500 K (e.g., 0.25 Wm⁻¹K⁻¹ or more, 0.5 Wm⁻¹K⁻¹ or more, 0.75 Wm⁻¹K⁻¹ or more, 1 Wm⁻¹K⁻¹ or more, 1.25 Wm⁻¹K⁻¹ or more, 1.5 Wm⁻¹K⁻¹ or more, 1.75 Wm⁻¹K⁻¹ or more, 2 Wm⁻¹K⁻¹ or more, 2.25 Wm⁻¹K⁻¹ or more, 2.5 Wm⁻¹K⁻¹ or more, 3 Wm⁻¹K⁻¹ or more, 3.5 Wm⁻¹K⁻¹ or more, 4 Wm⁻¹K⁻¹ or more, 4.5 Wm⁻¹K⁻¹ or more, 5 Wm⁻¹K⁻¹ or more, 6 Wm⁻¹K⁻¹ or more, 7 Wm⁻¹K⁻¹ or more, 8 Wm⁻¹K⁻¹ or more, or 9 Wm⁻¹K⁻¹ or more). In some examples, the material can have a thermal conductivity of 10 Wm⁻¹K⁻¹ or less at a temperature of from 300-500 K (e.g., 9 Wm⁻¹K⁻¹ or less, 8 Wm⁻¹K⁻¹ or less, 7 Wm⁻¹K⁻¹ or less, 6 Wm⁻¹K⁻¹ or less, 5 Wm⁻¹K⁻¹ or less, 4.5 Wm⁻¹K⁻¹ or less, 4 Wm⁻¹K⁻¹ or less, 3.5 Wm⁻¹K⁻¹ or less, 3 Wm⁻¹K⁻¹ or less, 2.5 Wm⁻¹K⁻¹ or less, 2.25 Wm⁻¹K⁻¹ or less, 2 Wm⁻¹K⁻¹ or less, 1.75 Wm⁻¹K⁻¹ or less, 1.5 Wm⁻¹K⁻¹ or less, 1.25 Wm⁻¹K⁻¹ or less, 1 Wm⁻¹K⁻¹ or less, 0.75 Wm⁻¹K⁻¹ or less, 0.5 Wm⁻¹K⁻¹ or less, or 0.25 Wm⁻¹K⁻¹ or less). The thermal conductivity can range from any of the minimum values described above to any of the maximum values described above. For example, the material can have a thermal conductivity of from 0.1 Wm⁻¹K⁻¹ to 10 Wm⁻¹K⁻¹ at a temperature of from 300 to 500K (e.g., 0.1 Wm⁻¹K⁻¹ to 5 Wm⁻¹K⁻¹, from 5 Wm⁻¹K⁻¹ to 10 Wm⁻¹K⁻¹, from 0.1 Wm⁻¹K⁻¹ to 2 Wm⁻¹K⁻¹, from 2 Wm⁻¹K⁻¹ to 4 Wm⁻¹K⁻¹, from 4 Wm⁻¹K⁻¹ to 6 Wm⁻¹K⁻¹, from 6 Wm⁻¹K⁻¹ to 8 Wm⁻¹K⁻¹, from 8 Wm⁻¹K⁻¹ to 10 Wm⁻¹K⁻¹, from 0.1 Wm⁻¹K⁻¹ to 9 Wm⁻¹K⁻¹, from 0.1 Wm⁻¹K⁻¹ to 8 Wm⁻¹K⁻¹, from 0.1 Wm⁻¹K⁻¹ to 7 Wm⁻¹K⁻¹, from 0.1 Wm⁻¹K⁻¹ to 6 Wm⁻¹K⁻¹, from 0.1 Wm⁻¹K⁻¹ to 4 Wm⁻¹K⁻¹, from 0.1 Wm⁻¹K⁻¹ to 3 Wm⁻¹K⁻¹, from 0.1 Wm⁻¹K⁻¹ to 1 Wm⁻¹K⁻¹, from 0.25 Wm⁻¹ K⁻¹ to 10 Wm⁻¹K⁻¹, from 0.5 Wm⁻¹K⁻¹ to 10 Wm⁻¹K⁻¹, from 1 Wm⁻¹K⁻¹ to 10 Wm⁻¹K⁻¹, from 2 Wm⁻¹K⁻¹ to 10 Wm⁻¹K⁻¹, from 3 Wm⁻¹K⁻¹ to 10 Wm⁻¹K⁻¹, from 4 Wm⁻¹K⁻¹ to 10 Wm⁻¹K⁻¹, from 6 Wm⁻¹K⁻¹ to 10 Wm⁻¹K⁻¹, from 0.25 Wm⁻¹K⁻¹ to 9 Wm⁻¹K⁻¹, from 0.5 Wm⁻¹K⁻¹ to 8 Wm⁻¹K⁻¹).

In some examples, the material has an electrical conductivity of 100 S/cm or more at a temperature of from 300 to 500 K (e.g., 125 S/cm or more, 150 S/cm or more, 175 S/cm or more, 200 S/cm or more, 225 S/cm or more, 250 S/cm or more, 300 S/cm or more, 350 S/cm or more, 400 S/cm or more, 450 S/cm or more, 500 S/cm or more, 600 S/cm or more, 700 S/cm or more, 800 S/cm or more, 900 S/cm or more, 1000 S/cm or more, 1250 S/cm or more, 1500 S/cm or more, 1750 S/cm or more, 2000 S/cm or more, 2250 S/cm or more, 2500 S/cm or more, 3000 S/cm or more, 3500 S/cm or more, 4000 S/cm or more, 4500 S/cm or more, 5000 S/cm or more, 5500 S/cm or more, 6000 S/cm or more, or 6500 S/cm or more). In some examples, the material has an electrical conductivity of 7000 S/cm or less at a temperature of 300-500 K (e.g., 6500 S/cm or less, 6000 S/cm or less, 5500 S/cm or less, 5000 S/cm or less, 4500 S/cm or less, 4000 S/cm or less, 3500 S/cm or less, 3000 S/cm or less, 2500 S/cm or less, 2250 S/cm or less, 2000 S/cm or less, 1750 S/cm or less, 1500 S/cm or less, 1250 S/cm or less, 1000 S/cm or less, 900 S/cm or less, 800 S/cm or less, 700 S/cm or less, 600 S/cm or less, 500 S/cm or less, 450 S/cm or less, 400 S/cm or less, 350 S/cm or less, 300 S/cm or less, 250 S/cm or less, 225 S/cm or less, 200 S/cm or less, 175 S/cm or less, 150 S/cm or less, or 125 S/cm or less). The electrical conductivity can range from any of the minimum values described above to any of the maximum values described above. For example, the material can have an electrical conductivity of from 100 to 7000 S/cm at a temperature of 300-500 K (e.g., from 100 S/cm to 3500 S/cm, from 3500 S/cm to 7000 S/cm, from 100 S/cm to 1000 S/cm, from 1000 S/cm to 2000 S/cm, from 2000 S/cm to 3000 S/cm, from 3000 S/cm to 4000 S/cm, from 4000 S/cm to 5000 S/cm, from 5000 S/cm to 6000 S/cm, from 6000 S/cm to 7000 S/cm, from 100 S/cm to 6000 S/cm, from 100 S/cm to 5000 S/cm, from 100 S/cm to 4000 S/cm, from 100 S/cm to 3000 S/cm, from 100 S/cm to 2000 S/cm, from 100 S/cm to 1500 S/cm, from 100 S/cm to 500 S/cm, from 150 S/cm to 7000 S/cm, from 250 S/cm to 7000 S/cm, from 500 S/cm to 7000 S/cm, from 1000 S/cm to 7000 S/cm, from 2500 S/cm to 7000 S/cm, from 5000 S/cm to 7000 S/cm, from 125 S/cm to 6500 S/cm, or from 150 S/cm to 6000 S/cm).

In some examples, the material has a Seebeck coefficient with an absolute value of 5 μV/K at a temperature of from 300-500K (e.g., 10 μV/K or more, 15 μV/K or more, 20 μV/K or more, 25 μV/K or more, 30 μV/K or more, 35 μV/K or more, 40 μV/K or more, 45 μV/K or more, 50 μV/K or more, 60 μV/K or more, 70 μV/K or more, 80 μV/K or more, 90 μV/K or more, 100 μV/K or more, 125 μV/K or more, 150 μV/K or more, or 175 μV/K or more). In some examples, the material has a Seebeck coefficient with an absolute value of 200 μV/K or less at a temperature of from 300-500K (e.g., 175 μV/K or less, 150 μV/K or less, 125 μV/K or less, 100 μV/K or less, 90 μV/K or less, 80 μV/K or less, 70 μV/K or less, 60 μV/K or less, 50 μV/K or less, 45 μV/K or less, 40 μV/K or less, 35 μV/K or less, 30 μV/K or less, 25 μV/K or less, 20 μV/K or less, 15 μV/K or less, or 10 μV/K or less). The absolute value of the Seebeck coefficient can range from any of the minimum values described above to any of the maximum values described above. For example, the material can have a Seebeck coefficient with an absolute value of from 5 to 200 μV/K at a temperature of from 300-500K (e.g., from 5 μV/K to 100 μV/K, from 100 μV/K to 200 μV/K, from 5 μV/K to 50 μV/K, from 50 μV/K to 100 μV/K, from 100 μV/K to 150 μV/K, from 150 μV/K to 200 μV/K, from 10 μV/K to 200 μV/K, from 25 μV/K to 200 μV/K, from 50 μV/K to 200 μV/K, from 75 μV/K to 200 μV/K, from 125 μV/K to 200 μV/K, from 5 μV/K to 175 μV/K, from 5 μV/K to 150 μV/K, from 5 μV/K to 125 μV/K, from 5 μV/K to 75 μV/K, from 5 μV/K to 50 μV/K, from 10 μV/K to 175 μV/K, or from 15 μV/K to 150 μV/K).

The thermal conductivity, electrical conductivity, Seebeck coefficient, or a combination thereof of the material can be determined at a temperature of 300 K or more (e.g., 325 K or more, 350 K or more, 375 K or more, 400 K or more, 425 K or more, 450 K or more, or 475 K or more). In some example, thermal conductivity, electrical conductivity, Seebeck coefficient, or a combination thereof of the material can be determined at a temperature of 500 K or less (e.g., 475 K or less, 450 K or less, 425 K or less, 400 K or less, 375 K or less, 350 K or less, or 325 K or less). The temperature at which thermal conductivity, electrical conductivity, Seebeck coefficient, or a combination thereof of the material is determined can range from any of the minimum values described above to any of the maximum values described above. For example, the thermal conductivity, electrical conductivity, Seebeck coefficient, or a combination thereof of the material can be determined at a temperature of from 300 K to 500 K (e.g., from 300 K to 400 K, from 400 K to 500 K, from 300 K to 350 K, from 350 K to 400 K, from 400 K to 450 K, from 450 K to 500 K, from 300 K to 475 K, from 300 K to 450 K, from 300 K to 425 K, from 300 K to 375 K, from 325 K to 500 K, from 350 K to 500 K, from 375 K to 500 K, from 425 K to 500 K, from 325 K to 475 K, or from 350 K to 450 K).

In some examples, the material is exposed to electromagnetic radiation at one or more frequencies of 1 GHz or more (e.g., 1.25 GHz or more, 1.5 GHz or more, 1.75 GHz or more, 2 GHz or more, 2.25 GHz or more, 2.5 GHz or more, 2.75 GHz or more, 3 GHz or more, 3.25 GHz or more, 3.5 GHz or more, 3.75 GHz or more, 4 GHz or more, 4.25 GHz or more, 4.5 GHz or more, or 4.75 GHz or more). In some examples, the material is exposed to electromagnetic radiation at one or more frequencies of 5 GHz or less (e.g., 4.75 GHz or less, 4.5 GHz or less, 4.25 GHz or less, 4 GHz or less, 3.75 GHz or less, 3.5 GHz or less, 3.25 GHz or less, 3 GHz or less, 2.75 GHz or less, 2.5 GHz or less, 2.25 GHz or less, 2 GHz or less, 1.75 GHz or less, 1.5 GHz or less, or 1.25 GHz or less). The one or more frequencies of electromagnetic radiation that the material is exposed to can range from any of the minimum values described above to any of the maximum values described above. For example, the material can be exposed to electromagnetic radiation at one or more frequencies of from 1 GHz to 5 GHz (e.g., from 1 GHz to 3 GHz, from 3 GHz to 5 GHz, from 1 GHz to 2 GHz, from 2 GHz to 3 GHz, from 3 GHz to 4 GHz, from 4 GHz to 5 GHz, from 1 GHz to 4.5 GHz, from 1 GHz to 4 GHz, from 1 GHz to 3.5 GHz, from 1 GHz to 2.5 GHz, from 1.5 GHz to 5 GHz, from 2 GHz to 5 GHz, from 2.5 GHz to 5 GHz, from 3.5 GHz to 5 GHz, from 1.5 GHz to 4.5 GHz, or from 2 GHz to 4 GHz).

In some examples, the material is exposed to electromagnetic radiation for an amount of time of 1 second or more (e.g., 2 seconds or more, 3 seconds or more, 4 seconds or more, 5 seconds or more, 10 seconds or more, 15 seconds or more, 20 seconds or more, 25 seconds or more, 30 seconds or more, 35 seconds or more, 40 seconds or more, 45 seconds or more, 50 seconds or more, 55 seconds or more, 1 minute or more, 1.25 minutes or more, 1.5 minutes or more, 1.75 minutes or more, 2 minutes or more, 2.5 minutes or more, 3 minutes or more, 3.5 minutes or more, 4 minutes or more, 4.5 minutes or more, 5 minutes or more, 6 minutes or more, 7 minutes or more, 8 minutes or more, or 9 minutes or more). In some examples, the material is exposed to electromagnetic radiation for an amount of time of 10 minutes or less (e.g., 9 minutes or less, 8 minutes or less, 7 minutes or less, 6 minutes or less, 5 minutes or less, 4.5 minutes or less, 4 minutes or less, 3.5 minutes or less, 3 minutes or less, 2.5 minutes or less, 2 minutes or less, 1.75 minutes or less, 1.5 minutes or less, 1.25 minutes or less, 1 minute or less, 55 seconds or less, 50 seconds or less, 45 seconds or less, 40 seconds or less, 35 seconds or less, 30 seconds or less, 25 seconds or less, 20 seconds or less, 15 seconds or less, 10 seconds or less, 5 seconds or less, 4 seconds or less, 3 seconds or less, or 2 seconds or less). The amount of time for which the material is exposed to electromagnetic radiation can range from any of the minimum values described above to any of the maximum values described above. For example, the material can be exposed to electromagnetic radiation for an amount of time of from 1 second to 10 minutes (e.g., 1 second to 1 minute, from 1 minute to 10 minutes, from 1 second to 30 seconds, from 30 seconds to 1 minute, from 1 minute to 5 minutes, from 5 minutes to 10 minutes, from 1 second to 9 minutes, from 1 second to 8 minutes, from 1 second to 7 minutes, from 1 second to 6 minutes, from 1 second to 5 minutes, from 1 second to 4 minutes, from 1 second to 3 minutes, from 1 second to 2 minutes, from 5 seconds to 10 minutes, from 10 seconds to 10 minutes, from 15 seconds to 10 minutes from 30 seconds to 10 minutes, from 45 seconds to 10 minutes, from 2 minutes to 10 minutes, from 4 minutes to 10 minutes, from 6 minutes to 10 minutes, from 5 seconds to 9 minutes, or from 10 seconds to 8 minutes).

In some examples, when the material is exposed to electromagnetic radiation at one or more frequencies of from 1 to 5 GHz for an amount of time of from 1 second to 10 minutes, then the material outputs a power of 0.1 μW or more (e.g., 0.25 μW or more, 0.5 μW or more, 0.75 μW or more, 1 μW or more, 1.25 μW or more, 1.5 μW or more, 1.75 μW or more, 2 μW or more, 2.5 μW or more, 3 μW or more, 3.5 μW or more, 4 μW or more, 4.5 μW or more, 5 μW or more, 6 μW or more, 7 μW or more, 8 μW or more, 9 μW or more, 10 μW or more, 15 μW or more, 20 μW or more, 25 μW or more, 30 μW or more, 35 μW or more, 40 μW or more, 45 μW or more, 50 μW or more, 60 μW or more, 70 μW or more, 80 μW or more, 90 μW or more, 100 μW or more, 125 μW or more, 150 μW or more, 175 μW or more, 200 μW or more, 225 μW or more, 250 μW or more, 300 μW or more, 350 μW or more, 400 μW or more, 450 μW or more, 500 μW or more, 600 μW or more, 700 μW or more, 800 μW or more, 900 μW or more, 1 milliWatt (mW) or more, 2 mW or more, 3 mW or more, 4 mW or more, 5 mW or more, 10 mW or more, 15 mW or more, 20 mW or more, 25 mW or more, 30 mW or more, 35 mW or more, 40 mW or more, 45 mW or more, 50 mW or more, 60 mW or more, 70 mW or more, 80 mW or more, 90 mW or more, 100 mW or more, 125 mW or more, 150 mW or more, 175 mW or more, 200 mW or more, 225 mW or more, 250 mW or more, 300 mW or more, 350 mW or more, 400 mW or more, 450 mW or more, 500 mW or more, 600 mW or more, 700 mW or more, 800 mW or more, or 900 mW or more). In some examples, when the material is exposed to electromagnetic radiation at one or more frequencies of from 1 to 5 GHz for an amount of time of from 1 second to 10 minutes, then the material outputs a power of 1 W or less (e.g., 900 mW or less, 800 mW or less, 700 mW or less, 600 mW or less, 500 mW or less, 450 mW or less, 400 mW or less, 350 mW or less, 300 mW or less, 250 mW or less, 225 mW or less, 200 mW or less, 175 mW or less, 150 mW or less, 125 mW or less, 100 mW or less, 90 mW or less, 80 mW or less, 70 mW or less, 60 mW or less, 50 mW or less, 45 mW or less, 40 mW or less, 35 mW or less, 30 mW or less, 25 mW or less, 20 mW or less, 15 mW or less, 10 mW or less, 5 mW or less, 1 mW or less, 900 μW or less, 800 μW or less, 700 μW or less, 600 μW or less, 500 μW or less, 450 μW or less, 400 μW or less, 350 μW or less, 300 μW or less, 250 μW or less, 225 μW or less, 200 μW or less, 175 μW or less, 150 μW or less, 125 μW or less, 100 μW or less, 90 μW or less, 80 μW or less, 70 μW or less, 60 μW or less, 50 μW or less, 45 μW or less, 40 μW or less, 35 μW or less, 30 μW or less, 25 μW or less, 20 μW or less, 15 μW or less, 10 μW or less, 9 μW or less, 8 μW or less, 7 μW or less, 6 μW or less, 5 μW or less, 4.5 μW or less, 4 μW or less, 3.5 μW or less, 3 μW or less, 2.5 μW or less, 2 μW or less, 1.75 μW or less, 1.5 μW or less, 1.25 μW or less, 1 μW or less, 0.75 μW or less, 0.5 μW or less, or 0.25 μW or less). The power output by the material when the material is exposed to electromagnetic radiation at one or more frequencies of from 1 to 5 GHz for an amount of time of from 1 second to 10 minutes can range from any of the minimum values described above to any of the maximum values described above. For example, when the material is exposed to electromagnetic radiation at one or more frequencies of from 1 to 5 GHz for an amount of time of from 1 second to 10 minutes, then the material can output a power of from 0.1 μW to 1 μW (e.g., from 0.1 μW to 1 mW, from 1 mW to 1 μW, from 0.1 μW to 1 μW, from 1 μW to 10 μW, from 10 μW to 100 μW, from 100 μW to 1 mW, from 1 mW to 10 mW, from 10 mW to 100 mW, from 100 mW to 1 μW, from 0.5 μW to 1 μW, from 1 μW to 1 μW, from 10 μW to 1 μW, from 100 μW to 1 μW, from 1 mW to 1 μW, from 10 mW to 1 μW, or from 100 mW to 1 μW). In some examples, when the material is exposed to electromagnetic radiation at one or more frequencies of from 1 to 5 GHz for an amount of time of from 1 second to 10 minutes, then the material can output a power of from 0.1 W to 1 μW.

In some examples, when the material is exposed to electromagnetic radiation at one or more frequencies of from 1 to 5 GHz for an amount of time of from 1 second to 10 minutes, then the material can output a power of from 0.1 μW to 10 μW (e.g., from 0.1 μW to 5 μW, from 5 μW to 10 μW, from 0.1 μW to 2 μW, from 2 μW to 4 μW, from 4 μW to 6 μW, from 6 μW to 8 μW, from 8 μW to 10 μW, from 0.1 μW to 8 μW, from 0.1 μW to 6 μW, from 0.1 μW to 4 μW, from 0.25 μW to 10 μW, from 0.5 μW to 10 μW, from 0.75 μW to 10 μW, from 1 μW to 10 μW, from 2 μW to 10 μW, from 4 μW to 10 μW, from 6 μW to 10 μW, from 0.25 μW to 9 μW, from 0.5 μW to 8 μW).

In some examples, when the material is exposed to electromagnetic radiation at one or more frequencies of from 1 to 5 GHz for an amount of time of from 1 second to 10 minutes, then the material outputs a power density of 10 W/m³ or more (e.g., 15 W/m³ or more, 20 W/m³ or more, 25 W/m³ or more, 30 W/m³ or more, 35 W/m³ or more, 40 W/m³ or more, 45 W/m³ or more, 50 W/m³ or more, 60 W/m³ or more, 70 W/m³ or more, 80 W/m³ or more, 90 W/m³ or more, 100 W/m³ or more, 125 W/m³ or more, 150 W/m³ or more, 175 W/m³ or more, 200 W/m³ or more, 225 W/m³ or more, 250 W/m³ or more, 300 W/m³ or more, 350 W/m³ or more, 400 W/m³ or more, 450 W/m³ or more, 500 W/m³ or more, 600 W/m³ or more, 700 W/m³ or more, 800 W/m³ or more, 900 W/m³ or more, 1×10³ W/m³ or more, 1.5×10³ W/m³ or more, 2×10³ W/m³ or more, 2.5×10³ W/m³ or more, 3×10³ W/m³ or more, 3.5×10³ W/m³ or more, 4×10³ W/m³ or more, 4.5×10³ W/m³ or more, 5×10³ W/m³ or more, 6×10³ W/m³ or more, 7×10³ W/m³ or more, 8×10³ W/m³ or more, 9×10³ W/m³ or more, 1×10⁴ W/m³ or more, 1.5×10⁴ W/m³ or more, 2×10⁴ W/m³ or more, 2.5×10⁴ W/m³ or more, 3×10⁴ W/m³ or more, 3.5×10⁴ W/m³ or more, 4×10⁴ W/m³ or more, 4.5×10⁴ W/m³ or more, 5×10⁴ W/m³ or more, 6×10⁴ W/m³ or more, 7×10⁴ W/m³ or more, 8×10⁴ W/m³ or more, 9×10⁴ W/m³ or more, 1×10⁵ W/m³ or more, 1.5×10⁵ W/m³ or more, 2×10³ W/m³ or more, 2.5×10⁵ W/m³ or more, 3×10⁵ W/m³ or more, 3.5×10⁵ W/m³ or more, 4×10⁵ W/m³ or more, 4.5×10⁵ W/m³ or more, 5×10⁵ W/m³ or more, 6×10⁵ W/m³ or more, 7×10′ W/m³ or more, 8×10⁵ W/m³ or more, or 9×10⁵ W/m³ or more). In some examples, when the material is exposed to electromagnetic radiation at one or more frequencies of from 1 to 5 GHz for an amount of time of from 1 second to 10 minutes, then the material outputs a power density of 1×10⁶ W/m³ or less (e.g., 9×10⁵ W/m³ or less, 8×10⁵ W/m³ or less, 7×10⁵ W/m³ or less, 6×10⁵ W/m³ or less, 5×10⁵ W/m³ or less, 4.5×10⁵ W/m³ or less, 4×10⁵ W/m³ or less, 3.5×10⁵ W/m³ or less, 3×10, W/m³ or less, 2.5×10⁵ W/m³ or less, 2-10⁵ W/m³ or less, 1.5×10⁵ W/m³ or less, 1×10⁵ W/m³ or less, 9×10⁴ W/m³ or less, 8-10⁴ W/m³ or less, 7×10⁴ W/m³ or less, 6×10⁴ W/m³ or less, 5×10⁴ W/m³ or less, 4.5×10⁴ W/m³ or less, 4×10⁴ W/m³ or less, 3.5×10⁴ W/m³ or less, 3×10⁴ W/m³ or less, 2.5×10⁴ W/m³ or less, 2×10⁴ W/m³ or less, 1.5×10⁴ W/m³ or less, 1×10⁴ W/m³ or less, 9×10³ W/m³ or less, 8-10³ W/m³ or less, 7-10³ W/m³ or less, 6-10³ W/m³ or less, 5-10³ W/m³ or less, 4.5-10³ W/m³ or less, 4-10³ W/m³ or less, 3.5×10³ W/m³ or less, 3×10³ W/m³ or less, 2.5×10³ W/m³ or less, 2×10³ W/m³ or less, 1.5×10³ W/m³ or less, 1×10³ W/m³ or less, 900 W/m³ or less, 800 W/m³ or less, 700 W/m³ or less, 600 W/m³ or less, 500 W/m³ or less, 450 W/m³ or less, 400 W/m³ or less, 350 W/m³ or less, 300 W/m³ or less, 250 W/m³ or less, 225 W/m³ or less, 200 W/m³ or less, 175 W/m³ or less, 150 W/m³ or less, 125 W/m³ or less, 100 W/m³ or less, 90 W/m³ or less, 80 W/m³ or less, 70 W/m³ or less, 60 W/m³ or less, 50 W/m³ or less, 45 W/m³ or less, 40 W/m³ or less, 35 W/m³ or less, 30 W/m³ or less, 25 W/m³ or less, 20 W/m³ or less, or 15 W/m³ or less). The power density output by the material when the material is exposed to electromagnetic radiation at one or more frequencies of from 1 to 5 GHz for an amount of time of from 1 second to 10 minutes can range from any of the minimum values described above to any of the maximum values described above. For example, when the material is exposed to electromagnetic radiation at one or more frequencies of from 1 to 5 GHz for an amount of time of from 1 second to 10 minutes, then the material outputs a power density of from 10 W/m³ to 1×10⁶ W/m³ (e.g., from 10 W/m³ to 1×10⁵ W/m³, from 1×10³ to 1×10⁶ W/m³, from 10 W/m³ to 100 W/m³, from 100 W/m³ to 1×10³ W/m³, from 1×10⁵ to 1×10⁴ W/m³, from 1×10⁴ to 1×10⁵ W/m³, from 1×10⁶ to 1×10⁶ W/m³, from 10⁶ W/m³ to 1×10⁶ W/m³, from 1×10³ to 1×10⁶ W/m³, or from 1×10⁴ to 1×10⁶ W/m³).

In some examples, when the material is exposed to electromagnetic radiation at one or more frequencies of from 1 to 5 GHz for an amount of time of from 1 second to 10 minutes, then the material outputs a power density of from 10 to 500 W/m³ (e.g., from 10 W/m³ to 250 W/m³, from 250 W/m³ to 500 W/m³, from 10 W/m³ to 100 W/m³, from 100 W/m³ to 200 W/m³, from 200 W/m³ to 300 W/m³, from 300 W/m³ to 400 W/m³, from 400 W/m³ to 500 W/m³, from 10 W/m³ to 450 W/m³, from 10 W/m³ to 400 W/m³, from 10 W/m³ to 300 W/m³, from 10 W/m³ to 200 W/m³, from 25 W/m³ to 500 W/m³, from 50 W/m³ to 500 W/m³, from 100 W/m³ to 500 W/m³, from W/m³ 200 W/m³ to 500 W/m³, from 300 W/m³ to 500 W/m³, from 25 W/m³ to 450 W/m³, from 50 W/m³ to 400 W/m³).

In some examples, when the material is exposed to electromagnetic radiation at one or more frequencies of from 1 to 5 GHz for an amount of time of from 1 second to 10 minutes, then the material generates a temperature increase of 10 °C or more (e.g., 15 °C or more, 20 °C or more, 25 °C or more, 30 °C or more, 35 °C or more, 40 °C or more, 45 °C or more, 50 °C or more, 60 °C or more, 70 °C or more, 80 °C or more, 90 °C or more, 100 °C or more, 125 °C or more, 150 °C or more, or 175 °C or more). In some examples, when the material is exposed to electromagnetic radiation at one or more frequencies of from 1 to 5 GHz for an amount of time of from 1 second to 10 minutes, then the material generates a temperature increase of 200 °C or less (e.g., 175 °C or less, 150 °C or less, 125 °C or less, 100 °C or less, 90 °C or less, 80 °C or less, 70 °C or less, 60 °C or less, 50 °C or less, 45 °C or less, 40 °C or less, 35 °C or less, 30 °C or less, 25 °C or less, 20 °C or less, or 15 °C or less). The temperature increase generated by the material when the material is exposed to electromagnetic radiation at one or more frequencies of from 1 to 5 GHz for an amount of time of from 1 second to 10 minutes can range from any of the minimum values described above to any of the maximum values described above. For example, the material is exposed to electromagnetic radiation at one or more frequencies of from 1 to 5 GHz for an amount of time of from 1 second to 10 minutes, then the material can generate a temperature increase of from 10 °C to 200 °C (e.g., from 10 °C to 100 °C, from 100 °C to 200 °C, from 10 °C to 40 °C, from 40 °C to 80 °C, from 80 °C to 120 °C, from 120 °C to 160 °C, from 160 °C to 200 °C, from 10 °C to 175 °C, from 10 °C to 150 °C, from 10 °C to 75 °C, from 15 °C to 200 °C, from 20 °C to 200 °C, from 25 °C to 200 °C, from 40 °C to 200 °C, from 50 °C to 200 °C, from 60 °C to 200 °C, from 75 °C to 200 °C, from 120 °C to 200 °C, from 15 °C to 175 °C, or from 25 °C to 150 °C).

In some examples, the material is flexible, low cost, lightweight, or a combination thereof.

### Methods of Making

Also disclosed herein are methods of making any of the materials disclosed herein.

For example, also disclosed herein are methods of making any of the porous materials disclosed herein. The methods can, for example, comprise depositing a plurality of particles on the two-dimensional material layer, thereby forming an initial material. Depositing the plurality of particles can, for example, comprise thermal oxidation, electroplating, lithographic deposition, electron beam deposition, thermal deposition, spin coating, drop-casting, zone casting, dip coating, blade coating, spraying, vacuum filtration, chemical vapor deposition (CVD), atomic layer deposition (ALD), physical vapor deposition (PVD), sputtering, pulsed layer deposition, molecular beam epitaxy, evaporation, or combinations thereof.

The plurality of particles can comprise any suitable material. For example, the plurality of particles can comprise a metal oxide. In some examples, the plurality of particles comprise Fe₃O₄, ZnO, CuO, or a combination thereof. In some examples, the plurality of particles comprise Fe₃O₄.

The plurality of particles can have an average particle size. “Average particle size” and “mean particle size” are used interchangeably herein, and generally refer to the statistical mean particle size of the particles in a population of particles. For example, the average particle size for a plurality of particles with a substantially spherical shape can comprise the average diameter of the plurality of particles. As used herein, the size of a particle can refer to the largest linear distance between two points on the surface of the particle. For an anisotropic particle, the average particle size can refer to, for example, the average maximum dimension of the particle (e.g., the length of a rod shaped particle, the diagonal of a cube shape particle, the bisector of a triangular shaped particle, etc.). Mean particle size can be measured using methods known in the art, such as evaluation by electron microscopy.

In some examples, the plurality of particles have an average particle size of 0.5 nanometers (nm) or more (e.g., 0.75 nm or more, 1 nm or more, 1.25 nm or more, 1.5 nm or more, 1.75 nm or more, 2 nm or more, 2.25 nm or more, 2.5 nm or more, 3 nm or more, 3.5 nm or more, 4 nm or more, 4.5 nm or more, 5 nm or more, 6 nm or more, 7 nm or more, 8 nm or more, 9 nm or more, 10 nm or more, 11 nm or more, 12 nm or more, 13 nm or more, 14 nm or more, 15 nm or more, 16 nm or more, 17 nm or more, 18 nm or more, 19 nm or more, 20 nm or more, 21 nm or more, 22 nm or more, 23 nm or more, or 24 nm or more). In some examples, the plurality of particles can have an average particle size of 25 nm or less (e.g., 24 nm or less, 23 nm or less, 22 nm or less, 21 nm or less, 20 nm or less, 19 nm or less, 18 nm or less, 17 nm or less, 16 nm or less, 15 nm or less, 14 nm or less, 13 nm or less, 12 nm or less, 11 nm or less, 10 nm or less, 9 nm or less, 8 nm or less, 7 nm or less, 6 nm or less, 5 nm or less, 4.5 nm or less, 4 nm or less, 3.5 nm or less, 3 nm or less, 2.5 nm or less, 2.25 nm or less, 2 nm or less, 1.75 nm or less, 1.5 nm or less, 1.25 nm or less, 1 nm or less, or 0.75 nm or less). The average particle size can range from any of the minimum values described above to any of the maximum values described above. For example, the plurality of particles can have an average particle size of from 0.5 nanometers (nm) to 25 nm (e.g., from 0.5 nm to 12 nm, from 12 nm to 25 nm, from 0.5 nm to 5 nm, from 5 nm to 10 nm, from 10 nm to 15 nm, from 15 nm to 20 nm, from 20 nm to 25 nm, from 0.5 nm to 20 nm, from 0.5 nm to 15 nm, from 0.5 nm to 10 nm, from 1 nm to 25 nm, from 5 nm to 25 nm, from 10 nm to 25 nm, from 15 nm to 25 nm, from 1 nm to 20 nm, or from 1 nm to 10 nm).

In some examples, the plurality of particles can be substantially monodisperse. “Monodisperse” and “homogeneous size distribution,” as used herein, and generally describe a population of particles where all of the particles have the same or nearly the same particle size.

As used herein, a monodisperse distribution refers to distributions in which 80% of the distribution (e.g., 85% of the distribution, 90% of the distribution, or 95% of the distribution) lies within 25% of the mean particle size (e.g., within 20% of the mean particle size, within 15% of the mean particle size, within 10% of the mean particle size, or within 5% of the mean particle size).

The plurality of particles can, independently, be of any shape, such as a regular shape, an irregular shape, an isotropic shape, or an anisotropic shape (e.g., a sphere, a rod, a quadrilateral, an ellipse, a triangle, a polygon, etc.). In some examples, the plurality of particles can have an isotropic shape. In some examples, the plurality of particles can have an anisotropic shape. In some examples, the plurality of particles can have a shape that is spherical, tetrahedral, cubic, hexagonal, or irregular.

The methods further comprise annealing the initial material to form an intermediate material.

In some examples, the initial material is annealed at a temperature of 500 °C or more (e.g., 550 °C or more, 600 °C or more, 650 °C or more, 700 °C or more, 750 °C or more, 800 °C or more, 850 °C or more, 900 °C or more, 950 °C or more, 1000 °C or more, 1100 °C or more, 1200 °C or more, 1300 °C or more, 1400 °C or more, 1500 °C or more, 1600 °C or more, 1700 °C or more, 1800 °C or more, or 1900 °C or more). In some examples, the initial material is annealed at a temperature of 2000 °C or less (e.g., 1900 °C or less, 1800 °C or less, 1700 °C or less, 1600 °C or less, 1500 °C or less, 1400 °C or less, 1300 °C or less, 1200 °C or less, 1100 °C or less, 1000 °C or less, 950 °C or less, 900 °C or less, 850 °C or less, 800 °C or less, 750 °C or less, 700 °C or less, 650 °C or less, 600 °C or less, or 550 °C or less). The temperature at which the initial material is annealed can range from any of the minimum values described above to any of the maximum values described above. For example, the initial material can be annealed at a temperature of from 500 °C to 2000 °C (e.g., from 500 °C to 1250 °C, from 1250 °C to 2000 °C, from 500 °C to 1000 °C, from 1000 °C to 1500 °C, from 1500 °C to 2000 °C, from 600 °C to 2000 °C, from 750 °C to 2000 °C, from 1000 °C to 2000 °C, from 500 °C to 1750 °C, from 500 °C to 1500 °C, from 500 °C to 1000 °C, from 500 °C to 750 °C, from 550 °C to 1950 °C, or from 600 °C to 1200 °C).

In some examples, the initial material is annealed for an amount of time of 10 minutes or more (e.g., 15 minutes or more, 30 minutes or more, 45 minutes or more, 1 hour or more, 1.5 hours or more, 2 hours or more, 2.5 hours or more, 3 hours or more, 3.5 hours or more, 4 hours or more, 4.5 hours or more, 5 hours or more, 5.5 hours or more, 6 hours or more, 7 hours or more, 8 hours or more, 9 hours or more, 10 hours or more, 11 hours or more, 12 hours or more, 14 hours or more, 16 hours or more, 18 hours or more, 20 hours or more, 22 hours or more, 24 hours or more, 30 hours or more, 36 hours or more, 42 hours or more, 48 hours or more, 54 hours or more, 60 hours or more, or 66 hours or more). In some examples. The initial material is annealed for an amount of time to 72 hours or less (e.g., 66 hours or less, 60 hours or less, 54 hours or less, 48 hours or less, 42 hours or less, 36 hours or less, 30 hours or less, 24 hours or less, 22 hours or less, 20 hours or less, 18 hours or less, 16 hours or less, 14 hours or less, 12 hours or less, 11 hours or less, 10 hours or less, 9 hours or less, 8 hours or less, 7 hours or less, 6 hours or less, 5.5 hours or less, 5 hours or less, 4.5 hours or less, 4 hours or less, 3.5 hours or less, 3 hours or less, 2.5 hours or less, 2 hours or less, 1.5 hours or less, 1 hour or less, 45 minutes or less, 30 minutes or less, or 15 minutes or less). The amount of time for which the initial material is annealed can range from any of the minimum values described above to any of the maximum values described above. For example, the initial material can be annealed for an amount of time of from 10 minutes to 72 hours (e.g., from 10 minutes to 36 hours, from 36 hours to 72 hours, from 10 minutes to 12 hours, from 12 hours to 24 hours, from 24 hours to 36 hours, from 36 hours to 48 hours, from 48 hours to 60 hours, from 60 hours to 72 hours, from 10 minutes to 60 hours, from 10 minutes to 48 hours, from 10 minutes to 24 hours, from 10 minutes to 6 hours, from 10 minutes to 4 hours, from 10 minutes to 2 hours, from 15 minutes to 72 hours, from 30 minutes to 72 hours, from 1 hour to 72 hours, from 2 hours to 72 hours, from 4 hours to 72 hours, from 6 hours to 72 hours, from 12 hours to 72 hours, from 24 hours to 72 hours, from 48 hours to 72 hours, from 15 minutes to 66 hours, or from 30 minutes to 60 hours).

The methods further comprise removing the plurality of particles from the intermediate material, thereby forming the material. Removing the plurality of particles can, for example, comprise etching, such as chemical etching. In some examples, removing the plurality of particles comprises exposing the plurality of particles to an etchant, such as an acid (e.g., hydrochloric acid, sulfuric acid, nitric acid, etc.).

In some examples, the methods can further comprise doping the material, e.g. by incorporating a dopant. Examples of dopants include, but are not limited to, C, H, B, N, O, P, S, Se, Te, and combinations thereof. In some examples, doping the material can comprise annealing in the presence of the dopant. In some examples the temperature at which the doping occurs can be selected to control the location of the dopant within the material, for example the temperature can be selected such that the dopant is located around the perimeter of the pores.

### Methods of Use and Articles of Manufacture

Also provided herein are methods of use of the materials described herein. The materials described herein can, for example, be used to convert electromagnetic radiation to electricity.

For examples, also disclosed herein are methods for converting electromagnetic radiation directly into electricity, the method comprising exposing any of the materials disclosed herein to electromagnetic radiation, such that the material absorbs at least a portion of the electromagnetic radiation, converts the absorbed electromagnetic radiation into thermal energy, and subsequently converts the thermal energy into electric energy via a thermoelectric effect. In some examples, the electromagnetic radiation absorbed by the material can comprise one or more frequencies of from 2-5 GHz.

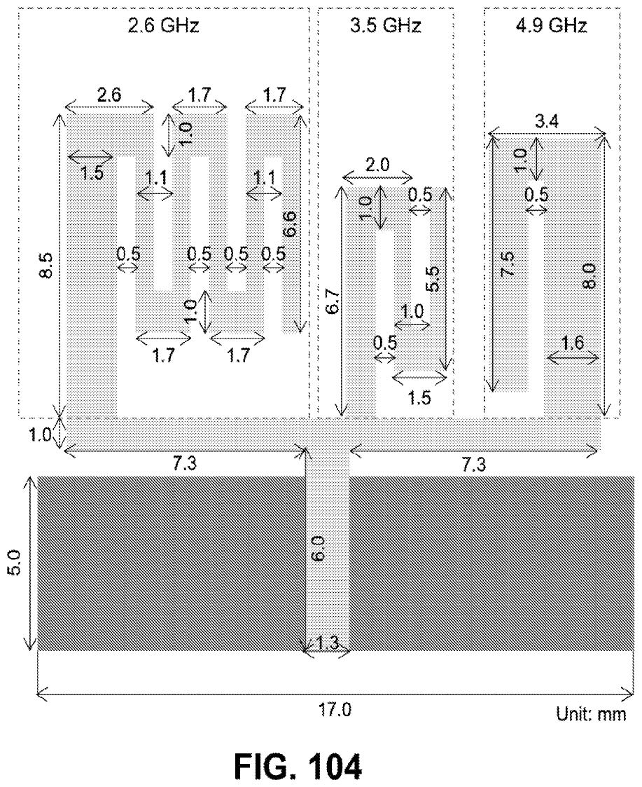

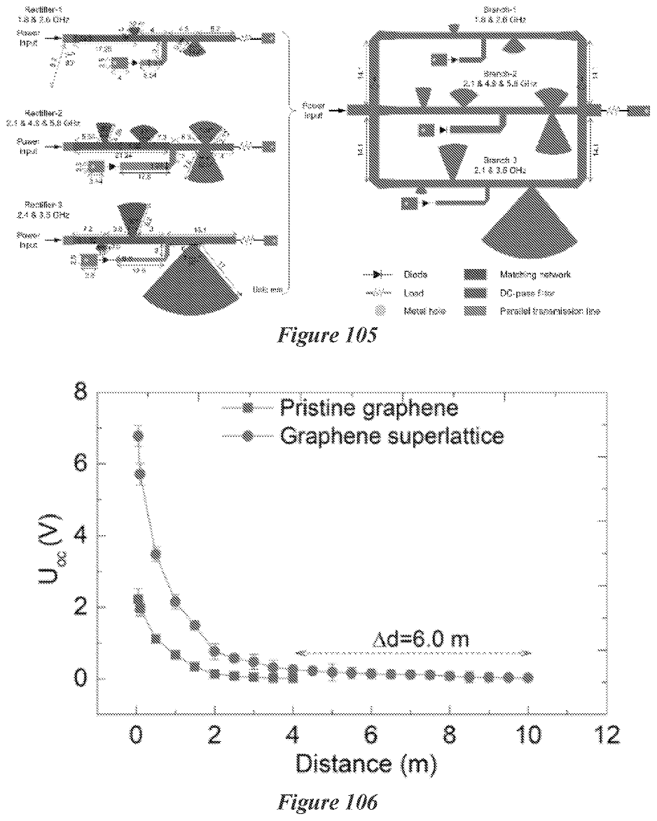

Also disclosed herein are devices and articles of manufacture comprising any of the materials disclosed herein. The materials can be used in various devices articles of manufacture, such as, for example, electronic devices, energy conversion devices, optical devices, optoelectronic devices, or combination thereof. In some examples, the device is a wearable electronic device. In some examples, the materials can be used as a power supply said devices or articles of manufacture. Such devices and articles of manufacture can be fabricated by methods known in the art. In some examples, the device or article of manufacture can comprise a device as shown in FIG. 104-FIG. 105.

A number of embodiments of the invention have been described. Nevertheless, it will be understood that various modifications may be made without departing from the spirit and scope of the invention. Accordingly, other embodiments are within the scope of the following claims.

The examples below are intended to further illustrate certain aspects of the systems and methods described herein, and are not intended to limit the scope of the claims.

### EXAMPLES

The following examples are set forth below to illustrate the methods and results according to the disclosed subject matter. These examples are not intended to be inclusive of all aspects of the subject matter disclosed herein, but rather to illustrate representative methods and results. These examples are not intended to exclude equivalents and variations of the present invention which are apparent to one skilled in the art.

Efforts have been made to ensure accuracy with respect to numbers (e.g., amounts, temperature, etc.) but some errors and deviations should be accounted for. Unless indicated otherwise, parts are parts by weight, temperature is in °C or is at ambient temperature, and pressure is at or near atmospheric. There are numerous variations and combinations of measurement conditions, e.g., component concentrations, temperatures, pressures and other measurement ranges and conditions that can be used to optimize the described process.

### Example 1—Graphene with Staggered, Ordered Nanometer-Sized Pores Converts Electromagnetic Waves to Electricity

Abstract. Harvesting largely ignored and wasted electromagnetic (EM) energy released by electronic devices and converting it into direct current (DC) electricity is an attractive strategy to not only reduce EM pollution but also address the ever-increasing energy crisis. Herein, a nanoparticle-templated graphene with monodisperse and staggered nanopores is reported that enables an EM-heat-DC conversion pathway. It is experimentally and theoretically demonstrates that this staggered nanoporous structure alters graphene's electronic and phonon structure by synergistically manipulating its intralayer nanostructures and interlayer interactions. An unprecedented and usually conflicting combination of properties was observed in the staggered nanoporous graphene, including high permittivity, low thermal conductivity, and enhanced Seebeck effect, which leads to efficient absorption and conversion of EM waves into heat and the output of DC through the thermoelectric effect. Overall, these results advance the fundamental understanding of the structure-property relationships of ordered nanoporous graphene and provide a new paradigm to reduce EM pollution and generate electric energy.

Introduction. The recent breakthrough in information and communication technology (e.g., 3G-5G) has led to an astronomical rise in electronic device usage and the release of particularly low-frequency electromagnetic (EM) waves ranging from 2 to 5 GHz (L- and C-band) into the surrounding environment (Iqbal, A. et. al. Science 369, 446-450 (2020); Lipton, J. et. al. Matter 3, 546-557 (2020)). However, only 20-30% of EM waves (e.g., produced by base stations, wireless routers and electronic devices) are utilized in telecommunications (Ma, Z. L. et al. Angew. Chem. Int. Ed. 15, e202200705 (2022); Yun, T. et al. Adv. Mater. 32, 2070064 (2020)). The rest are largely ignored and wasted, causing high EM pollution to the surrounding environment and leading to health concerns, signal interference in device-to-device communications, and heat generation in electronic devices (known as overheating) (Wu, Z. C. et al. Adv. Mater. 34, 2107538 (2022); Liu, L. Y. et al. Proc. Natl. Acad. Sci. USA. 118, e2105838118 (2021)). Therefore, harvesting the freely available EM radiation and converting it into usable direct current (DC) electricity is an attractive strategy to not only reduce EM pollution but also address the ever-increasing energy crisis. To date, no single-component material system can convert EM waves to DC electricity because of contradictory material requirements (Su, L. Z. et al. Science 375, 1385-1389 (2022); Peng, X. et al. Sci. Adv. 6, eabba9624 (2020); Hong, H. X. et al. Energy Environ. Sci. 15, 621-632 (2022)). For example, EM absorbing and shielding materials require a high permittivity, which is usually associated with a high thermal conductivity, while thermoelectric materials require a low thermal conductivity and fail to absorb EM radiation (Wan, S. J. et al. Nat. Mater. 20, 624 (2021); Han, M. K. et al. AC'S Nano 14, 5008 (2020)). To overcome this challenge, it was sought to design a single-component material system that enables EM-heat-DC conversion: (i) efficiently absorbing and converting low-frequency EM waves into heat, creating an associated temperature gradient, and (ii) outputting DC electricity via the Seebeck effect.

Graphene, with its characteristic high permittivity, has been demonstrated to possess remarkable EM dissipation abilities (e.g., converting EM into heat) (Park, J. M. et al. Nature 590, 249-255 (2021); Wu, S et. al. Nat. Mater. 20, 488-494 (2021)). However, the intrinsically high thermal conductivity, low Seebeck coefficient, and zero bandgap structure prevent heat-DC conversion (Sierra, J. F. et al. Nat. Nanotechnol. 13, 107-111 (2018); Li, T. et al. Nat. Energy 3, 148-156 (2018)). Element doping and the creation of graphene nanostructures (e.g., nanoribbons) have been widely used to alter graphene's electronic and phonon structure by covalently tuning the intralayer atomic bonding (Wang, H. M. et al. Nat. Rev. Phys. 3, 791-802 (2021); Chen, C. X. et al. Nat. Electron. 4, 653-663 (2021); Lin, L. et al., Nat. Mater. 18, 520 (2019)). While not fully understood yet, recent research has shown that the manipulation of interlayer interactions between different graphene layers (e.g., van der Waals force) by stacking two sheets of graphene that are twisted by a small angle (known as the magic angle of graphene superlattices) enables new graphene material properties and function (Gadelha, A. C. et al. Nature 590, 405-409 (2021); Qin, W. et al. Phys. Rev. Let. 127, 097001 (2021)). In order to achieve the above goal, it was sought to tune the electronic and phonon structure of graphene via a combination of both intralayer and interlayer strategies—the creation of ordered nanopores on graphene surfaces (intralayer effect) and the formation of partially overlapped nanopores on different graphene layers (namely a staggered porous structure; interlayer effect reveals similarity to magic angle graphene superlattices). Current methods for creating ordered porous graphene, such as electron beams, can only achieve micrometer-sized, completely overlapped pores, which usually display a limited density of carbon atoms located at the pore edges and thus a weak intralayer effect (Mukherjee, R. et al. Nat. Commun. 5, 3710 (2014); Han, J. H. et al. Adv. Mater. 34, 2108750 (2021); Allen, M. J. et al Chem. Rev. 110, 132 (2010)). However, the synthesis of monodisperse, nanometer-sized pores (<10 nm) with a staggered porous structure across different graphene layers remains challenging.

This work reports a method to create monodisperse, nanometer-sized pores with well-controlled pore sizes and shapes on graphene templated by transition metal oxide nanoparticles formed in-situ. In graphene with more than one layer, the nanopores on different graphene layers partially overlap with each other, resulting in the desired staggered nanoporous structure. It was found that the formed non-graphitized carbons at the edge of the graphene nanopores serve as dipoles to improve the EM-heat conversion through dipole relaxation polarization at relatively low EM frequencies (i.e., 2-5 GHz). Furthermore, the pore edges promote phonon scattering to reduce the thermal conductivity of the graphene and confine the electron transport through splitting the Dirac point and breaking up the Fermi energy surfaces, which significantly enhance the Seebeck effect of graphene. As a result, the synergy of the high permittivity, the reduced thermal conductivity and the enhanced Seebeck coefficient make this class of staggered, ordered nanoporous graphene a promising material to achieve the proposed EM-heat-DC conversion.

### Results and Discussion

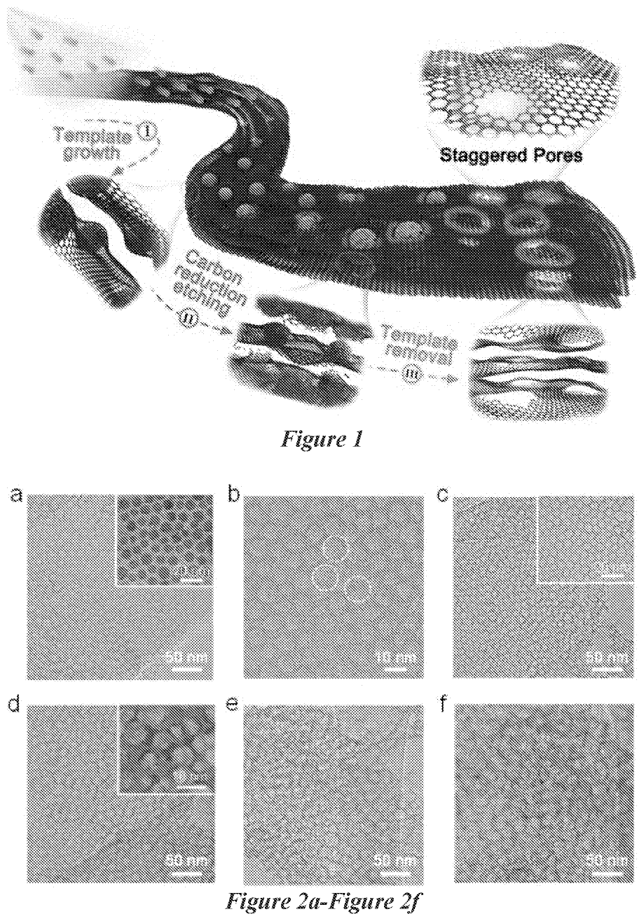

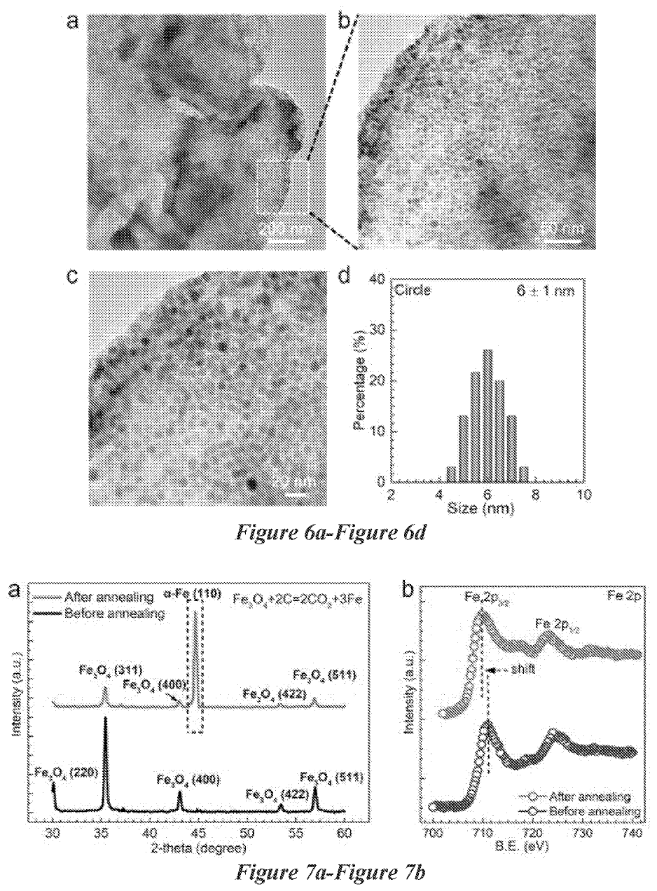

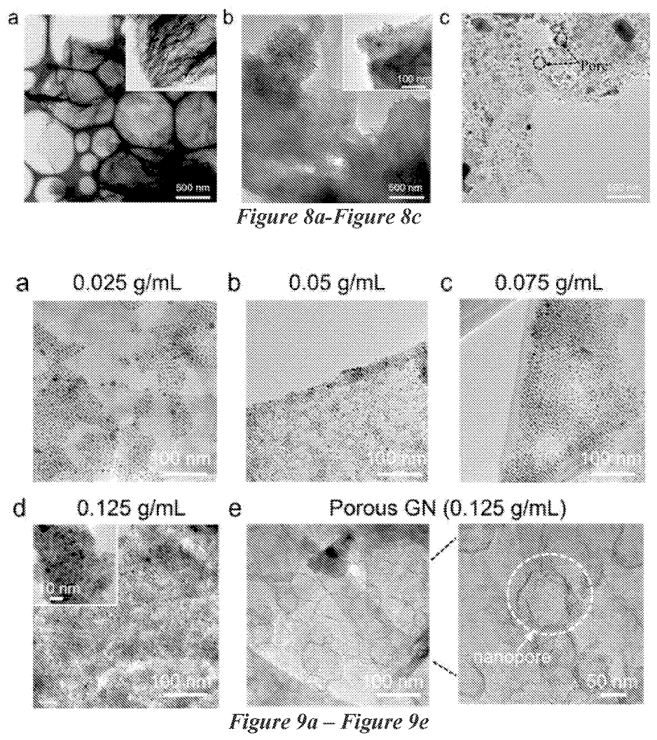

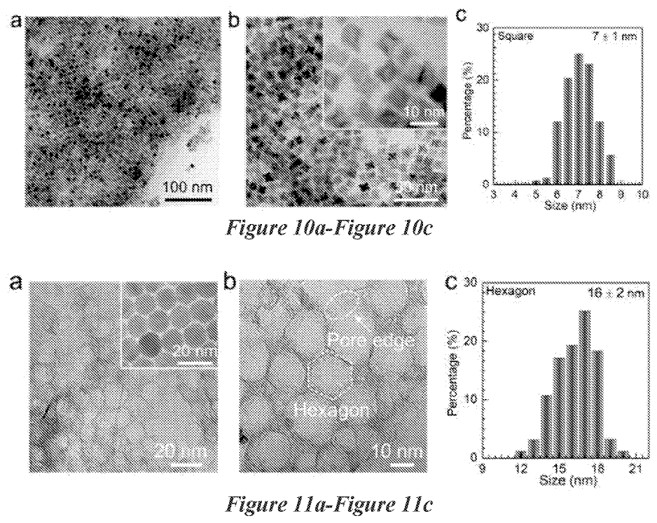

Synthesis and structural characterization of staggered, ordered nanoporous graphene. To achieve the desired electronic structure for DC generation from EM waves, it was sought to create monodisperse, nanometer-sized pores on graphene surfaces using nanoparticles as templates, as shown in FIG. 1. First, monodisperse iron (II, III) oxide (Fe₃O₄) nanoparticles were grown in-situ on the surface of the graphene nanosheets via a thermal decomposition process. Fe₃O₄ nanoparticles oxidized the underlying graphene during the subsequent annealing treatment to locally generate nanopores. Finally, the remaining Fe₃O₄ nanoparticles were removed using hydrochloric acid, revealing these monodisperse nanometer-sized pores on the graphene surface as shown in the representative transmission electron microscopy (TEM) images in FIG. 2a-FIG. 2b and FIG. 6. The phase evolution of the oxidation process is verified using X-ray photoelectron spectroscopy (XPS) and X-ray diffraction (XRD), as shown in FIG. 7. It is noted here that both a flat graphene surface and a proper surface coverage of Fe₃O₄ nanoparticles create the monodisperse nanopores on the graphene. Distorted circular pores with polydisperse size distributions were observed on either a wrinkled surface or a flat surface coated with excess Fe₃O₄ nanoparticles, as shown in FIG. 8-FIG. 9. In addition, square and hexagonal nanopores can be created on graphene using cubic and hexagonal Fe₃O₄ nanoparticles, respectively (FIG. 2c and FIG. 10-FIG. 11).

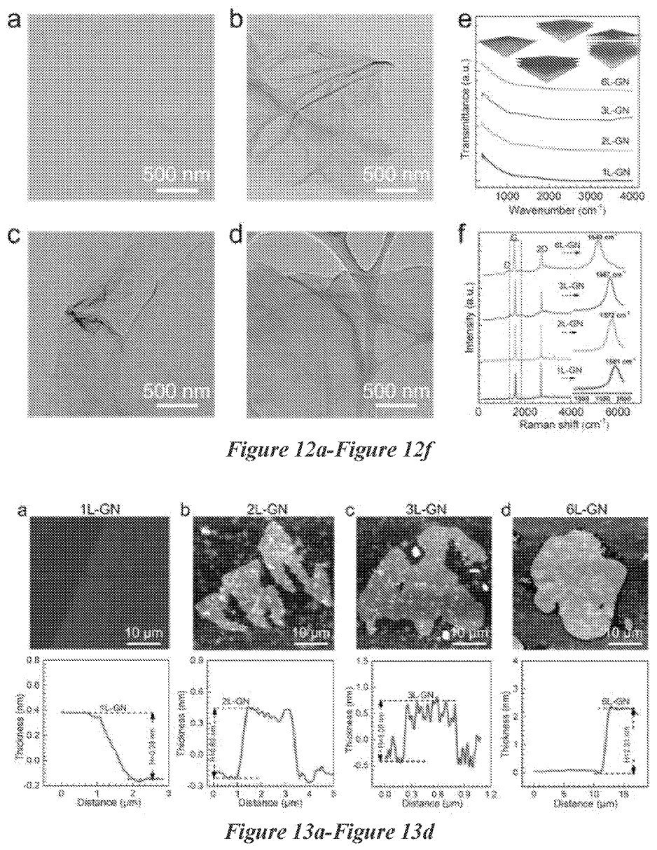

Besides tuning the shape and size of nanopores on graphene, nanopores were created on graphene having more than one layer. Representative TEM images showed bilayer, trilayer, and multilayer (six layers on average; see FIG. 12-FIG. 13 and Note Si) graphene with circular nanopores. In particular, the Fe₃O₄ nanoparticles initially grown on the outer layers of the graphene successively etched carbon atoms from the outer layers to the inner layers, which can combine with particle-induced local distortions and the interlayer slipping of graphene to cause a partial overlapping of nanopores on different graphene layers (namely staggered pore structures), as evidenced in FIG. 2d-FIG. 2f and the inset in FIG. 2d. These experimental results demonstrate the ability to generate staggered homogeneous nanoporous graphene with controllable pore sizes, shapes, and layer numbers.

Electromagnetic wave dissipation by staggered, ordered nanoporous graphene. For efficient DC electricity generation from EM waves released from 3G-5G electronics, efficient absorption and conversion of EM energy into thermal energy at low EM frequencies (typically 2-5 GHz; Table 1) is required, which is quantified by the EM dissipation factor (η).

TABLE 1
Representative EM frequency ranges for
3G, 4G, and 5G wireless technology.

| | 3G | 4G | 5G |
|---|---|---|---|
| Band | (GHz) | (GHz) | (GHz) |
| 1 | 1.71-1.78 | 1.88-1.90 | 3.30-3.40 |
| 2 | 1.88-1.90 | 2.32-2.37 | 3.40-3.60 |
| 3 | 2.01-2.02 | 2.57-2.63 | 4.80-5.00 |

The heat (W) generated by the EM dissipation can be calculated as (Yun, T. et al. Adv. Mater. 32, 1906769 (2020)):

W=D·E²·f·η (1)

where D is a coefficient associated with the volume of EM dissipation materials, and E and f represent the power and frequency of the applied EM wave, respectively, can be written as (Wang, X. X. et al. Adv. Mater. 32, 2002112 (2020)):

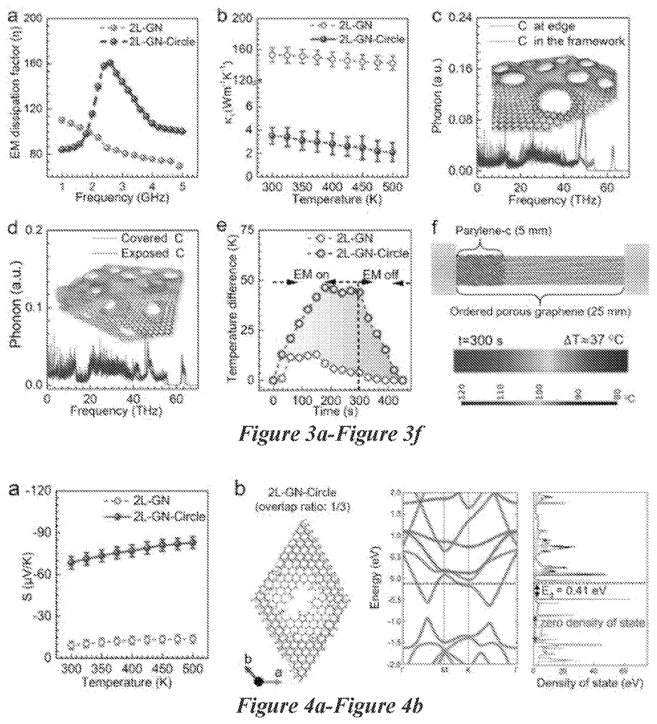

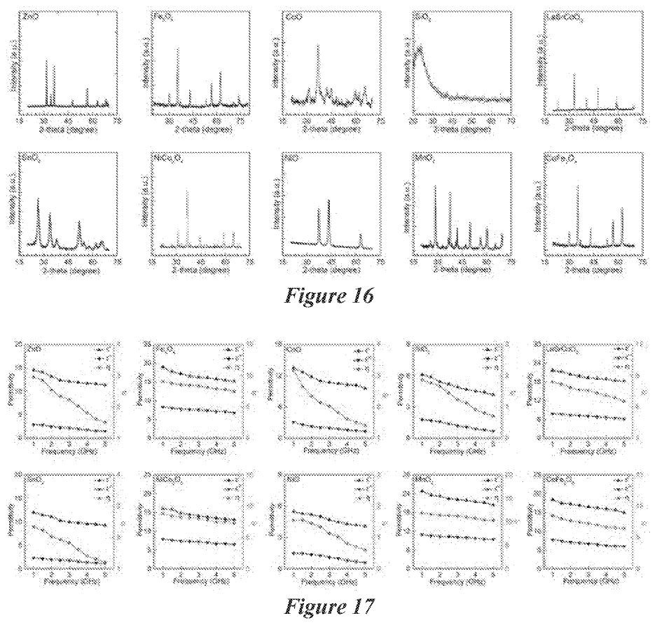

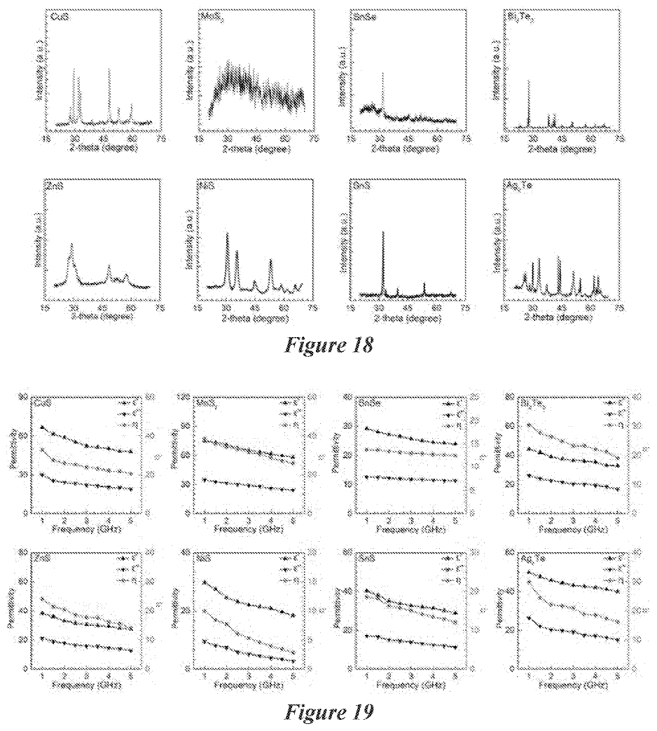

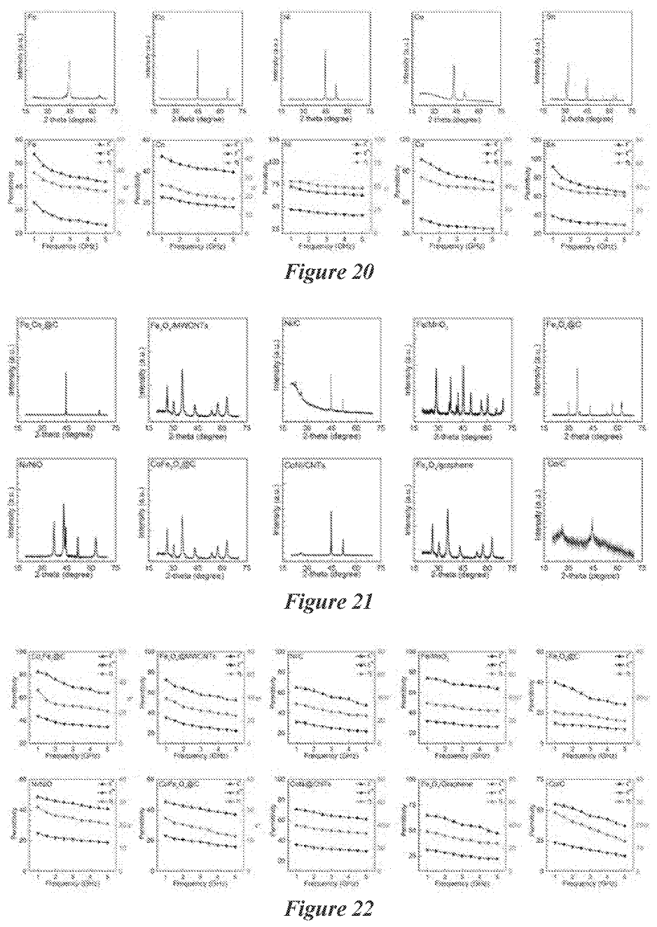

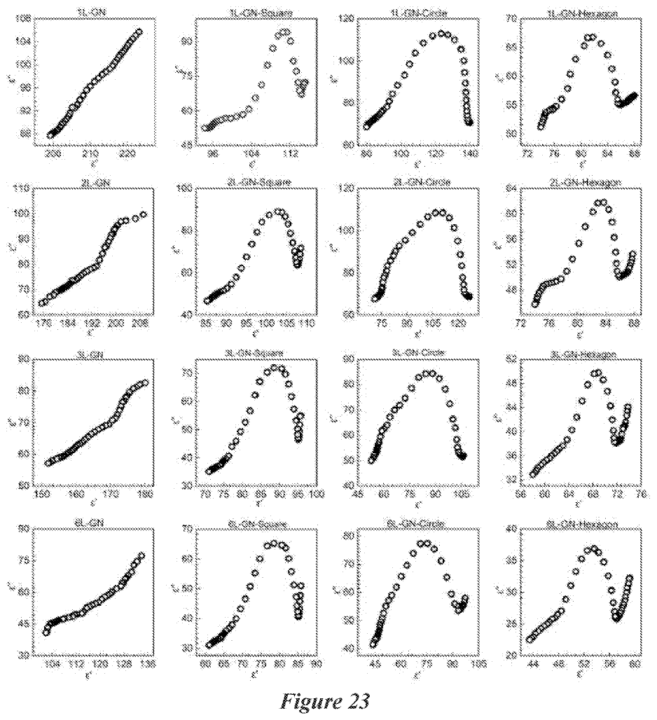

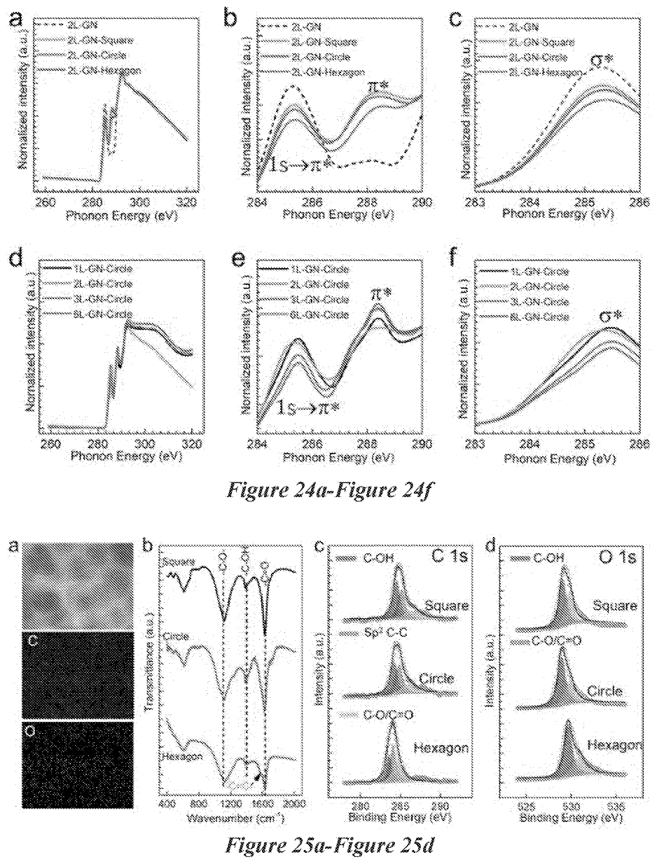

η=εᵣ tan δ_{c}=εᵣε″/ε′ (2)

where εᵣ is the relative complex permittivity and tan δ_{c} is the dielectric tangent loss, defined as the ratio of the imaginary and real part of the permittivity (ε″/ε′). The permittivity and η of graphene with different structures are shown in FIG. 3a and FIG. 14-FIG. 15. Within the EM frequency range of 2-5 GHz, the of monolayer and bilayer nanoporous graphene is larger than their trilayer and multilayer counterparts. In addition, the η of graphene with circular nanopores is higher than that of graphene with other pore shapes, which is attributed to the excellent EM wave incident angle-independence of the circular pores (see Note S5 and FIG. 16-FIG. 17). The highest η value among ordered nanoporous graphene, 160.8 for bilayer graphene with staggered circular pores, is higher than that of nonporous graphene (116.9) and a majority of the conventional EM dissipating materials (FIG. 18-FIG. 24, and Table 2).

TABLE 2
Permittivity, polarization frequency, and EM dissipation
factor of conventional EM dissipation materials.

| | | | Polarization | EM | |
|---|---|---|---|---|---|
| | | | frequency | dissipation | |
| Material | ε′ | ε″ | (GHz) | factor, η | Ref. |
| Fe₃O₄/Fe | 19.3- | 3.9- | 8.4, 13.5 | ~4.0 | Li, X. et al. ACS Appl. |
| | 14.2 | 2.8 | | | Mater. Interfaces 11, |
| | | | | | 19267-19276 (2019) |
| Fe₃O₄/Cu | 10.7- | 2.6- | 10.8 | ~3.0 | Fang, G. et al. J. Alloys |
| | 6.1 | 1.0 | | | Compd. 817, 152764 |
| | | | | | (2020) |
| FeSn₂/Sn | 9.3- | 4.7- | 8.2 | ~4.8 | Zhang, X. et al. Carbon 96, |
| | 3.1 | 1.4 | | | 972-979 (2016) |
| Fe@Ag | 6.1- | 0.7- | 5.1, 6.0, 11.7 | <0.1 | Yang, P. A. et al. Chem. |
| | 4.3 | 0.1 | | | Eng. J. 430, 132878 (2022) |
| FeSiAl/NiZn | 9.1- | 1.4- | 10.2 | <1.5 | Lei, C. et al. J. Alloys |
| | 7.5 | 0.1 | | | Compd. 822, 153674 |
| | | | | | (2020) |
| Co@CoO | 9.2- | 1.6- | 3.9, 9.3 | <1.7 | Deng J et al. J. Colloid |
| | 8.6 | 0.1 | | | Interface Sci. 509, 406-413 |
| | | | | | (2018) |
| CoO/Co₃O₄ | 7.2- | 2.0- | 8.6, 12.6 | <2.2 | Xie, X. et al. Chem. Eng. J. |
| | 4.9 | 1.2 | | | 396, 125205 (2020) |
| Co—Ni—P | 15.4- | 8.0- | 6.0, 8.1, 12.6 | ~8.1 | Liu, J. et al. Appl. Surf. Sci. |
| | 8.0 | 0.3 | | | 257, 2383-2386 (2011) |
| Ni@Ni₂O₃ | 14.1- | 1.2. | 15.9 | <1.3 | Wang, B. et al. J. Alloys |
| | 12.1 | 0.2 | | | Compd. 567, 21-25 (2013) |
| Ni@SnO₂ | 8.2- | 4.8- | 9.3, 14.2 | <5.0 | Zhao, B. et al. ACS Appl. |
| | 7.7 | 1.9 | | | Mater. Interfaces 8, 28917- |
| | | | | | 28925 (2016) |
| Cu@Ni | 23.1- | 14.9- | 7.5, 10.5, 17.2 | <15 | Zhou, Y. et al. Nano 13, |
| | 8.7 | 0.9 | | | 1850052 (2018) |
| SrZnCoFe₁₆O₂₇ | 6.1- | 0.3- | 10.4 | <0.4 | Azizi, P. et al. J. Alloys |
| | 6.0 | 0.2 | | | Compd. 739, 211-217 |
| | | | | | (2018) |
| TiN/Ni/C | 17.3- | 6.1- | 9.4, 12.1 | <6.5 | Zhang, Y. et al. Compos. |
| | 11.8 | 4.2 | | | Part B-Eng. 193, 108028 |
| | | | | | (2020) |
| MnO₂/NPC | 13.2- | 4.0- | 10.4, 12.8, 15.4 | <4.2 | Yang, H. et al. Chem. Eng. |
| | 8.5 | 3.5 | | | J. 417, 128087 (2021) |
| C/MnO/Co | 10.3- | 6.5- | 8.9, 13.6, 16.0 | <6.7 | Zheng, S. et al. Compos. |
| | 4.8 | 2.2 | | | Part A-Appl. S. 23, 106814 |
| | | | | | (2022) |
| Fe/NPC | 13.2- | 6.2- | 9.5 | <6.5 | Heng, L. et al. Appl. |
| | 6.2 | 4.1 | | | Organomet. Chem. 33, |
| | | | | | e4991 (2019) |
| Fe/CNT | 15.6- | 5.9- | 16.0 | <6.0 | Qi, X. et al. Mater. Sci. |
| | 7.2 | 4.1 | | | Eng. B-Adv. 198, 108-112 |
| | | | | | (2015) |
| (Fe₇₀Ni₃₀)/C | 12.1- | 6.0- | 9.2, 14.8 | <6.2 | Xie, Z. et al. J. Mater. Sci. |
| | 7.3 | 3.2 | | | Technol. 27, 607-614 |
| | | | | | (2011) |
| Fe—Co/NC/rGO | 8.0- | 5.3- | 9.8, 13.2 | <5.5 | Wang, S. et al. Nano Micro |
| | 2.5 | 1.4 | | | Lett. 11, 1-16 (2019) |
| Fe@C@BaTiO₃ | 16.3- | 5.1- | 10.8, 14.8 | <5.5 | Shi, G. et al. J. Alloys |
| | 9.4 | 3.8 | | | Compd. 655, 130-137 |
| | | | | | (2016) |
| Fe₂O₃/C/rGO | 7.8- | 1.3- | 16.6 | <1.5 | Ding, L. et al. Compos. |
| | 4.8 | 0.1 | | | Commun. 21, 100362 |
| | | | | | (2020) |
| F₃O₄/Fe@C@MoS₂ | 10.6- | 2.4- | 11.5, 16.9 | <2.5 | Tong, Z. et al. Carbon 179, |
| | 7.7 | 1.5 | | | 646-654 (2021) |
| Co/C | 6.7- | 2.2- | 13.1 | <2.3 | Ge, J. et al. Compos. Part |
| | 5.0 | 0.9 | | | B-Eng. 224, 109172 (2021) |
| Co/CNT | 18.4- | 20.7- | 7.5 | <21.0 | Xiao, X. et al. Compos. |
| | 3.2 | 1.3 | | | Part B-Eng. 152, 316-323 |
| | | | | | (2018) |
| CoAl@C | 20.0- | 8.3- | 12.1 | <8.5 | Li, D. et al. ACS Appl. |
| | 10.0 | 2.1 | | | Mater. Interfaces 9, 44704- |
| | | | | | 44714 (2017) |
| COMo@HNCP | 7.9- | 4.5- | 8.2, 11.9, 15.8 | <4.7 | Huang, W. et al. Carbon |
| | 4.2 | 1.1 | | | 167, 19-30 (2020) |
| Co@SiOₓC | 5.6- | 1.9- | 11.7, 14.0, 15.5 | <2.1 | Ge, J. et al. J. Alloys |
| | 5.0 | 0.5 | | | Compd. 831, 154442 |
| | | | | | (2020) |
| Co₃O₄/rGO | 12.2- | 6.5- | 12.1, 14.9 | <6.8 | Ma, J. et al. Chem. Eng. J. |
| | 8.0 | 2.5 | | | 339, 487-498 (2018) |
| Ni/CNTs | 6.4- | 6.8- | 8.5 | <7.0 | Sha, L. et al. ACS Appl. |
| | 1.8 | 3.7 | | | Mater. Interfaces 9, 40412- |
| | | | | | 40419 (2017) |
| Ni/TiO₂/C | 13.0- | 9.2- | 15.4, 16.5, 17.7 | <9.4 | Zhou, C. et al. Chem. Eng. |
| | 8.9 | 0.1 | | | J. 383, 123095 (2020) |
| Ni@C@ZnO | 11.8- | 5.7- | 7.6, 12.0 | <5.8 | Wang, L. et al. Chem. Eng. |
| | 8.7 | 3.6 | | | J. 383, 123099 (2020) |
| NiO@SiO₂@GN | 6.1- | 2.9- | 3.9, 15.6 | <3.0 | Wang, L. et al. Mater. Sci. |
| | 3.8 | 1.0 | | | Eng. B-Adv. 178, 1403- |
| | | | | | 1409 (2013) |
| Ni@Co₃O₄/rGO | 9.8- | 4.0- | 9.7, 15.6, 16.9 | ~4.1 | Tong, Z. et al. Appl. Surf. |
| | 5.2 | 3.3 | | | Sci. 565, 150483 (2021) |
| Cu/C | 21.7- | 13.9- | 15.3 | ~14.1 | He, N. et al. Chem. Eng. J. |
| | 20.5 | 5.3 | | | 378, 122160 (2019) |
| Sn@Mo₂C/C | 13.0- | 5.5- | 11.7, 13.1, 14.4 | ~5.6 | Qian, X. et al. Small 17, |
| | 6.5 | 3.3 | | | 2100283 (2021) |
| CuFe₂O₄/MoS₂ | 8.5- | 2.4- | N.A. | <2.5 | Liu, J. et al. Chem. Eng. J. |
| | 6.0 | 2.3 | | | 429, 132253 (2022) |
| MnFe₂O₄/MgO | 10.0- | 4.0 | 10.0 | <4.5 | Meng, X. et al. Carbon |
| | 7.0 | 2.0 | | | 194, 207-219 (2022) |
| Co@C | 16.0- | 28.0- | 13.7 | <28.0 | Zhao, H. Q. et al. Compos. |
| | 6.0 | 8.0 | | | Part B-Eng. 196, 108119 |
| | | | | | (2020) |
| CoFe₂O₄/porous C | 20.0- | 9.5- | 15.1 | <9.5 | Xu, R. X. et al. Chem. Eng. |
| | 10.0 | 4.5 | | | J. 427, 130796 (2022) |
| Fe@Ag | 7.0- | <0.1 | 10.0 | <0.2 | Yang, P. A. et al. Chem. |
| | 6.0 | | | | Eng. J. 430, 132878 (2022) |

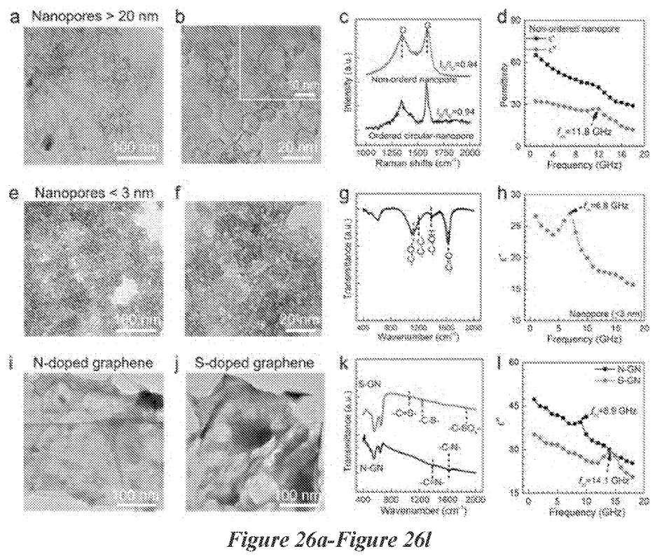

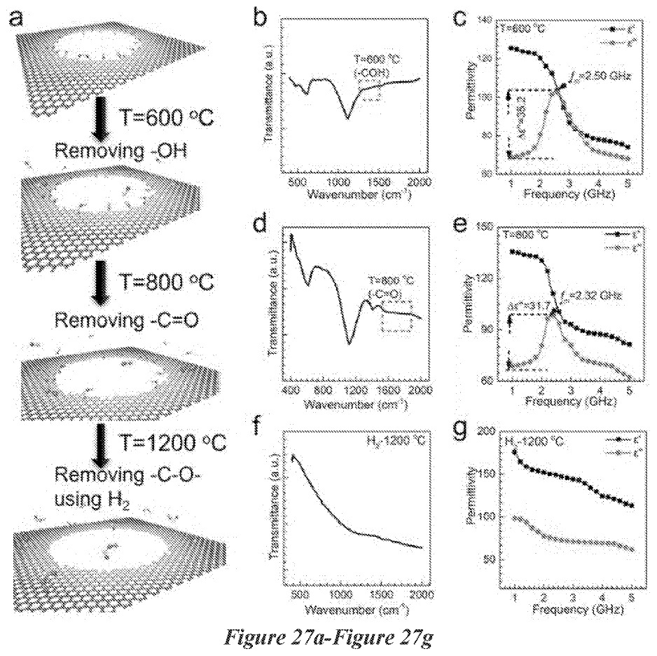

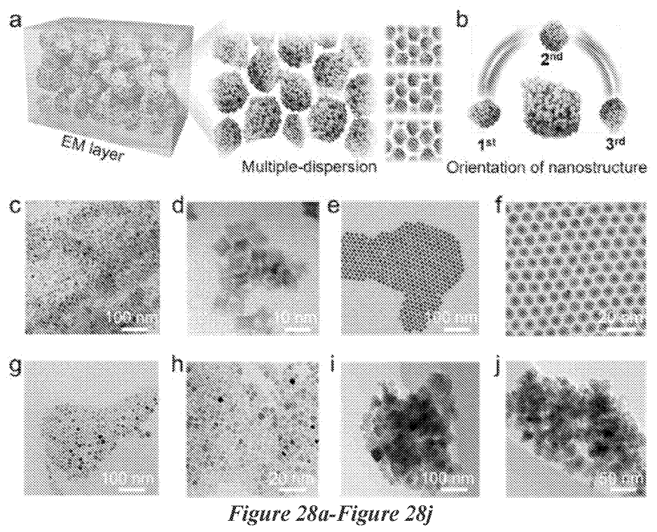

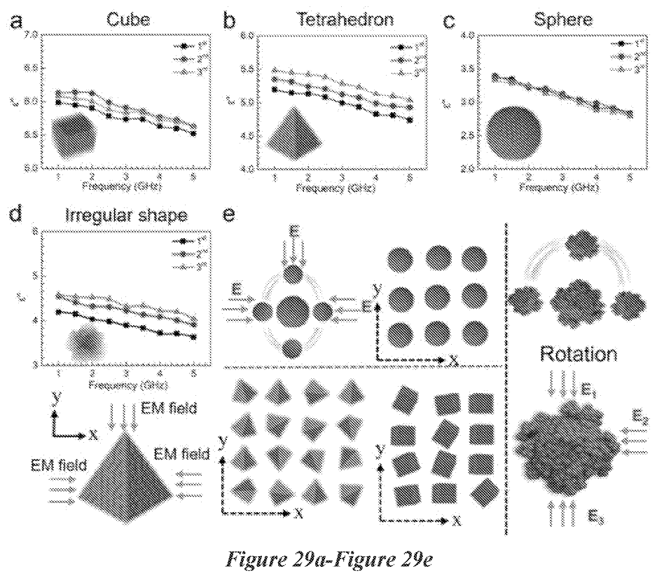

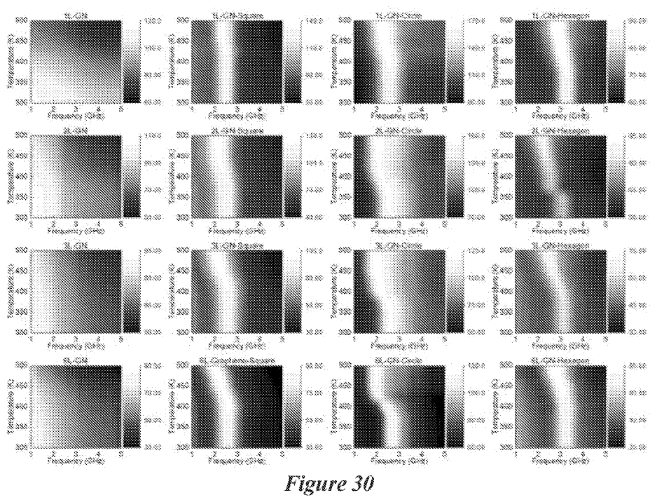

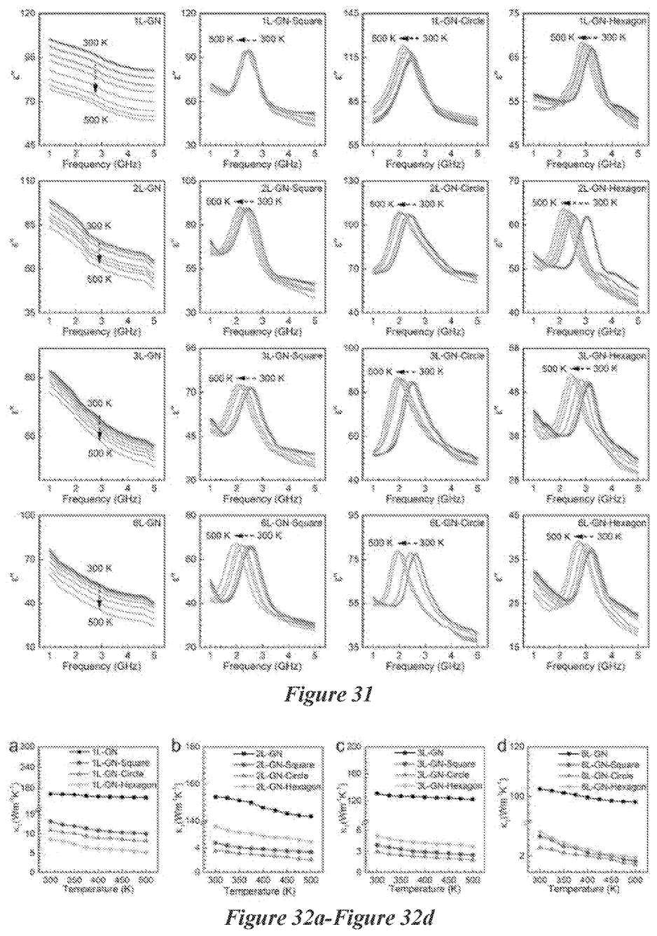

Measurement of the Cole-Cole curves of ordered nanoporous graphene (FIG. 25) demonstrates that the remarkable q of ordered nanoporous graphene is significantly attributed to the dipole relaxation polarization at low EM frequencies, which is consistent with the Debye relaxation theory (Sun, H. et al. Adv. Mater. 48, 8120 (2014); Zhang, M. et al. Mater. Sci. Eng. R. 145, 100627 (2021)). Considering the fact that the dipole polarization relaxation of conventional EM dissipating materials typically takes place at high frequencies (usually >8 GHz), due to a comparable relaxation time of their dipoles with respect to the frequency of the applied EM field (see Table 2), X-ray absorption fine structure (XAFS) spectroscopy (C is near edge), XPS, TEM mapping, Raman spectroscopy, and Fourier transform infrared spectroscopy (FT-IR) analysis of the ordered nanoporous graphene were performed, which collectively demonstrated that the distribution of dipoles with large electronegativity difference (e.g., C—O, C═O and C—OH) at the pore edges causes an increase in the relaxation time of dipoles and thus shifts the dipole relaxation polarization toward lower frequencies (Quan, B. et al. Adv. Funct. Mater. 29, 1901236 (2019); Hou, Y. L. et al. Nat. Commun. 13, 1227 (2022)), as shown in FIG. 26-FIG. 27 and Note S2. The above proposed mechanism is further supported by the low η of graphene with polydisperse, distorted pores, nitrogen or sulfur-doped graphene, and graphene with completely overlapped nanopores across different graphene layers, at low EM frequencies, which is because the dipole relaxation polarization of the above modified graphene is located at medium and high EM frequencies (>5 GHz) but not at low frequencies (2-5 GHz), as shown in FIG. 28-FIG. 29 and Note S3-Note S4. Furthermore, an increase in the intensity of the dipole relaxation polarization with temperature was measured, leading to an increase in t of ordered porous graphene (FIG. 30-FIG. 31). This result suggests that the ordered nanoporous graphene enables efficient EM dissipation at elevated temperatures.

Thermal conductivity of staggered, ordered nanoporous graphene. Upon dissipating the EM waves into heat, an ultralow thermal conductivity (Yer) is desired to maintain the temperature profile in the ordered nanoporous graphene to drive the directional diffusion of charge carriers from the hot side to the cold side. However, the pristine (nonporous) graphene is well known for its ultrahigh κ_{T}, preventing the formation of a sufficient temperature gradient for the generation of DC electricity via the Seebeck effect (Roychowdhury, S. et al. Science 371, 722-727 (2021)). In the next set of experiments, the effect of the nanoporous structure on the κ_{T} was investigated. As evidenced in FIG. 3b, the κ_{T} of the bilayer graphene with circular nanopores lies between 3.5 and 2.1 W/m·K over a temperature range of 300-500 K, which is two orders of magnitude lower than that of nonporous bilayer graphene. It was also observed that κ_{T} decreases with an increase in the number of graphene layers. The κ_{T} of bilayer graphene with circular nanopores is almost two orders of magnitude lower than graphene nanoribbons, other two-dimensional materials (e.g., tungsten diselenide, 2H molybdenum disulfide, and MXenes) and porous nanomaterials (e.g., graphene aerogel, graphitized carbon, and carbon foam), as listed in Table 3. The κ_{T} of graphene with different pore shapes is also compared in FIG. 32.

TABLE 3
Thermal conductivity of a variety of modified
graphene, 2D materials, and porous carbons.

| | Thermal | | |
|---|---|---|---|
| | conductivity | Temperature | |
| Material | (W/m · K) | (K) | Ref. |
| Isotopically-modified | >4,000 | 320 | Chen, S. S. et al. Nat. Mater. 11, |
| graphene | | | 203-207 (2012) |
| Graphene laminate | 40-90 | 323 | Malekpour, H. et al. Nano Lett. 9, |
| | | | 5155-5161 (2014) |
| Reduced graphene | ~6.5 | 500 | Zeng, W. et al. Nano Energy 54, |
| oxide | | | 163-174 (2018) |
| CVD-synthesized | 28 | 350 | Ma, W. G. et al. Nano Res. 11, 741- |
| graphene | | | 750 (2018) |
| Br-doped graphene | ~78 | 350 | Chio, M. et al. ACS Appl. Mater. |
| | | | Interfaces 13, 24304 (2021) |
| Graphene quantum | 58.9 | 298 | Yao, J. A. et al. ACS Appl. Mater. |
| dots/CNT | | | Interfaces 12, 39145 (2020) |
| Single CNT | 2,000 | 320 | Fujii, M. et al. Phys. Rev. Lett. 95, |
| | | | 065502 (2005) |
| Monolayer MoS₂ | 87.8 | N.A. | Li, X. F. et al. ACS Nano 13, 2481- |
| | | | 2489 (2019) |
| Ti₃C₂Tₓ | 108 | 600 | Gholivand H. et al. J. Appl. Phys. |
| | | | 126, 065101 (2019) |
| WSe₂ | ~10 | 800 | Yuan K. P. et al. Phys. Chem. Chem. |
| | | | Phys. 21, 468-477 (2019) |
| Porous SiC ceramic | ~1.5 | 1,000 | Santhosh, B. et al. J. Euro. Ceram. |
| | | | Soc. 41, 1151 (2021) |
| Porous carbon | 4.5 | N.A. | Zhao Y. J. et al. Energy Buildings |
| | | | 158, 1049 (2018) |
| Few-layer WS₂ | 32 | 298 | Kam, K. K. et al. J. Phys. Chem. 86, |
| | | | 463 (1982) |
| Bilayer WS₂ | 32 | 298 | Peimyoo, N. et al. Nano Res. 8, |
| | | | 1210 (2015) |
| Al-CNT | ~80 | 573 | Ujah, C. O. et al. J. Mater. Sci. 54, |
| | | | 14064 (2019) |

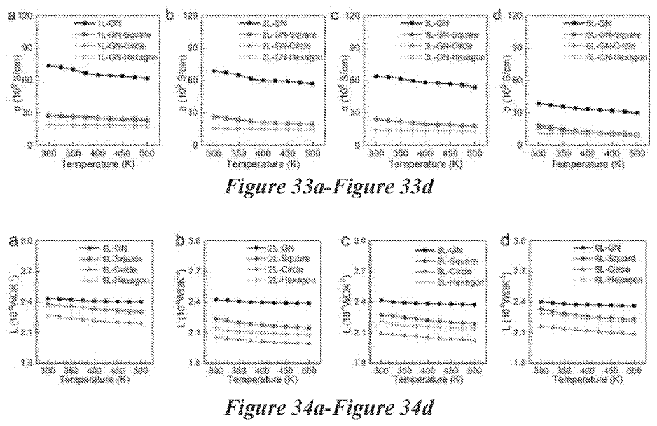

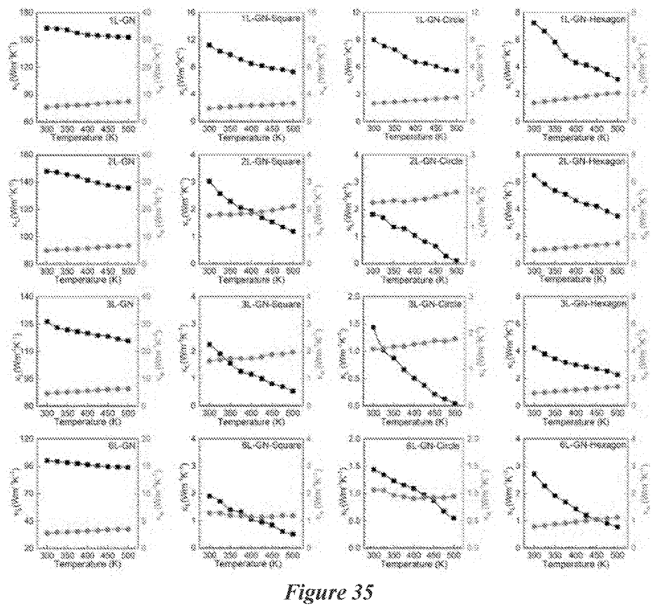

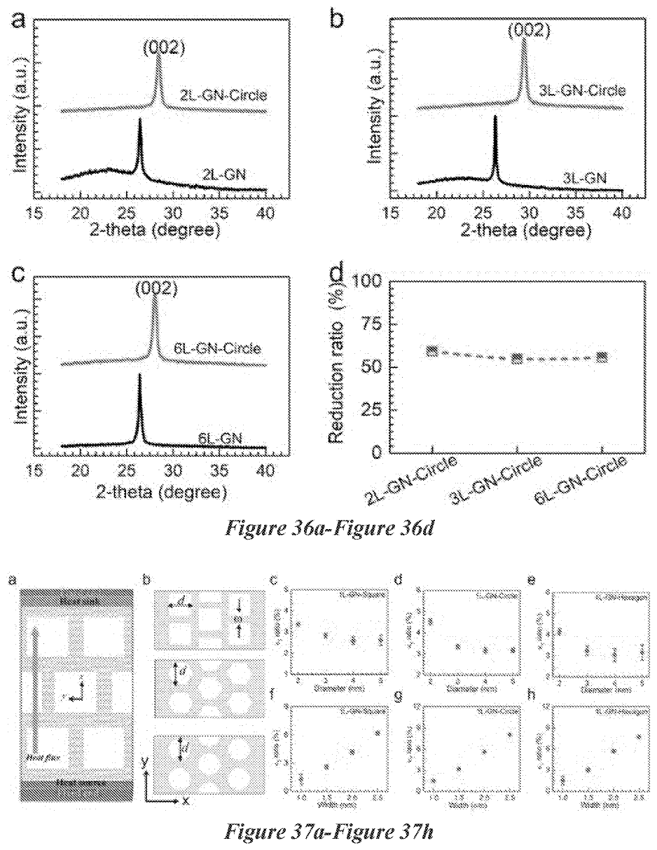

It is well established that κ_{T} has contributions from the electron and lattice thermal conductivity (κₑ and κ_{L}, respectively) and that Ke is proportional to the electric conductivity (σ) (Shi, X. L. et al. Chem. Rev. 15, 7399-7515 (2020)). To elucidate the role of the nanoporous structure in the reduced κ_{T}, the σ, κₑ, and κ_{L} of the ordered nanoporous graphene were measured as a function of temperature (see Note S6). As shown in FIG. 33-FIG. 35, upon creating the nanopores on graphene, an abrupt decrease in κ_{L} was found to be the main contributor to the reduction of κ_{T}. To provide insight, molecular dynamics simulations were performed to compute the localization and scattering of phonons at the pore edges of graphene (see interatomic potential parameters and detailed computational methods in Note S7, FIG. 37 and Table 4). In one graphene layer, carbon atoms in the dipoles located at the pore edges weaken the phonon coupling behavior, particularly in the phonon frequency of 50-65 THz, as evidenced in FIG. 3c and FIG. 38-FIG. 39. The mismatch in the phonon density of states at a phonon frequency <50 THz also gives rise to strong phonon scattering at the pore edges, known as the phonon backscattering effect (Suzuura, H. et al. Phys. Rev. B 65, 235412 (2002); Han, Z. R. et al. Phys. Rev. Lett. 128, 045901 (2022)). In addition, the existence of carbon atoms both covered by neighboring layers of graphene and exposed by the pores weakens the phonon coupling behavior in ordered nanoporous graphene with more than one layer, as shown in FIG. 3d (see FIG. 40-FIG. 42 for the effect of the number of graphene layers and staggered porous graphene with different overlap ratios, which are defined by the ratio of the pore area that is covered by a neighboring graphene layer to the total pore area). The presence of nanopores was found to decrease the spacing between graphene layers (evidenced by the diffraction peak of the (002) crystal plane of graphene in FIG. 36), which further weakens the phonon coupling of covered and exposed carbon atoms in a single graphene layer.

TABLE 4
Dependence of d₁₋₄ and thermal conductivity of a four-layer
graphene nanosheet on its shifting distance, S₂₋₄.

| S₂₋₄ | d₁₋₄ | Thermal conductivity |
|---|---|---|
| (Å) | (Å) | (W/mK) |
| 0 | 10.50 | 13.80 |
| 20 | 9.53 | 13.26 |
| 40 | 9.52 | 13.06 |
| 60 | 10.42 | 13.49 |
| 80 | 9.46 | 12.68 |
| 100 | 9.52 | 13.07 |

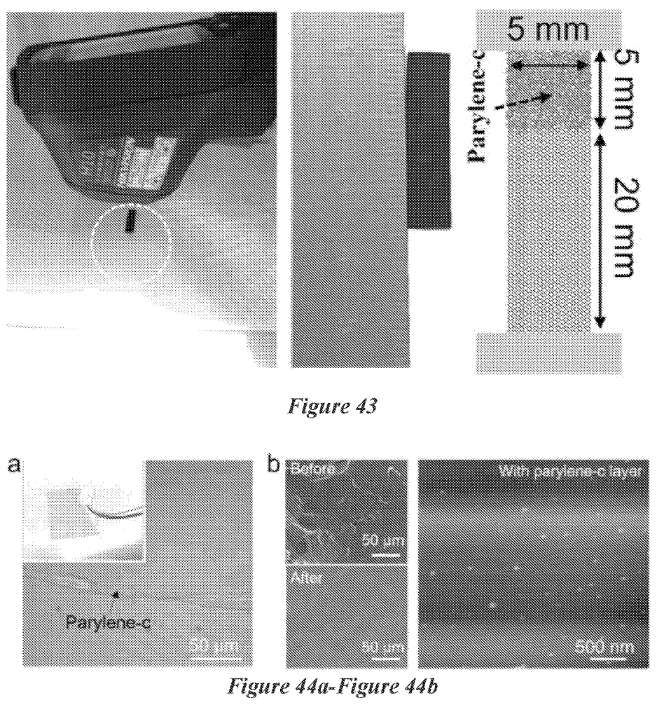

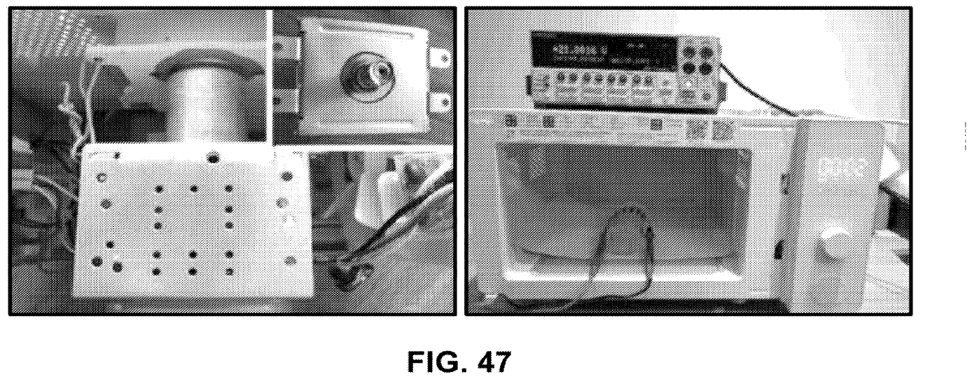

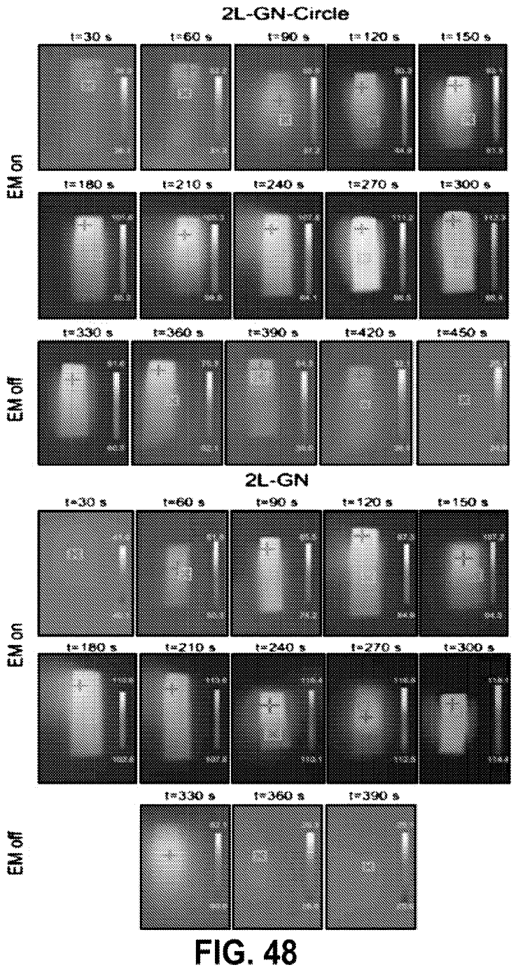

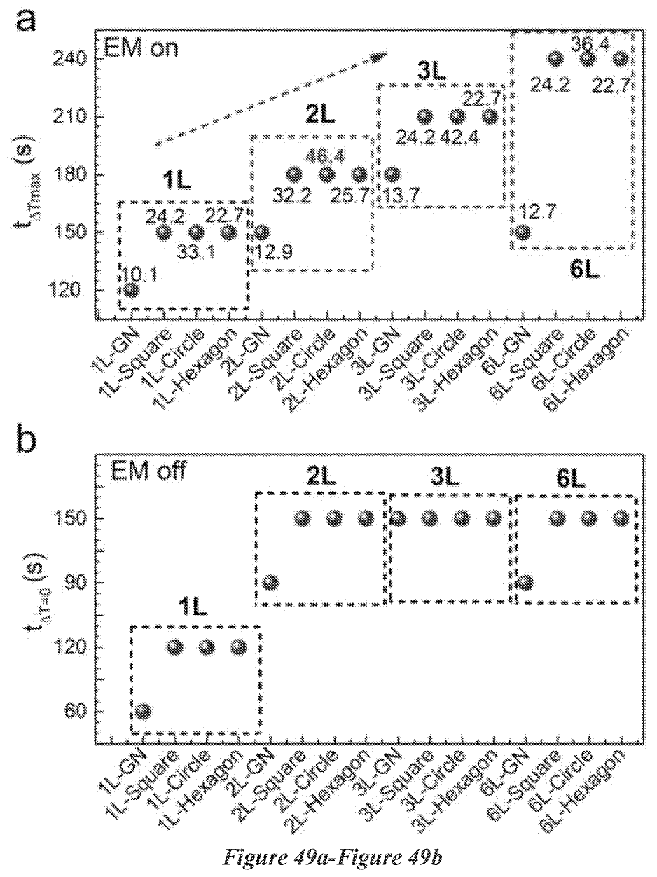

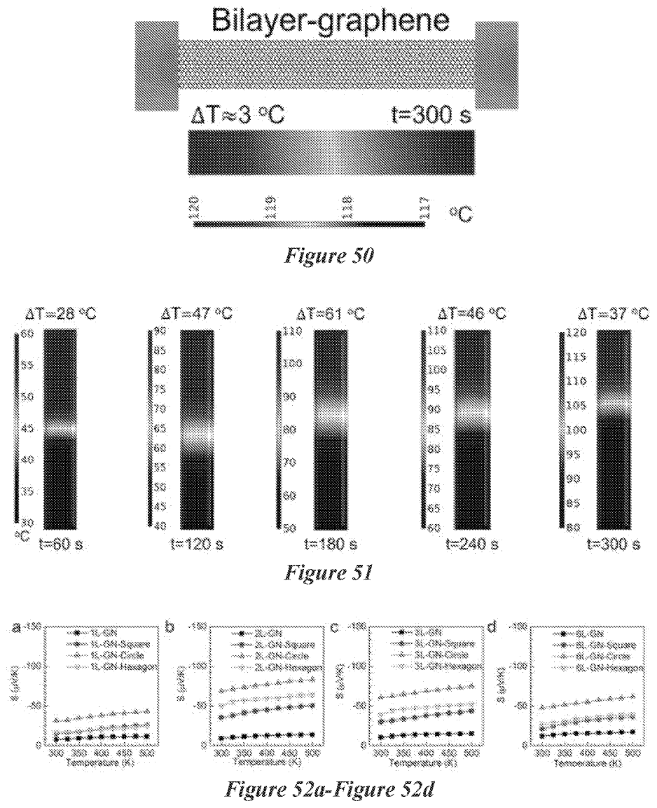

Next, it was sought to design an ordered porous graphene-based device to generate a temperature gradient upon EM radiation. Strips of graphene that were 25 mm-in-length, 5 mm-in-width and 10 μm-in-thickness were fabricated and coated a 690 nm-thick adiabatic parylene-c layer on one end of the strip using chemical vapor deposition (see FIG. 43-FIG. 46 and Note S8). Upon radiating the strips with EM waves with a frequency of 2.45 GHz using a homemade EM emitting cavity with a 100 W magnetron (see FIG. 47), the temperature profile and temperature gradient (defined as the temperature difference between the two ends of the graphene strip (ΔT) divided by the strip length (25 mm)) as a function of time was determined using an infrared thermometer. As shown in FIG. 3e and FIG. 48-FIG. 49, upon EM radiation, the temperature gradient of the bilayer graphene with circular nanopores increases and reaches a maximum at 180 s with a value of 1.86 K/mm, which is approximately four times that of a nonporous bilayer graphene-based strip (0.52 K/mm). Upon removing the EM radiation, the temperature gradient recovers to zero after 150 s. These results demonstrate that a large temperature gradient in ordered nanoporous graphene can be generated upon EM radiation, further confirmed using finite-element analysis (FIG. 3f, FIG. 50-FIG. 51 and Note S9).

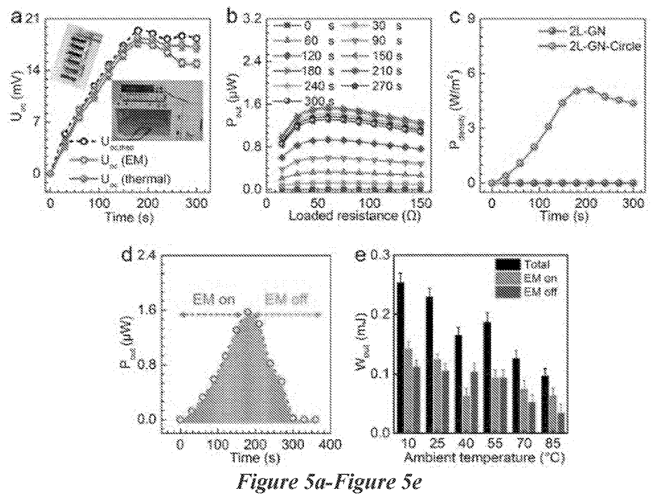

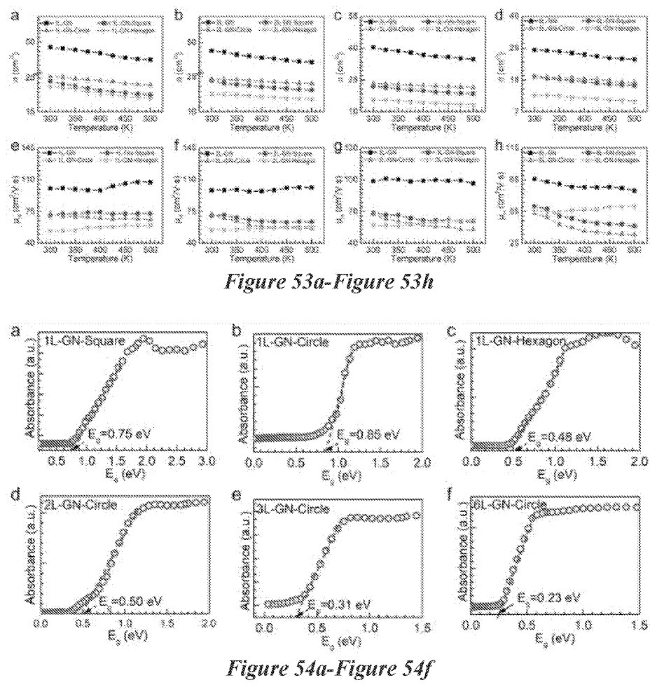

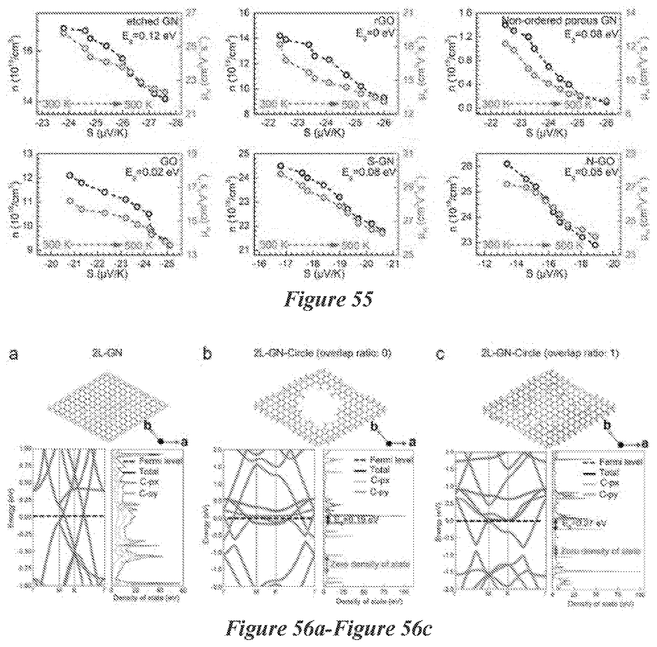

Seebeck effect of staggered, ordered nanoporous graphene. It is well known that pristine graphene lacks the strong Seebeck effect required for efficient DC generation from a temperature gradient (Zuev, Y. M. et al. Phys. Rev. Lett. 102, 096807 (2009); Harzheim, A. et al. Nano Lett. 12, 7719 (2018)). It was found that the presence of nanoporous structures greatly enhances the Seebeck effect of graphene, and the absolute value of the Seebeck coefficient (|S|) of ordered nanoporous graphene is comparable with conventional thermoelectric materials and larger than other modified graphene (Table 5). As shown in FIG. 4a and FIG. 52, the |S| of bilayer graphene with ordered circular nanopores was between 69-83 μV/K over a temperature range of 300-500 K, at least six times larger than that of nonporous graphene (<10 μV/K), with bilayer graphene with square and hexagonal nanopores being ~50% and ~15% smaller, respectively. The negative sign of S indicates an n-type semiconducting behavior for the ordered porous graphene, in which electrons are the predominant carriers (Lusk, M. T. et al. Phys. Rev. Lett. 100, 175503 (2008): Chen, L. C. et al. Nat. Maier. 18, 1321 (2019)). Temperature-dependent Hall carrier measurements and UV photoelectron spectroscopy analysis of ordered nanoporous graphene were performed at different temperatures to unveil the origin of the exceptional |S| value. As shown in FIG. 53-FIG. 54 and Note S10, the presence of nanopores improves the effective mass (m*), reduces the carrier concentration (η), and opens the graphene bandgap (E_{g}). However, |S| value of a series of modified graphene, including sulfur or nitrogen-doped graphene, graphene with polydisperse pore structures, and reduced graphene oxide, all of which possess different m*, n, and E_{g}, are less than 30 μV/K (FIG. 55 and Note S11). These results suggest that the synergistic effect of monodisperse nanometer-sized pores and the staggered porous structure alters the electronic structure and thus enhances the |S| of graphene.

TABLE 5
Absolute Seebeck coefficient of conventional 2D nanomaterials.

| | Absolute Seebeck | | |
|---|---|---|---|
| | coefficient | Temp. | |
| Material | (μV/K) | (K) | Ref. |
| Twisted bilayer | ~11 | 300 | Mahapatra, P. et al. Nano Lett. 17, 6822- |
| graphene | | | 6827 (2017) |
| Multilayer graphene | ~20 | <300 | Lin Y. et al. Energy Environ. Sci. 13, |
| | | | 4114 (2020) |
| S-doped graphene | ~30 | 300 | Xu, Y. et al. Small 10, 2182 (2014) |
| Graphene nanoribbon | ~30 | 300 | Zheng, H. et al. Appl. Phys. Lett. 100, |
| | | | 093104 (2012) |
| SnS₂ | ~140 | 300 | Chang, Y. et al. J. Mater. Sci. Mater.-El. |
| | | | 31, 5425 (2020) |
| Bi-doped SnSe | ~100 | 300 | Chandra, S. et al. ACS Energy Lett. 3, |
| | | | 1153 (2018) |
| Mo₂TiC₂Tₓ | ~50 | 800 | Karmakar, S. et al. Phys. Rev. Mater. 4, |
| | | | 124007 (2020) |
| p-typed MoS₂ | ~50 | 450 | Kong, S. et al. J. Phys. Chem. B 122, |
| | | | 713 (2018) |
| 2H—MoS₂ | ~30 | 323 | Gangwar, P. et al. Mater. Res. Express 6, |
| | | | 105062 (2019) |
| Graphene/PVP | 45.1 | 500 | Cho, C. et al. Nano Energy 28, 426 |
| | | | (2016) |
| Si doped Graphene | ~100 | 300 | Lee, W. et al. Nano Energy 87, 106188 |
| | | | (2021) |
| Graphene/PEDOT:PSS | 32.3 | 100 | Liu, X. et al. J. Mater. Sci. Mater.-El. |
| | | | 30, 20369 (2019) |
| Graphene/MoS₂ | 50 | 550 | Sadeghi, H. et al. 2D Mater. 4, 015012 |
| | | | (2016) |
| Graphene/C₆₀ | 55 | N.A. | Wu, Q. Q. et al. Sci. Reps. 7, 11680 |
| | | | (2017) |
| Graphene/BiSrTe alloy | ~165 | 300 | Shin W. H. et al. J. Alloys Compd. 718, |
| | | | 342 (2017) |
| Graphene/carbon | ~15 | 298 | Dong, D. P. et al. Nano Energy 39, 470 |
| aerogel | | | (2017) |
| CNT/CuzSe | ~100 | 450 | Nunna, R. et al. Energy Environ. Sci. 10, |
| | | | 1928 (2017) |
| CF/Bi₂Te₃ | ~50 | 300 | Jagadish, P. et al. Compos. Part B-Eng. |
| | | | 175, 107085 (2019) |
| MXene-PEDOT:PSS | 57.3 | 400 | Guan, X. et al. ACS Appl. Mater. |
| | | | Interfaces 12, 13013 (2020) |
| SnTe/WSe₂ | ~50 | 600 | Wang, X. C. et al. J. Electron. Mater. |
| | | | 51, 486 (2022) |

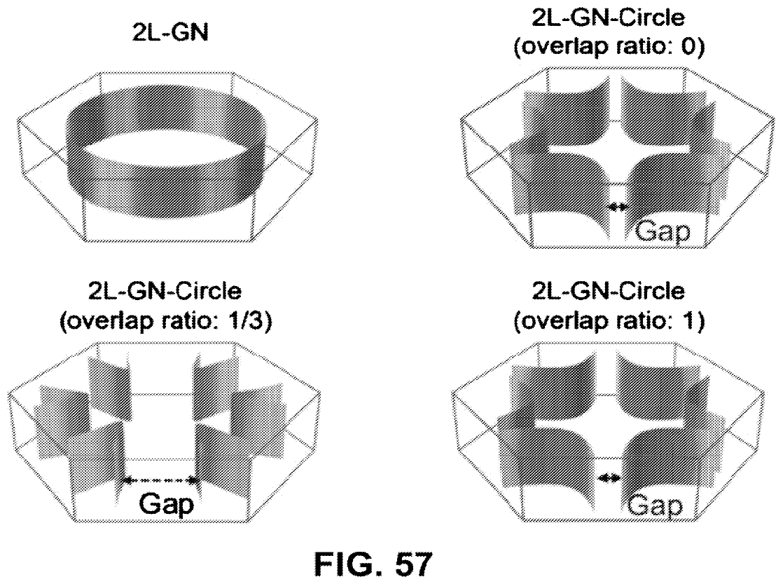

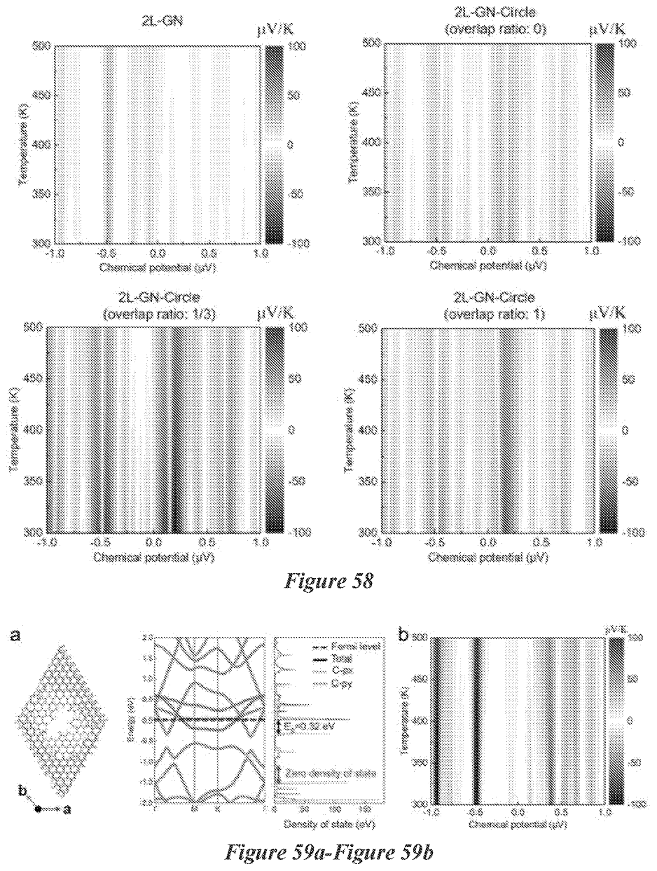

To elucidate the mechanism for |S| enhancement, a first-principles density functional theory study of the band structure of the ordered nanoporous graphene was performed (Note S12). As evidenced in the band structure of bilayer graphene with staggered circular pores (with an overlap ratio of ⅓) in FIG. 4b, the Dirac points split and shift from their original positions (i.e., G, M, and K for nonporous graphene) to regions between G-M and K-G, resulting in an open bandgap structure with a bandgap of 0.47 eV, which is in good quantitative agreement with the experimental characterization (0.51 eV; FIG. 54). Furthermore, the splitting of the Dirac points leads to a breaking up of the original, continuous Fermi surfaces in the Brillouin zone into disconnected Fermi surfaces with different energies, which act as electron cages and confine carrier mobility in each Fermi surface (known as the Dirac trap effect) (Ding, Y. F. et al. Nat. Commun. 10, 841 (2019)). The calculated projected density of states in FIG. 4b reveals a high density of states (known as van Hoff singularity points) separated by zero density states. This electronic structure, combined with the Dirac trap effect, facilitates the interaction between electrons and phonons (known as the phonon drag effect) and tremendously enhances the |S| of graphene (Shi, X. L. et al. Chem. Rev. 120, 7399 (2020)) Particularly, compared with bilayer graphene with completely overlapped nanopores (overlap ratio is 1), the staggered pore structure with a partial overlap ratio facilitates the splitting of the Dirac points and thus generates higher intensity van Hoff singularity points, which are beneficial to the enhancement of the Seebeck effect of graphene (see FIG. 56-FIG. 61 for the effect of pore shape, graphene layer number, and overlap ratio) (Lin, Y. et al. Energy Environ. Sci. 13, 4114 (2020); Tomadin, A. et al. Phys. Rev. B 104, 125443 (2021); Wei, P. et al. Phys. Rev. Lett. 102, 166808 (2009)).

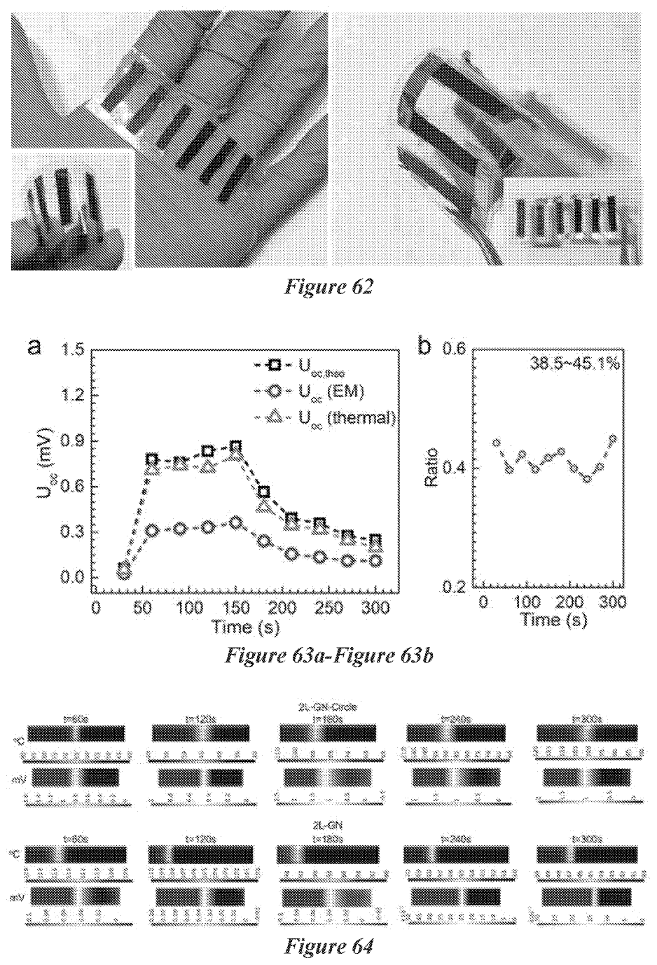

Electricity output by staggered, ordered nanoporous graphene. Based on the above analysis, bilayer graphene with staggered circular nanopores possess the most desirable η, κ_{T}, and |S|among the different nanoporous structures. In the final set of experiments, a device including six strips of ordered nanoporous graphene was fabricated on an insulating polydimethylsiloxane substrate to explore its EM-heat-DC conversion (FIG. 62). As shown in FIG. 5a, the open-circuit voltage (U_{oc}) of the graphene-based device was measured to increase to ~17.7 mV over about 180 s before decreasing with continued EM radiation. In contrast, the U_{oc} of a nonporous graphene-based device was only 0.8% of that of porous graphene-based device (FIG. 63). The theoretical U_{oc,theo} was calculated as (Jiang, B. B. et al. Science 371, 830 (2021)):

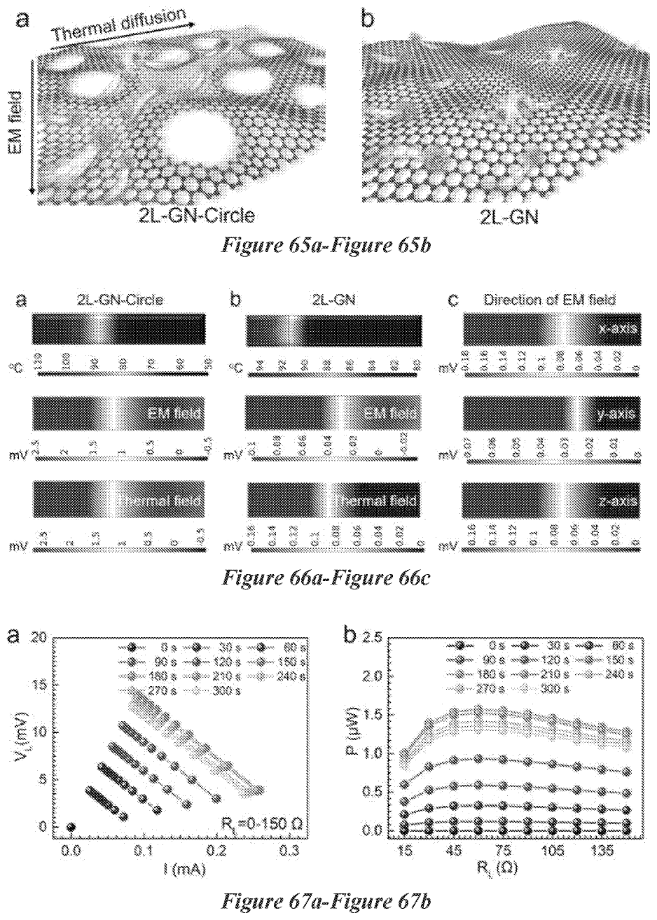

U_{oc,theo}=ΔT·N·|S| (3)

where N is the number of strips of ordered porous graphene, and the average |S| of the bilayer porous graphene between 300-450 K was 72.3 μV/K. The experimental U_{oc} of ordered porous graphene is 71.0-92.8% of the U_{oc,theo}. It is hypothesized that this reduction of U_{oc} compared to U_{oc,theo} is caused by the interference between the EM and thermal fields—the mismatch between the direction of the alternating EM field, and the temperature gradient causes a deviation of the flux of electrons and thus lowers the U_{oc}. This hypothesis is validated by directly applying the same ΔT to the porous graphene-based device without of EM radiation. The measured U_{oc} in this case is in better quantitative agreement with U_{oc,theo}. Additional finite-element analysis further supports the experimental measurements, as shown in FIG. 64-FIG. 65 and Note S13. In addition, the effect of this interference on graphene with different porous structures is shown in FIG. 66.

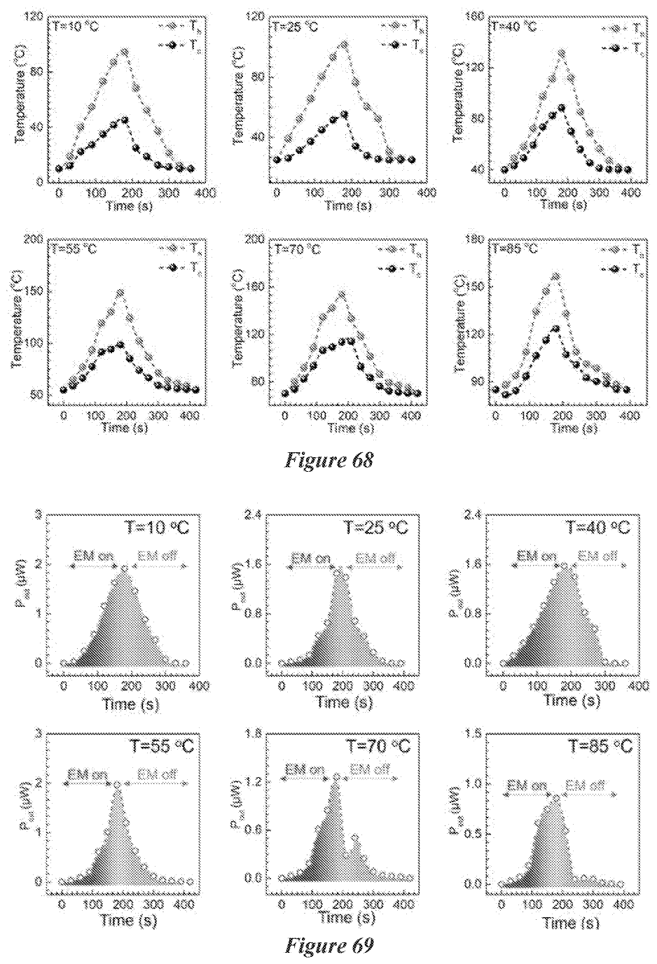

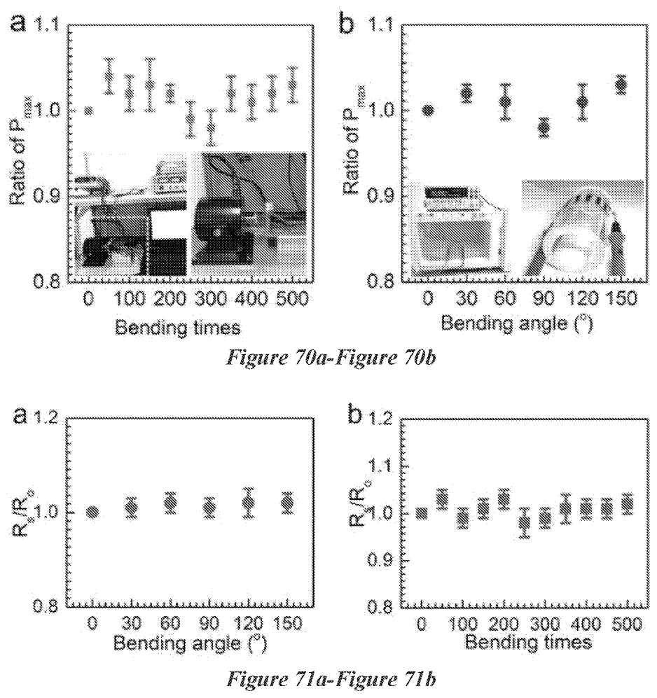

By measuring the output voltage-current curve of the ordered nanoporous graphene-based devices as a function of load resistance (0-150Ω) and EM radiation time (FIG. 5b and FIG. 67), the maximum output power and power density were measured to be 1.5 μW and 5.1 W/m² with a load resistance of 60Ω upon EM radiation for 180 s, which is comparable to that of conventional thermoelectric materials (FIG. 5c and Table 6). Furthermore, the device can output electric energy of ~0.23 mJ per EM radiation cycle (180 s for both EM radiation on and off) for at least 500 cycles (see FIG. 5d). Finally, the ordered nanoporous graphene-based devices exhibited an excellent electricity generation performance over a wide temperature range (10-85 °C, FIG. 5e, FIG. 68-FIG. 69 and Note S14) and after being bent 500 times (Note S15-Note S16 and FIG. 70-FIG. 72).

TABLE 6
Maximum power density and temperature difference of current electricity
generating materials that utilize temperature gradients.

| | P_{density} | ΔT | P_{density}/ΔT | |
|---|---|---|---|---|
| Material | (mW/cm²) | (K) | (mW/cm² · K) | Ref. |
| n/p-SWCNT | 4.16 | 30 | 0.138 | Sheng, M. et al. Carbon 158, 802- |
| | | | | 807 (2020) |
| TENG | ~1.4 × 10⁻² | 80 | 1.75 × 10⁻⁴ | Wu, Y. et al. Adv. Mater. Technol. |
| | | | | 3, 1800166 (2018) |
| n-type Ag₂Se | 23 | 30 | 7.66 × 10⁻¹ | Ding, Y. F. et al. Nat. Commun. |
| | | | | 10, 841 (2019) |
| PEDOT:PSS/Cu₂Se | 9.1 × 10⁻² | 30 | 3.0 × 10⁻³ | Lu, Y. et al. ACS Appl. Mater. |
| | | | | Interfaces 11, 12819-12829 (2019) |
| TE/PEDOT:PSS | 5.72 × 10⁻² | 40 | 1.43 × 10⁻³ | Bae E. et al. Sci. Rep. 6, 18805 |
| | | | | (2016) |
| PANI/CNT/Te | 6.24 × 10⁻² | 40 | 1.56 × 10⁻³ | Wang, L. M. et al. Mater. Chem. |
| | | | | Front. 1, 741-748 (2017) |
| PEDOT:PSS/ | 8.0 × 10⁻² | 40 | 2.0 × 10⁻³ | Tian, R. et al. J. Mater. Chem. A 5, |
| TiS₂[(HA)(NMF)] | | | | 564-570 (2017) |
| PEDOT:PSS/Te/Cu₇Te₄ | 3.95 × 10⁻² | 39.1 | 1.01 × 10⁻³ | Lu, Y. et al. ACS Appl. Mater. |
| | | | | Interfaces 10, 42310 (2018) |
| PVP/Ag/Ag₂Te | 3.41 × 10⁻¹ | 39.6 | 8.6 × 10⁻³ | Meng, Q. F. et al. ACS Appl. |
| | | | | Mater. Interfaces 11, 33254 (2019) |
| Ag₂Se/Ag/PEDOT | 7.47 × 10⁻² | 27 | 2.76 × 10⁻³ | Wang, Z. X. et al. Mater. Today |
| | | | | Phys. 21, 100553 (2021) |
| CNT/PEG | 1.25 × 10⁻⁴ | 25 | 5 × 10⁻⁶ | Wang, L. M. et al. Energy |
| | | | | Environ. Mater. 3, 67-79 (2019) |
| NbSe₂/WS₂ | 7.3 × 10⁻⁷ | 60 | 1.21 × 10⁻⁸ | Romanenko, A. et al. J. Structure |
| | | | | Chem. 58, 893 (2017) |
| Bi_{0.5}Sb_{0.15}Te₃ | 2.28 × 10⁻³ | N.A. | N.A. | Koyano, M. et al. J. Electron. |
| | | | | Mater. 41, 1317 (2012) |
| (Nb_{0.8}Ta_{0.2})_{0.8}Ti_{0.2}FeSb | 211 | 655 | 0.32 | Yu, J. J. et al. Adv. Energy Mater. |
| | | | | 10, 2000888 (2020) |
| Ag—Se-TENG | 3.21 × 10⁻¹ | 110 | 2.9 × 10⁻³ | Mallick, M. M. et al. ACS Appl. |
| | | | | Mater. Interfaces 12, 19655 (2020) |
| Bi₂Te₃-TENG | 9.2 | 52.5 | 1.75 × 10⁻¹ | Yu, C. X. et al. Nano Energy 17, |
| | | | | 104 (2014) |
| Ce_{y}Fe₃CoSb₁₂ | 2.1 | 570 | 3 × 10⁻³ | Tan, G. J. et al. J. Electron. Mater. |
| | | | | 43, 1712 (2014) |
| Bi₂Te₃ | 11.14 | N.A. | N.A. | Saberi, Y. et al. J. Alloys Compd. |
| | | | | 904, 163918 (2022) |
| Ge_{0.84}Pb_{0.1}Sb_{0.06} | 1,760 | 425 | 4.14 | Gurbanov, G. R. et al. |
| | | | | Semiconductors 54, 1304 (2020) |
| Se—Co—Ni alloy | 4,360 | 500 | 8.72 | Nielsen, M. D. et al. AIP Advance |
| | | | | 5, 053602 (2015) |

Conclusion. Herein, a method to create staggered, monodisperse nanometer-sized pores on the surface of graphene is reported. It was observed that the presence of these nanopores and the staggered porous structure alter the electronic and phonon structure of the graphene (e.g., dipole polarization relaxation, open bandgap structure, splitting of Dirac points, and phonon scattering), resulting in desirable functionalities such as a high permittivity, low thermal conductivity, and high Seebeck coefficient. As a result, the ordered nanoporous graphene enables the efficient generation of DC electricity through the absorption and dissipation of EM waves into heat, followed by a simultaneous thermoelectric process. These results advance the fundamental understanding of the structure-property relationship of ordered nanoporous graphene and provide a material design method to efficiently absorb and convert low-frequency EM waves and waste heat from the environment into usable electricity. This class of multifunctional ordered nanoporous graphene may expand the potential utility of graphene in energy harvesting, thermal management, and photocatalytic water splitting.

Future efforts can experimentally control the overlap ratio of nanopores on different graphene layers to study its influence on the graphene properties. In addition, the self-powering and self-charging of wearable electronics building on the success of the emerging 5G communication using ordered porous graphene-based devices is being investigated.

### Methods

Materials. Iron acetylacetonate, oleic acid, oleyl amine, ammonia (28 wt %), hydrogen peroxide (30 wt %), sodium molybdate dehydrate, thiourea, ferrous chloride, cobalt acetate, ethylene glycol, zinc acetate, lanthanum oxide, cobalt nitrate, tetraethyl orthosilicate, sodium hydroxide, oxalic acid, strontium carbonate, cobalt oxalates, bismuth nitrate pentahydrate, tellurium powder, 1-butyl-3-methylimidazolium bromide, silver nitrate, stannous chloride, sulfur powder, ethylenediaminetetraacetic acid disodium, copper nitrate, hexadecyltrimethylammonium bromide, formaldehyde, cyclohexane, isopropanol, iron pentacarbonyl, 1,3-dimethylimidazoline-2-selenone, hydrochloric acid (38 wt %), and parylene-c monomer were brought from Sigma-Aldrich. Raw graphene and multiwall carbon nanotube were obtained from XF-NANO tech. Co. All chemical reagents are analytical pure reagents and were used without further purification. Polydimethylsiloxane film was brought from Shanghai Muke Technol. Co. Water used in all the experiments was purified using a Milli-Q water purification system (Simplicity C9210).

Synthesis of graphene with ordered nanometer-sized pores. First, iron acetylacetonate, raw graphene, prepared by chemical vapor deposition (CVD), oleic acid, and oleyl amine were mixed and ultrasonicated for 30 min. Afterward, the mixture was heated between 110 and 120 °C with vigorous stirring for 2 h under a nitrogen flow. Next, the mixture was heated to 220 °C and kept at this temperature for 30 min, followed by heating up to 300 °C at a heating rate of 2 °C/min where it stayed for another 30 min. After cooling to room temperature, the graphene decorated with iron oxide (Fe₃O₄) nanoparticles was collected via centrifugation after dispersing it in cyclohexane and isopropanol.

Fe₃O₄ nanoparticle-coated graphene was kept at 300 °C for 60 min under constant nitrogen flow to remove residual organics. Next, the temperature was increased to 900 °C at a rate of 1 °C/min and maintained at this temperature for 2 h to create nanopores on the graphene. After cooling to room temperature, the graphene was dispersed into a hydrochloric acid solution with a pH between 1.5 and 2.0 to remove the residual nanoparticles, resulting in the formation of nanometer-sized pores on the graphene surface. The nanopore shapes can be tuned by forming nanoparticles with different geometries (see Table 7). By utilizing raw graphene with specific numbers of layers, double layer, trilayer, or multilayer graphene with nanopores can be fabricated.

TABLE 7
Experimental parameters for the synthesis of ordered
porous graphene with different nanopore shapes.

| Fe₃O₄ | Diameter | V_{Oleic acid} | Heat rate |
|---|---|---|---|
| nanoparticle shape | (nm) | (mL) | (°C/min) |
| Cubic | 7 ± 1 | 10 | 8 ± 1 |
| Spherical | 6 ± 1 | 12 | 8 ± 1 |
| Hexagonal | 16 ± 2 | 9 | 8 ± 1 |

Fabrication of graphene-based devices for EM-heat-DC conversion. A thin film of ordered nanoporous graphene with a thickness of ~10.0±0.8 μm was spin-coated on a silicon substrate and later cut into several 25 mm long and 5 mm wide strips. Next, 20 mm of each strip was covered, and the exposed region (5 mm) of the graphene was coated with parylene-c using a CVD process involving four steps at 120, 130, 140, and 150 °C with corresponding times of 20, 20, 40, and 0-120 min, respectively. The temperature of the CVD deposition chamber was set to 650 °C, and the parylene-c monomer was placed in the CVD evaporation chamber that was set at 120 °C. The thickness of the parylene-c coating was tuned by the chemical deposition time. After deposition, six parylene-c-coated graphene strips were assembled onto a 20 μm-thick polydimethylsiloxane film, with ~5 mm spacing between each strip. Finally, all the strips were connected in series using conductive copper paste.

Characterization. The phase identification of graphene materials was performed using a Bruker D8 ADVANCE X-ray diffractometer (XRD) with Cu Ka radiation (λ=0.15406 nm). A Joel JEM 2100 F transmission electron microscope (TEM) with a 200 kV field emission was employed to investigate the morphology of the nanoparticles and graphene. X-ray photoelectron spectrometer (XPS) analyses were performed using an Escalab 250Xi spectrometer. The synchrotron X-ray absorption near-edge structure (XANES) was characterized with a Beamline 33BM-C in the XOR Division at the Advanced Photon Sources. The graphitization level of ordered nanoporous graphene was measured using a Jobin Yvon HR 800 confocal Raman spectroscope. The UV-visible absorption spectra of graphene were obtained with a Shimadzu UV-3600 UV-visible spectrophotometer.

Evaluation of the EM dissipation ability of graphene. The temperature-dependent permittivity of graphene was measured using an Agilent N5232 vector network analyzer based on the single-port transmission-line theory. Specifically, a 30 vol % mixture of graphene in silicone resin was pressed into a toroidal ring with an outer diameter of 7.00 mm and an inner diameter of 3.04 mm. The permittivity of the graphene and silicone resin mixture can be calculated as (Lv, H. et al. Prog. Mater. Sci. 127, 100946 (2022)):

log₁₀εₘᵢₓₜᵤᵣₑ=y_{graphene} log₁₀ε_{graphene}+y_{silicon} log₁₀ε_{silicon} (4)

where y_{graphene} and y_{silicon} represent the volume fraction of the graphene and silicone resin, respectively, εₘᵢₓₜᵤᵣₑ, ε_{graphene}, and ε_{silicon} represent the permittivity of the silicone resin/graphene mixture, pure graphene, and pure silicone resin, respectively. After ε_{silicon} was measured, ε_{graphene} was calculated based on Equation (4). The uncertainty in the permittivity measurements is about 10-12% due to variation originating from the sample preparation.

Characterization of the thermal conductivity, electric conductivity, and Seebeck coefficient of graphene. The electric conductivity (σ) of graphene materials was measured according to a four-probe method using a Keithley 4200-SCS electrometer. The thickness of the graphene film was measured using a Tencor profilometer. The surface morphology of the graphene sample was characterized using a Park NX10 atomic force microscope. The graphene's temperature-dependent σ and Seebeck coefficient (S) were measured using an Ulvac-Riko ZEM-3 system. The graphene was hot-pressed into a pellet with a length of ~12 mm and a width of ~3 mm. The thermal conductivity (κ_{T}) of graphene can be calculated as (Zhou, C. J. et al. Nat. Mater. 20, 1378 (2021)):

κ_{T}=DCₚλ (5)

where D is the density, Cₚ is the specific heat value, and λ is the thermal diffusivity. κ_{T} was measured using a Netzsch LFA-467 laser flash system according to the laser flash diffusivity method with a pyroceram disk as reference. In addition, the specific heat values were collected using a Pyroceram 9606 system. Hall carrier concentration was measured using a physical property measurement system. The uncertainty of the electrical-output value is about 15-20% due to the error in σ, κ_{T}, and S measurement. The error of temperature is around 1 K.

Synthesis of graphene with nanopore sizes less than 3 nm. 0.1 g of the bilayer graphene prepared by chemical vapor deposition (CVD) was added to 100 mL of hydrogen peroxide (H₂O₂; 30 wt %) and was ultrasonicated for 30 min. Afterward, the solution was heated to 80 °C and kept at this temperature for 1.2 h under magnetic stirring. Finally, the nanoporous graphene with pore diameters <3 nm was collected using centrifugation and dried at 80 °C for 24 h.

Synthesis of nitrogen (N)-doped graphene. 10 mg of bilayer graphene prepared by CVD was dispersed in 50 mL of distilled water and ultrasonicated for 30 min. Next, 0.8 mL of pyrrole monomer was dissolved in the above graphene dispersion and ultrasonicated for another 30 min. The mixture was transferred to an autoclave and heated at 180 °C for 12 h. N-doped graphene was collected and washed using distilled water, followed by a vacuum drying process at 60 °C for 24 h.

Synthesis of sulfur (S)-doped graphene. 100 mg of thioacetamide (TAA) and 10 mg of bilayer graphene prepared by CVD were dispersed into a solvent mixture consisting of 30 mL of distilled water, and 0.1 mL of H₂O₂ (30 wt %), and 0.1 mL of hydrochloric acid (HCl; 38 wt %).

Next, the solution was transferred to an autoclave and heated at 150 °C for 10 h. S-doped graphene was washed using distilled water and dried at 60 °C for 24 h under a vacuum.

Synthesis of silicon (SiO₂) nanospheres. SiO₂ nanospheres were synthesized using the modified Stöber method (Zhang, C. M. et al. J. Mater. Chem. A 9, 25706-25730 (2021)). Specifically, 2 mL of ammonia was added into a solution mixture containing 5 mL of tetraethyl orthosilicate (TEOS), 50 mL of absolute ethanol, and 50 mL of distilled water. After the mixture was vigorously stirred at room temperature for 1 h, the SiO₂ nanospheres were washed with ethanol and dried in air.

Synthesis of cobalt- and iron-based spindle oxide (CoFe₂O₄ or Fe₃O₄) nanospheres. To synthesize CoFe₂O₄ nanospheres, 1 mmol ferrous chloride (FeCl₂), or cobalt acetate (Co(Ac)₂) and 2 mmol ferric chloride (FeCl₃), were added to 50 mL of ethylene glycol and were stirred for 20 min. Next, 15 mmol urea was added to the above solution. Subsequently, the chemicals were transferred into an autoclave and heated at 150 °C for 12 h. After cooling to room temperature, the products were collected after being washed with distilled water and ethanol and were dried at 80 °C for 10 h.

Iron (II, III) oxide (Fe₃O₄) nanospheres were made through a solvothermal method. Specifically, 1 mmol FeCl₂ and 2 mmol FeCl₃ were mixed into 50 mL of ethylene glycol and stirred for 20 min. Next, 15 mmol of urea was added and the mixture was transferred into an autoclave. The autoclave was then heated at 180 °C for 12 h. After cooling to room temperature, the Fe₃O₄ nanospheres were washed with distilled water and ethanol, and dried at 80 °C for 10 h.

Synthesis of iron oxide@carbon (Fe₃O₄@C) nanospheres. 0.1 g of Fe₃O₄ nanospheres were dispersed into a solution consisting of 60 mL of distilled water, 60 mL of ethanol solution, and 0.8 mL of NH₃·H₂O. Next, the obtained mixture was ultrasonicated for 1 h. Subsequently, 0.4 g of resorcinol and 2 mL of formaldehyde were added to the above mixture and stirred for 24 h. Finally, the formed Fe₃O₄@phenolic resin was heated at 600 °C under a nitrogen flow to obtain Fe₃O₄@C.

Synthesis of zinc oxide (ZnO) nanorods. ZnO nanorods were synthesized using a hydrothermal method (Lv, H. et al. J. Colloid Interface Sci. 450, 381-387 (2015)). First, 0.12 g of zinc acetate and 0.5 g of sodium hydroxide were dissolved in a 10 mL solution of ethanol and water (equal volume). Next, the solution was transferred into an autoclave and heated at 180 °C for 12 h. The ZnO nanorods were collected using centrifugation and washed with distilled water.

Synthesis of cobalt oxide (CoO) nanorods. The CoO nanorods were produced using a hydrothermal method. Specifically, 0.04 mmol of cobalt nitrate (Co(NO₃)₂) was dissolved in a solution of 30 mL water and 15 mL oxalic acid. Next, the solution was transferred into an autoclave and heated at 150 °C for 12 h. After a hydrothermal reaction, the products were separated by centrifugation and washed with distilled water.

Synthesis of silver telluride (Ag₂Te) nanorods. Ag₂Te nanorods were synthesized according to previous research (Zuo, P. et al. J. Phys. Chem. C 112, 14825-14829 (2008)). Specifically, 1 mL of hydrazine (N₂H₄·H₂O) was added into 10 mL of an aqueous solution consisting of 10 mmol silver nitrate (AgNO₃) and 100 mmol ethylenediaminetetraacetic acid disodium (Na₂EDTA). Next, 0.1 mmol of Te powder was added into the above solution. After aging at room temperature for 30 min, the solution was heated to 80 °C for 30 min. Finally, the product was obtained by centrifugation and rinsed with water.

Synthesis of bismuth telluride (Bi₂Te₃) nanoflowers. Bi₂Te₃ nanoflowers were synthesized using a hydrothermal method (Scheele, M. et al. Adv. Func. Mater. 19, 3476-3483 (2009)). Specifically, 0.97 g of bismuth nitrate pentahydrate and 1.20 g of potassium hydroxide were dissolved in 60 mL of ethylene glycol and the solution was stirred for 30 min. Next, 0.38 g of tellurium powder (Te) and 4 g of 1-butyl-3-methylimidazolium bromide were added to the above mixture and then stirred for another 2 h. Subsequently, the solution was transferred into an autoclave and heated at 160 °C for 6 h. Finally, the products were collected through high-speed centrifugation, washed with distilled water and ethanol, and dried in a vacuum oven at 60 °C for 12 h.

Synthesis of molybdenum disulfide (MoS₂) nanoflowers. 0.1 g of sodium molybdate (NaMoO₄) and 0.1 g of thioacetamide (CH₃CSNH₂) were mixed with 50 mL of distilled water and stirred for 20 min. Next, the solution was transferred into an autoclave and kept at 180 °C for 14 h. 2H phase MoS₂ (2H—MoS₂) nanoflowers were obtained after cooling to room temperature.

Synthesis of copper monosulfide (CuS) nanoflowers. CuS nanoflowers were prepared using a hydrothermal method. 1 mmol of copper nitrate (Cu(NO₃)₂), 0.2 mmol of hexadecyltrimethylammonium bromide (CTAB) and 1 mmol of sulfur (S) were mixed into 50 mL of ethylene glycol and stirred for 20 min. Next, the mixture was transferred into an autoclave at 140 °C for 10 h. After cooling to room temperature and washing with distilled water, CuS nanoflowers were obtained.

Synthesis of tin selenide (SnSe) nanoparticles. SnSe nanoparticles were produced via a solution-processing method. First, 0.12 g of stannous chloride (SnCl₂) was dissolved in a solvent mixture consisting of 5 mL of oleylamine and 4 mL of dichloromethane. Next, this solution was heated to 230 °C. After adding 90 mg of 1,3-dimethylimidazoline-2-selenone, the mixture was held at 230 °C for 2 h. After cooling to room temperature, the SnSe nanoparticles were collected through centrifugation and washed with hexane.

Synthesis of lanthanum-strontium-cobalt-based (LaSrCo) perovskite nanoparticles. LaSrCo perovskite nanoparticles were prepared by grinding a mixture of 1 mmol lanthanum oxide (La₂O₃), 1 mmol strontium carbonate (SrCO₃), and 1 mmol cobalt oxalates (CoC₂O₄), followed by heating at 950-1,000 °C for 4 h. After cooling to room temperature, LaSrCo perovskite nanoparticles were obtained.

Synthesis of tin sulfide (SnS) nanoparticles. SnS nanoparticles were synthesized through a hydrothermal reaction. 0.25 g of SnCl₂ was dissolved in 40 mL of ethylene glycol under ultrasonication for 2 h. Next, 0.084 g of thiourea was dissolved in the above solution under magnetic stirring for 1 h. After that, the mixed solution was transferred to an autoclave and heated at 180 °C for 12 h. After cooling down to room temperature, the SnS nanoparticles were collected by centrifugation and washed using distilled water.

Synthesis of iron/manganese dioxide (Fe/MnO₂) and iron/multiwalled carbon nanotube (Fe/MWCNT) composites. Fe/MnO₂ nanorod composites were prepared via a liquid-phase method. First, MnO₂ nanorods were synthesized by dissolving 15 mmol manganese sulfate (MnSO₄) and 10 mmol potassium permanganate (KMnO₄) in 100 mL of distilled water and was stirred for 20 min. Next, the solution was heated to 80 °C for 20 h. After cooling to room temperature, the final product was washed with ethanol under centrifugation and dried in a vacuum oven at 50 °C. Fe/MnO₂ was synthesized through a thermal decomposition process using iron pentacarbonyl (Fe(CO)s) and the obtained MnO₂. Specifically, 0.1 g of MnO₂ was dissolved in 600 mL of kerosene and was ultrasonicated for 20 min. Next, Fe(CO)s was added to the mixture and heated at 180 °C for 6 h in the presence of nitrogen. Finally, Fe/MnO₂ nanorods were washed using ethanol. Fe/MWCNT was synthesized using a similar process by using MWCNTs (15 mg) instead of the MnO₂ rods.

Synthesis of Fe₃O₄/graphene composites. First, 20 mg of pristine (nonporous) graphene was added to 100 mL of glycol, followed by ultrasonication for 30 min. 0.3 mol of FeCl₂ and 0.6 mol of FeCl₃ were added to the mixture. Next, the mixture was stirred for 20 min, transferred to an autoclave, and heated at 140 °C for 24 h. After cooling to room temperature, graphene/Fe-glycolate was obtained by centrifugation and washing with distilled water. Finally, the obtained graphene/Fe-glycolate was heated at 400 °C under nitrogen gas for 2 h to form Fe₃O₄/graphene.

Synthesis of cobalt-iron alloy-coated carbon (CoFe₂@C) composites. CoFe@C was synthesized using a two-step reaction. In the first step, 0.1 mol of Co(Ac)₂ and 0.2 mol of FeCl₃ were mixed into 30 mL of ethylene glycol and stirred for 30 min. Next, 15 mmol of urea was added to the above solution. Subsequently, the mixture was transferred to an autoclave and heated at 200 °C for 12 h. After cooling to room temperature, the precipitate was collected using a magnetic field. In the second step, 0.8 g of the obtained precipitate was dispersed into a solution containing 80 mL of distilled water, 20 mL of ethanol, and 2.1 mL of ammonia under ultrasonication for 1 h. Next, 0.5 g of resorcinol and 3 mL of formaldehyde were added and the mixture was polymerized over 24 h. Finally, the formed brownish precipitate (CoFe₂O₄@phenolic resin) was reduced by hydrogen at 800 °C for 2 h with a heating rate of 5 °C/min.

Synthesis of nickel/nickel oxide (Ni/NiO) composites. Ni/NiO composites were synthesized by a two-step method consisting of a hydrothermal reaction and a subsequent solution reduction (Guo, Y. H. et al. J. Alloys Compd. 731, 143-149 (2018)). In the first step, 120 mg of anhydrous nickel chloride (NiCl₂) was dissolved in 100 ml of distilled water under ultrasonication for 30 min. Next, an ammonia solution was added dropwise to the solution to reach a pH value between 9 and 10. Afterward, the solution was transferred to an autoclave to conduct a hydrothermal reaction at 160 °C for 10 h. The precipitate was collected and dried at 80 °C for 24 h. In the second step, 100 mg of the precipitate was dissolved in 30 mL of distilled water and stirred for 30 min. Next, 15 mL of hydrazine hydrate was added to the solution. After 5 min, the solution mixture was transferred to an autoclave and heated at 150 °C for 20 h. The composites were then obtained by centrifugation and were washed with distilled water.

### Note S1. Analysis of Nonporous, Pristine Graphene

Crystallinity of nonporous graphene. In this work, CVD was used to prepare pristine nonporous graphene with different numbers of layers to synthesize the ordered nanoporous graphene. Inspection of the transmission electron microscope (TEM) images of graphene with different numbers of layers shown in FIG. 12a-FIG. 12d reveals that the surface of all the different graphene structures is smooth without remarkable wrinkles, which is distinct from the surface morphology of graphene made through chemical methods (e.g., Hummer and arc-discharge methods) (Chabot, V. et al. Energy Environ. Sci. 7, 1564-1596 (2014); Dreyer, D. R. et al. Chem. Soc. Rev. 39, 228-240 (2010)). These observations suggest a high crystallinity of the CVD-synthesized graphene. As evidenced in the Fourier transform infrared spectroscopy (FT-IR) spectra (FIG. 12e), all the graphene with different numbers of layers do not exhibit remarkable transmission peaks. In the Raman spectrum shown in FIG. 12f, two broad peaks at ~1,580 (G-band) cm⁻¹ and ~1,350 (D-band) cm⁻¹ are observed, corresponding to the typical in-plane vibration of sp² carbon atoms in a 2D hexagonal lattice and the vibration of sp³ carbon atoms of disordered graphite, respectively (Fang, B. et al. Adv. Maier. 32, 1902664 (2019); Sun, Z. X. et al. Chem. Rev. 120, 10366 (2020)). The ratios of the ID/G values are less than 0.1, which confirms the high crystallinity of graphene prepared through CVD. This high crystallinity with few defects is crucial in ensuring an excellent electric conductivity and a high permittivity of graphene at low electromagnetic (EM) frequencies.

Layers of nonporous graphene. First, the thickness of graphene with different numbers of layers was measured using atomic force microscopy (AFM). As shown in FIG. 13a-FIG. 13d, the thickness of graphene increases with an increase in the number of layers. Specifically, the thickness of the graphene was 0.39, 0.69, 1.09, and 2.31 nm for graphene with 1, 2, 3 and 6 layers, respectively. Furthermore, the 2D peak at around 2,680 cm⁻¹ in the respective Raman spectra was analyzed. With an increase in the number of graphene layers, a significant shifting of the G-band to a low wavenumber, and the 2D peak intensity became weaker than that of the G-band peak was observed (Paillet, M. et al. J. Raman Spectrosc. 49, 8-12 (2017)).

### Note S2. Analysis of the Low-Frequency Relaxation Polarization of Ordered Nanoporous Graphene

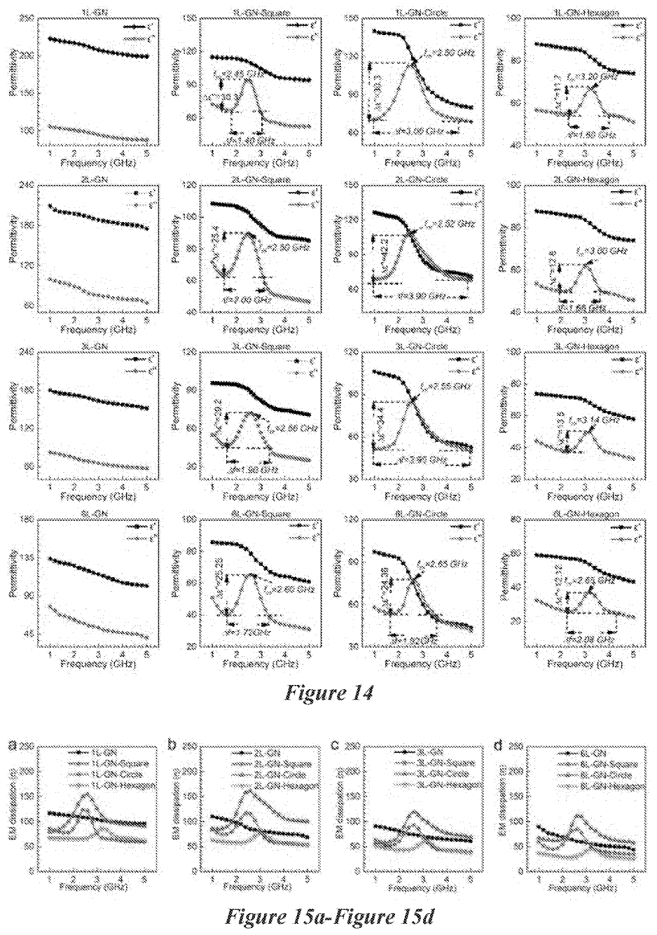

Dipole chemical bonds in ordered nanoporous graphene. The permittivity of graphene as a function of the EM frequency is shown in FIG. 14. For pristine graphene with different numbers of layers, ε′ and ε″ decrease as the EM wave frequency increases from 1 to 5 GHz. For graphene with ordered nanopores, a sharp decrease in s′ was observed, and within the same frequency region, ε″ exhibits a remarkable permittivity resonance peak. The existence of a resonance peak in ε″ suggests a frequency dispersive behavior, which is caused by a dipole relaxation polarization behavior (Bagchi, B. et al. J. Chem. Phys. 90, 7338 (1989); Dou, Y. K. et al. Appl. Phys. Lett. 104, 052102 (2014)). According to the classic Debye theory, when a dipole relaxation polarization behavior occurs, the plot of ε′ as a function of ε″ forms a semicircle, denoted as the Cole-Cole semicircle. The relative complex permittivity can be written as (Zeng, X. J. et al. Carbon 168, 606-623 (2020)):

$${ε}_{r} = {ε}_{∞} + \frac{{ε}_{s} - {ε}_{∞}}{1 + j 2 π f τ} = {ε}^{′} - j {ε}^{″} \qquad ( S1 )$$

where ε_{S}, ε_{∞}, and τ are the static permittivity, relative dielectric permittivity at a high frequency limit, and the dipole relaxation time, respectively. After the separation of real and imaginary parts (Qin, F. et al. J. Appl. Phys. 111, 061301 (2012)):

$${ε}^{′} = {ε}_{∞} + \frac{{ε}_{s} - {ε}_{∞}}{1 + {( 2 π f )}^{2} {τ}^{2}} \qquad ( S2 )$$

$${ε}^{″} = {ε}_{∞} + \frac{2 π f τ ( {ε}_{s} - {ε}_{∞} )}{1 + {( 2 π f )}^{2} {τ}^{2}} \qquad ( S3 )$$

Based on Equations (S2) and (S3), ε′-ε″ can be written as:

(ε′−ε_{∞})²+(ε″)²=(εₛ−ε_{∞})² (S4)

According to Equation (S4), each Cole-Cole semicircle corresponds to one Debye relaxation process. As shown in FIG. 25, the existence of Cole-Cole semicircles in ordered nanoporous graphene suggests a dipole relaxation polarization behavior at low-frequency regions, which was mainly attributed to the polarization of dipoles at the edge of the nanopores. The rearrangement of dipoles at the pore edge with respect to the EM field leads to a dipole relaxation polarization.

To provide insight into the mechanism of low frequency polarization behavior, the crystal structure of graphene was analyzed. X-ray absorption near-edge structure (XANES) characterization in FIG. 26a compares carbon of pristine graphene and carbon of ordered nanoporous graphene. Three peaks at 285.3, 288.3, and 292.1 eV were observed in the XANES spectra. The first two peaks correspond to 1s→π* and π* from graphitized carbon atoms, and the third peak is attributed to 1s→ca* (Rabchinskii, M. K. et. al. Carbon 182, 593-604 (2021)). The unoccupied π* states (i.e., the first two peaks in the XANES spectra) indicate the sp² carbon structure (Liang, X. Q. et al. J. Electron Spectrosc. Relat. Phenom. 196, 89-93 (2014)). As shown in FIG. 26b, the intensity of the first two peaks of ordered nanoporous graphene is lower than that of pristine graphene, suggesting a decrease in the graphene crystallinity due to the presence of the nanoporous structure (Velez, J. J. V. et al. J. Phys. Chem. C 118, 25456 (2014)). In addition, the slope of the peaks in FIG. 26c indicates that carbons with low crystallinity are mainly located at the pore edges rather than in the nonporous regions. To further investigate the effect of the number of graphene layers on the crystallinity, the XANES of C Is of the circularly porous graphene with different numbers of layers was performed. As shown in FIG. 26d-FIG. 26f, a similar slope is observed for all the graphene materials, indicating an ordered distribution of dipoles in the graphene. TEM element mapping, FT-IR, and X-ray photoelectron spectroscopy (XPS) spectra demonstrate that the dipoles in the ordered nanoporous graphene correspond to —C—OH, —C—O, and —C═O bonds.

Analysis of the polarization frequency of ordered nanoporous graphene. Dipole relaxation polarization frequency is affected by the relaxation time (τ) of the dipoles, which is determined by the type and location of dipoles. Typically, dipoles with a large electronegativity difference (Δη) exhibit large dipole moments and thus larger, which enables the polarization relaxation behavior in response to low-frequency EM waves (Wang, H. et al. Appl. Phys. Lett. 101, 083116 (2012)). In ordered porous graphene, the dipoles at the pore edges mainly include —C═O, —C—OH, and —C—O dangling bonds, which have higher electronegativity difference (Δη>1.4) than other carbon-involved dipoles in element-doped graphene (such as Δη=0.5 for C—N, Δη=0.3 for C—P, Δη=~0.1 for C—S, and Δη=~0.3 for C—H). Besides the dipole type, the distribution of dipoles also affects r. Compared with non-dangling dipole bonds, the dipoles located at the edge of the pores on the graphene exhibit a larger dipole moment and thus an increase in τ, resulting in a dipole relaxation polarization behavior at low EM frequency.

Note S3. Polarization Behavior of Graphene with Different Structures

Effect of nanopore size on the polarization behavior of graphene. In this section, a series of graphene with different structures was synthesized to confirm the low-frequency dipole relaxation polarization behavior of the ordered nanoporous graphene. First, bilayer graphene including distorted pores with diameters >20 nm were synthesized by coating excess amounts of nanoparticles on the graphene, as shown in FIG. 28a-FIG. 28b. This obtained graphene, with polydisperse, large nanopores, possesses the same types of dipoles as the ordered nanoporous graphene. As shown in the Raman spectra (FIG. 28c), the G-band of the bilayer graphene with polydisperse, large nanopores is broader than that of the bilayer graphene with monodisperse, 6 nm-in-diameter nanopores, suggesting a decrease in the crystallinity of the graphene caused by the polydisperse, large nanopores. In addition, the graphene with polydisperse, large nanopores shows polarization in a high-frequency region (~11.8 GHz), as shown in FIG. 28d.

Next, graphene with nanopores with diameters <3 nm was synthesized using H₂O₂-assisted chemical etching, as shown in FIG. 28e-FIG. 28f. The dipole types of this graphene with small nanopores were measured to be the same as graphene with monodisperse, 6 nm-in-diameter nanopores, measured using FT-IR (FIG. 28g). In addition, the polarization frequency of graphene with nanopores with diameters <3 nm is located in the medium frequency region (~6.8 GHz), which was still larger than that of graphene with monodisperse 6 nm-in-diameter nanopores, as shown in FIG. 28h.

Effect of dipole type on the polarization behavior of graphene. In this section, the dipole types of graphene were altered using N- and S-doping (FIG. 28i-FIG. 28j). As confirmed in FT-IR (FIG. 28k), C—N and C—S dipoles were formed in N- and S-doped graphene, respectively. In addition, the polarization peaks of both N- and S-doped graphene were located in the high-frequency region (>8.9 GHz), which is consistent with previous studies (FIG. 28l) (Lv, H. et al. J. Mater. Chem. A 9, 19710-19718 (2021); Lv, H. et al. ACS Sustainable Chem. Eng. 6, 1539-1544 (2018)). The polarization frequencies of current EM absorbing composite materials based on graphene lie in the medium- to high-frequency regions, as summarized in Table 2.

Note S4. Tuning the dipole types of graphene using annealing. Here it was sought to tune the dipoles of the ordered nanoporous graphene using a multistep thermal annealing method, as shown in FIG. 29. When annealing the bilayer graphene with circular nanopores at 600 °C for 25 min, the decomposition of C—OH bonds into water and nonpolar C—C bonds was measured, whereas the other two types of dipoles (i.e., C—O and C═O) remained stable. Further annealing at 800 and 1,200 °C, the disappearance of the peaks associated with C—O and C═O in the FT-IR spectra, respectively, was observed. During this annealing process, no remarkable shifts of the dipole peaks were observed as there were no measurable changes to the intrinsic r of the dipoles. Hence, decomposition of the dipoles results in a decrease in the concentration of dipoles in the graphene, leading to a reduction in the polarization intensity.

Note S5. Effect of pore structure on the polarization intensity of graphene. As shown in FIG. 14, with the same number of layers, graphene with circular nanopores exhibits a higher polarization intensity than graphene with square and hexagonal nanopores. It was hypothesized that the high polarization intensity of circularly porous graphene was due to: (i) the concentration of dipoles and (ii) the pore shapes.

Effect of dipole concentration on the polarization of graphene. Considering the fact that all dipoles contain oxygen, the oxygen concentration was used to quantify the concentration of the dipoles in the nanoporous graphene. As shown in XPS, the oxygen concentration in the bilayer graphene with circular, square, and hexagonal nanopores was 13.1 wt %, 15.4 wt %, and 4.9 wt %, respectively. Graphene with hexagonal pores has the lowest oxygen content due to the relatively large pore sizes (16±2 nm) compared with graphene with circular (6±1 nm) and square nanopores (7±1 nm).

Effect of pore shape on the polarization of graphene. According to the polarization mechanism, the polarization intensity depends on the angle between the EM field directions and the dipoles' orientation. A maximum EM energy is required to rotate the dipoles when the EM field and the dipole moment are in parallel. Since the dipoles were located at the pore edges, the intrinsic symmetry of the nanopores affects the dipole relaxation polarization with respect to the direction of the incident EM wave. For circular nanopores, the polarization of the graphene was measured to be independent of the direction of the incident EM wave. For square and hexagonal nanopores, the polarization of the graphene varies as the direction of the incident EM waves changes, according to previous studies (Lou, Z. C. et al. J. Mater. Sci. Technol. 113, 33 (2022)).

Note S6. Calculation of lattice and electron thermal conductivity of graphene. To provide insight into the reduction in the κ_{T} of ordered porous graphene, the lattice (κ_{L}) and electron thermal conductivity (Ce) can be calculated based on the Widemann-Franz relationship (Ao, D. W. et al. Adv. Sci. 5, 2103547 (2022)):

κ_{T}=κₑ+κ_{L} (S5)

κₑ=σ×L×T (S6)

where L presents the Lorenz number that correlates with S:

$$L = 1.5 + ex ( - \frac{\vert S \vert}{116} ) \qquad ( S7 )$$

FIG. 34 shows the relationship of L (in the units of 10⁻⁸ W·Ω·K²) and S1 (in the units of μV·K⁻¹).

Note S7. Molecular dynamics simulation of the thermal conductivity of graphene. In this section, molecular dynamics simulations were performed to study the effect of the pore structure (e.g., pore shape, pore size, and staggered porous structure) and the number of graphene layers on the κ_{T} of porous graphene. The Tersoff potential with an optimized parameter set was used to model graphene, and a reverse non-equilibrium molecular dynamics simulation was applied to calculate the κ_{T} of graphene based on Fourier's law of thermal conduction (Chang, C. W. et al. Phys. Rev. Lett. 101, 075903 (2008)):

J=−κ_{T}∇T (S8)

where J is the heat flux and ∇T is the temperature gradient in the heat flux direction. In this modelling, the initial atomic configuration was equilibrated at T=300 K in a canonical ensemble (NVT) for 20 ps with a time step Δt=1 fs.

After the system reached equilibrium (FIG. 37a), the system is switched to a microcanonical ensemble (NVE) for energy conservation. To create a temperature gradient along the graphene direction, the atoms located at the left end (in a region with a width of 10 Å; highlighted in red) and the right end (in a region with a width of 10 Å; highlighted in blue) were kept at T=350 K (heat source) and T=300 K (heat sink), respectively, by coupling the carbons with a Nose-Hoover thermostat. In the NVE ensemble, the simulation was conducted for 100 ps to allow the system to reach a steady state after applying a temperature gradient along the x direction. After forming the stable temperature gradient in the sample, the simulation was conducted for another 50 ps to obtain the heat flux and the time-averaged temperature profile. To calculate the heat flux, the accumulative energy changes in both the heat source and sink regions were recorded as a function of simulation time, and the energy change rate represents the heat flux. To obtain the temperature profile, the entire system was divided into a series of thin slabs with widths of 10 Å along the x direction, and the temperature of each slab was calculated based on the kinetic energy of all the atoms within the slab.

Effect of pore size on the thermal conductivity of graphene. FIG. 37b shows the atomic configurations of monolayer graphene nanosheets with different pore shapes. In each graphene nanosheet, the pores were arranged into three rows that are separated by a distance, χ, in the x-direction, and the adjacent rows were shifted by a distance equivalent to the size, d, of the pore with respect to each other in they direction. The width of the nanoribbons was defined as the edge-to-edge distance between the two nearest neighboring pores (denoted as ω). The dimensions of the monolayer graphene nanosheet is set as (3χ+30)×2χ×3.4 Å³, in which χ=(d+ω). A periodic boundary condition was applied in they direction, while a free boundary condition was applied in the z direction. Both ends of the graphene nanosheets are fixed during the simulation by freezing the carbon atoms in two thin slabs with a thickness of ~5 Å (highlighted in gray in FIG. 37b).

FIG. 37c-FIG. 37e plots the effect of the pore size and the width co on the ratio of the κ_{T} of monolayer porous graphene nanosheet to the Kr of nonporous monolayer graphene (defined as the Tr ratio). It was observed that the Tr ratio decreases with an increase in the pore size and increases with an increase in the nanoribbon width, which is consistent with past simulation studies of graphene nanomesh (Feng, T. L. et al. Carbon 101, 107 (2016)) and graphene kirigami (Wei, C. et al. Carbon 104, 203 (2016)). These results reveal that the presence of ordered nanopores on the graphene surface leads to a significant reduction of the κ_{T} of graphene (the ratio of κ_{T} is <5%), which is consistent with the experimental measurements. Furthermore, it was observed that an increase in the pore size decreases the κ_{T} ratio for the same pore size. For example, the ratio of κ_{T} of graphene with circular nanopores decreases from 4.8% to 3.1%, with an increase in the pore diameter from 2 to 5 nm.

Effect of pore density on the thermal conductivity of graphene. In addition to the pore diameter, the effect of pore density on the or of graphene was studied by varying ω. In the simulation, the pore diameter was set at 4 nm. As shown in FIG. 37f-FIG. 37h, a decrease in ω, equivalent to an increase in the pore density, reduces the κ_{T} of ordered porous graphene. For example, the ratio of κ_{T} decreases from ~8.2% to ~1.8%, with a decrease in ω from 2.5 to 1.0 nm.

In a nanoporous graphene nanosheet, the main thermal conduction paths are the nanoribbons between two adjacent nanopores and parallel to the heat transport direction. Past molecular dynamics simulations on the nanoribbon of two-dimensional nanomaterials have shown that the edges of the nanoribbons significantly affect their Kr because of the edge localization and boundary scattering effects, both of which arise from the mismatch (or weak coupling) of the phonon density of states of the carbon atoms at the nanoribbon edge and the density of states of the atoms in the nanoribbon (away from the edge) (Wang, Y. et al. Appl. Phys. Lett. 101, 013101 (2012); Guo, Z. X. et al. Appl. Phys. Lett. 95, 163103 (2009); Evans, W. J. et al. Appl. Phys. Lett. 96, 203112 (2010)). It was hypothesized here that the reduction in the κ_{T} of ordered porous graphene is attributed to two mechanisms: (i) weak coupling of phonons at the pore edge and (ii) backscattering of phonons at the pore edges. The first mechanism leads to an enhanced three-phonon Umklapp scattering in parallel nanoribbons, while the second mechanism significantly elongates the phonon transport pathway due to the existence of the perpendicular (or close to perpendicular) nanoribbon (Wei, Z. Y. et al. Carbon 49, 2653 (2011)).

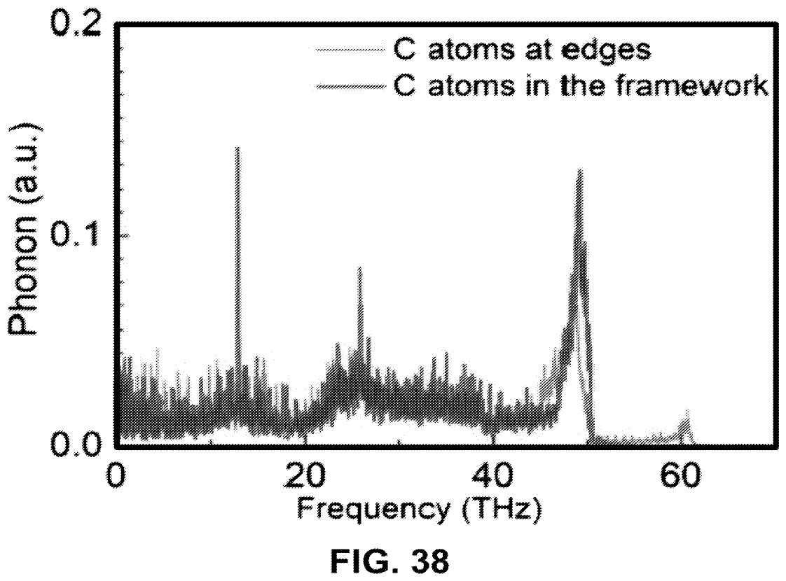

To provide insight into the reduction in the h-r of ordered nanoporous graphene, the phonon density of states of carbon atoms in graphene nanoribbon with armchair and zigzag edges was calculated. As shown in FIG. 3c and FIG. 38, a clear difference between the phonon density of states of carbon atoms at the edge of the nanoribbon and carbon atoms in the nanoribbon (away from the edge) was observed in both types of graphene nanoribbons. Particularly, in the frequency range between 50 and 65 THz, the phonon density of states of carbon atoms in the nanoribbons is negligible, while a peak exists in the phonon density of states of the C atoms at the pore edges. These calculation results suggest that phonons in this frequency range are localized at the edges of graphene nanoribbons and are not able to transport energy as efficiently as the delocalized phonons in the graphene nanoribbons, which is consistent with previous simulation studies that the coupling degree of phonons in graphene nanoribbons is only 0.2 (coupling degree of completely coupled phonons is 1.0).

In addition to the weak coupling of phonons localized at the edge, backscattering of phonons at the pore edges caused by the mismatch in phonon density of states with frequencies lower than 50 THz also contributes to the decrease in the κ_{T} of porous graphene. To provide more evidence, the time-averaged spatial distribution of heat flux on each atom in the ordered nanoporous graphene was calculated using vector arrows after establishing a stable temperature gradient in the graphene. The vector arrows show the transport of heat flux in the porous graphene nanosheets and the associated heat flux transport pathways and the phonon scattering at the pore edges. The atomic heat flux is described using the following equation (Cao, H. Y, et al. Phys. Lett. A 376, 525 (2012)):

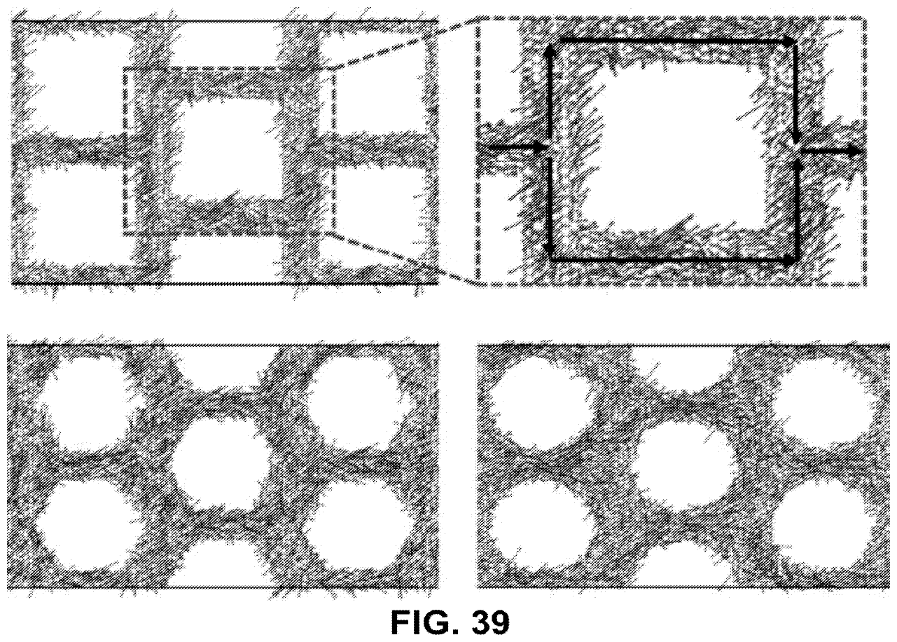

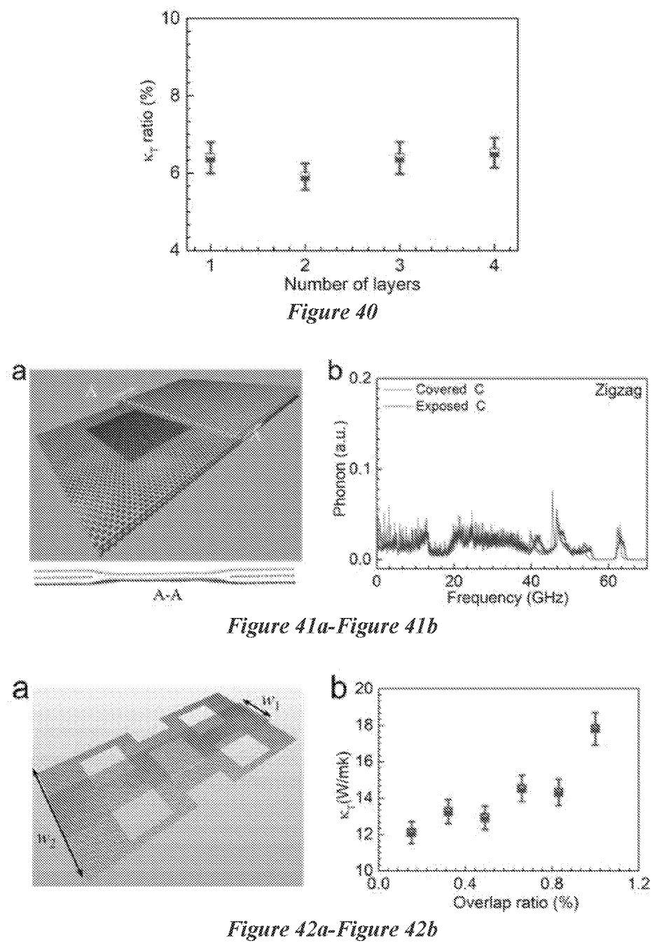

Jᵢ=εᵢvᵢ−Sᵢ·vᵢ (S9)

where εᵢ, vᵢ, and Sᵢ are the atomic energy, the velocity vector, and the stress tensor of atom i, respectively. As shown in FIG. 39, during the propagation of a phonon from the heat source to the heat sink, it is backscattered to change its propagation direction when it encounters a pore edge. This backscattering effect largely reduces the mean free path of phonons and significantly increases the transport pathways of phonons (indicted by the black arrows in FIG. 39) in nanoporous graphene, resulting in a significant decrease in the κ_{T}. For both the weak coupling and the backscattering of phonons at the pore edges, their effects on κ_{T} are related to the edge-to-surface area ratio of the porous graphene nanosheet. The simulation indicates that a high edge-to-surface area ratio leads to a high probability for phonons to be trapped and backscattered at the pore edges. When the pore density and size are set at a constant, the edge-to-surface area ratio of ordered nanoporous graphene is estimated to be 4d: 2\sqrt{3}d: πd=1.27:1.10:1 for square, hexagonal and circular pore shapes, respectively. Therefore, the κ_{T} of graphene with square nanopores was calculated to be the lowest among the different pore shapes.

Effect of the number of graphene layers on the thermal conductivity of graphene. Here the effect of the number of graphene layers on the κ_{T} of the ordered porous graphene was studied. In the simulation, the pore size was kept at 4 nm, the width of the nanoribbons was set at 2.5 nm, and the interlayer distance was set to be 0.34 nm, which is equal to the interlayer distance of bulk graphite. Inspection of FIG. 40 reveals that κ_{T} decreases with an increase in the number of graphene layers, which is consistent with previous studies on the κ_{T} of multilayer graphene nanosheets and graphene nanoribbons (Gho, S. et al. Nat. Mater. 9, 555 (2010)). It has been experimentally and computationally demonstrated that the cross-plane phonon resonance effect (also known as cross-plane phonon coupling) alters the basal plane κ_{T} of multilayer graphene nanoribbons, leading to an enhancement in the three-phonon Umklapp scattering (Li, X. B. et al. Phys. Rev. B 81, 245318 (2010)).

Effect of the staggered pore structure on the thermal conductivity of graphene. In the simulation described above, the graphene nanosheets are completely overlapped with each other in the multilayer graphene. However, in the experiments, a staggered porous structure was observed in multilayer graphene with nanopores. Therefore, the effect of the overlap ratio of graphene layers in four-layer graphene nanosheets with square pores was simulated. The overlap ratio was tuned by shifting the second and fourth graphene layers along they-direction, as shown in FIG. 41a. For simplicity, the distance between the center of mass of the first and fourth graphene layers along the graphene thickness direction (z-axis) was utilized as the overlap ratio. It is difficult to control and determine the overlap ratio of multilayer nanoporous graphene in the experiments. As shown in FIG. 41b, it was observed that the overlap ratio of the graphene layers has a significant impact on the κ_{T} of multilayer graphene. It is hypothesized here that the shifting of the second and fourth graphene layers reduces the screening effect between adjacent graphene layers and reduces the interlayer spacing between graphene, which is consistent with the experimental observations shown in FIG. 36.

Furthermore, the attraction across graphene layers imposes a compression on the whole nanosheet, particularly in areas where the graphene nanoribbons have a high overlap ratio. For multilayer nanoporous graphene nanosheets, the smaller the overlap ratio of two adjacent graphene layers is, the more intense the compression the constitutive graphene layers impose on the whole nanosheet. To provide theoretical support, the distance between the center of mass of the first and the fourth layer of the four-layer porous graphene nanosheet (d₁₋₄) was simulated as a function of the shifting distance of the second and the fourth layer (S₂₋₄). As shown in Table 4, for all S₂₋₄ ranging from 0 to 100 Å, d₁₋₄ is ~1 Å, which is smaller than that of perfectly overlapped graphene nanosheets, except for S₂₋₄=60 Å. At S₂₋₄=60 Å, the shifting distance is equal to the periodicity of the square pores, and the graphene layers are fully overlapped in the same way as S₂₋₄=0 Å. In addition, a five-layer graphene nanosheet with square nanopores was simulated. The difference in distances between the center of mass of the first and the fifth layer (d₁₋₅) of perfectly overlapped graphene nanosheets and partially overlapped graphene was calculated to be ~1.5 Å. This simulation result is in agreement with the experimental measurement that the interlayer spacing between nanoporous graphene with limited numbers of layers was measured to be ~3.2 Å, and it decreases to ~2.9 Å nm as the number of layers increases.

Next, the κ_{T} of the four-layer nanoporous graphene nanosheet was calculated as a function of d₁₋₄. As shown in Table 4, the κ_{T} decreases with a decrease in d₁₋₄. it is hypothesized that this trend can be attributed to an enhanced ross-plane resonance effect and an edge-induced phonon scattering effect in partially overlapped nanoporous graphene. To quantify the enhancement of the edge phonon scattering, the coupling of the phonon spectrum (P₁(ω)) of atoms at the edges of the graphene nanoribbon and the phonon spectrum (P₂(ω)) of atoms in the middle of the graphene nanoribbon is calculated as (Zhu, H. T. et al. Nat. Commun. 9, 2497 (2018)):

Phonon coupling=(∫\sqrt{P₁(ω)P₂(ω)}dω)²/(∫P₁(ω)dω∫P₂(ω))dω) (S10)

When the graphene nanoribbons are partially overlapped, the calculated phonon coupling factor of the graphene nanoribbons with armchair edges is significantly reduced compared with perfectly overlapped graphene nanoribbons, which is similar to that of graphene with zigzag edges, as shown in FIG. 41b and FIG. 3d. A reduction in the phonon coupling factor suggests that the overlapped area of adjacent graphene nanosheets decreases, resulting in an enhanced backscattering of phonons at the pore edges and a decrease in κ_{T} of the graphene nanosheet.

To further validate the second mechanism and obtain the dependence of the thermal conductivity on the overlapping degree, the κ_{T} of a monolayer graphene nanoribbon with periodic pores covered by a defect-free, nonporous graphene nanoribbon was simulated and the overlap ratio between the porous graphene and the nonporous graphene is precisely tuned by adjusting the width of the top nonporous graphene, as schemed in FIG. 42a. The overlap ratio is 0 and 1 for no overlapping and complete overlapping of the pores by the covering graphene, respectively. Inspection of FIG. 42b reveals that as the width of the nonporous graphene increases, the κ_{T} of the porous graphene increases due to the coupling between the atoms at the pore edge of the porous graphene and the atoms in the defect-free, nonporous graphene.

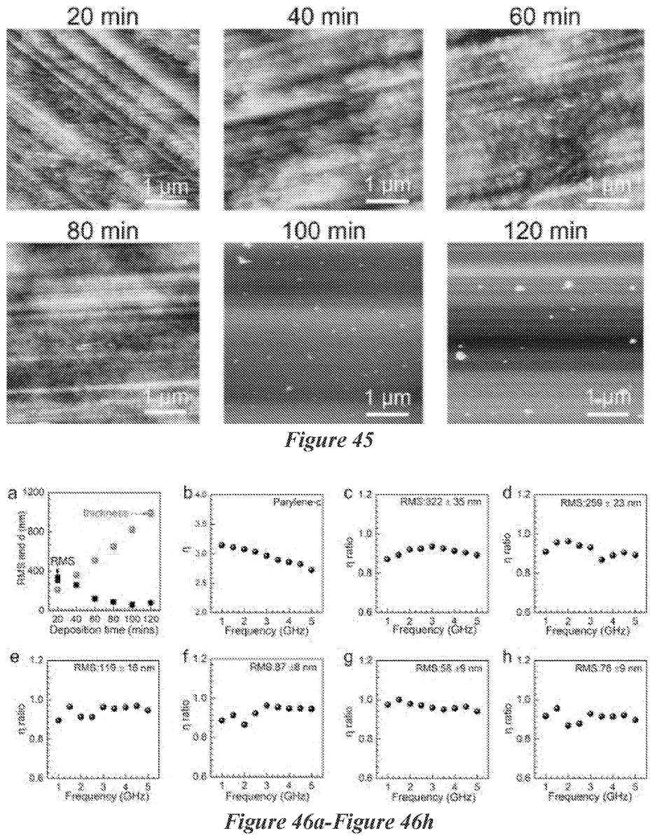

Note S8. Optimization of the thickness of deposited parylene-c films on graphene. Past studies have reported that a nanometer-thick parylene-c coating is a desirable wave-transmission material that enables EM waves to pass through without significant EM energy loss (Lv, H. L. et al. Adv. Funct. Mater. 30, 1907261 (2020)). To create a temperature gradient on each graphene-based strip, one side of the strip was coated using a nanometer-thick, adiabatic parylene-c polymer using CVD, as shown in FIG. 44. However, the deposited parylene-c film may alter the surface roughness of the graphene, which in turn affects the EM dissipation by altering its surface EM wave scattering. The surface roughness and thickness of the parylene-c polymer films was quantified as a function of deposition time using AFM, as shown in FIG. 45. The surface roughness was determined using the root mean square of the surface height profile. As shown in FIG. 46, the thickness of the parylene-c polymer film increases with an increase in the CVD time, and the surface roughness decreases dramatically as the deposition time increases. Furthermore, the EM dissipation ratio of a graphene film before and after deposition of a parylene-c layer was analyzed as a function of EM frequency (1-5 GHz). It was found that at the lowest surface roughness (58±9 nm; the corresponding deposition time was 100 min), the ratio of the EM dissipation factor r of the graphene strips (see Equation 1) with and without a parylene-c layer is ~1.0, whereas the other surface roughness gives rise to EM dissipation factor ratios ranging between 0.8 and 1.0. These results suggest that a 770 nm-thick parylene-c layer has no measurable effect on the EM dissipation of the graphene, which was used in the experiments.

Note S9. Finite element analysis of the temperature profile in graphene. COMSOL was used to simulate the temperature profile of graphene strips as a function of the EM radiation time. In the simulation, the power of the microwave emission was set to 100 W with a frequency of 2.45 GHz and the permittivity, κ_{T}, and Seebeck coefficient of bilayer graphene with circular nanopores were used. The graphene strip was 25 mm long and 5 mm wide, which is the same as the experiments. The temperature profile of the nanoporous graphene with and without the coated parylene-c layer was calculated. As shown in FIG. 3f, upon EM radiation for 300 s, a 1.48 °C/mm temperature gradient was formed between the high-temperature side (parylene-c-coated end) and the low-temperature side (no parylene-c coating). In contrast, the graphene without a coated parylene-c layer did not generate a significant temperature gradient. These computation results are consistent with the experimental measurements (FIG. 50).

Furthermore, FIG. 51 shows the temperature gradient of graphene with one end coated with a parylene-c layer as a function of the EM radiation time. The temperature gradient was calculated to be approximately 1.12, 1.88, 2.44, 1.84, and 1.48 °C/mm for an EM radiation time of 60, 120, 180, 240, and 300 s, respectively, which is in qualitative agreement with the experiments (FIG. 3e).

Next, the temperature gradient, the electric potential, and the associated electricity output of graphene with and without nanopores were simulated as a function of the EM radiation time. The end of the graphene strip without the parylene-c layer was set to be the ground electric potential. As shown in FIG. 64, the nanoporous graphene gives rise to a significant temperature gradient and electric potential between the two ends of the graphene strip, and a maximum electric potential (3.0 mV) was generated at 180 s of EM radiation. In contrast, upon the same EM radiation, nonporous graphene with one end coated with a parylene-c layer generates a small temperature gradient (maximal value is <0.4 °C/mm) and a small electric potential (<0.1 mV).

Note S10. Mechanism for the enhancement in the Seebeck coefficient of graphene. In general, the absolute value of the Seebeck coefficient |S| is affected by the carrier concentration, effective mass, and electronic structure.

Effect of carrier concentration on the Seebeck coefficient of graphene. The carrier concentration (n) was measured as a function of the temperature via a Hall carrier measurement. As shown in FIG. 53a-FIG. 53d, compared with nonporous graphene, the presence of pores reduces n by 37.9-57.6%, which contributes to the enhancement in |S| of porous graphene.

Effect of the effective mass on the Seebeck coefficient of graphene. In general, the effective mass (m*) is proportional to |S| and can be qualitatively determined by its inverse proportional relationship to the mobility (μH) (Zhu, H. T. et al. Nat. Commun. 270, 10 (2019)). The μH can be calculated as (Blackburn, J. L. et al. Adv. Mater. 11, 1704386 (2018)):

μH=σ/ne (S11)

where σ is the electric conductivity, and e is the electronic charge (1.6×10⁻¹⁹ C). The calculated pH of both the porous and nonporous graphene is shown in FIG. 53e-FIG. 53h. It was found that the creation of nanopores on the graphene surface will significantly reduce the PH of graphene due to the decrease in the electron transport path. For example, the pH of bilayer graphene with circular nanopores is 55.2-72.7 cm²/V·s, which is 56.0-72.3% of that of bilayer nonporous graphene. The decrease in the pH value indicates an increase in m*, which is beneficial to the absolute |S| value.

Effect of electronic structure on the, Seebeck coefficient of graphene. The SI value of graphene can also be tuned via the electronic structure of graphene, including the Fermi surface, energy band structure, and bandgap value (Xu, S. D. et al. Prog. Mater. Sci. 121, 100840 (2021)). The role of the Fermi surface and energy band structure was discussed in the section of the density functional theory simulation (see Note S11). Nonporous graphene has a zero bandgap value and a negligible |S|. Here it was sought to study the effect of nanopores on the bandgap value of ordered porous graphene. The converted UV-visible diffuse reflectance curves of ordered porous graphene shown in FIG. 54 demonstrate the open bandgap structure (semiconductor behavior) of ordered porous graphene. Specifically, the bandgap values were 0.75, 0.85, and 0.48 eV for monolayer graphene with square, circular, and hexagonal nanopores, respectively. As the number of layers increases, the bandgap value of graphene with circular nanopores decreases from 0.85 to 0.23 eV.

Overall, the enhanced |S| of graphene with ordered nanometer-sized pores is due to a reduction in n, an increase in m*, and the open bandgap structure, although the quantitative relationship between the bandgap value and S1 has yet to be understood.

Note S11. First principle density functional theory simulation of the electron structure of graphene. In this work, first principles density functional theory was used to simulate the band structure of graphene. The simulation includes crystal model design and optimization, the building of a static self-consistent field, and a density of states calculation. All calculation steps are completed in VASP-6.1.0 (Hafner, J. et al. J. Comput. Chem. 29, 2044 (2008)), combined with the Perdew-Burke-Ernzerhof (PBE) functional (Perdew, J. P. et al. Phys. Rev. Lett. 77, 3865-3868 (1996); Kresse, G. et al. Phys. Rev. B. 59, 1758 (1999)) under the generalized gradient approximation (Becke, A. D. et al. J. Chem Phys. 104, 1040 (1996)). The frame of density functional theory with D3 dispersion correction (Grimme, S. et al. J. Chem Phys 132, 154104 (2010)) is combined with the projector augmented wave (Blochl, P. E. et al. Phys. Rev. B 50, 17953 (1994)), and the plane wave cut-off energy was set to 500 eV. The K point adopts the density of 3×3×1. The finite displacement method combined with phononpy-2.11 (Togo, A. et al. Scrip. Mater. 108, 1-5 (2015)) was used to calculate the phonon structure of graphene. The temperature-dependence of |S| was calculated using BoltzTraP-1.2 (Madsen, G. K. et al. Comp. Phys. Commun. 175, 67 (2006)). Herein, graphene was studied with three structure models: i) monolayer graphene with a single 1.2 nm-size circular or square pore at the center of the surface; ii) bilayer graphene with a 1.2 nm-diameter circular pore on each graphene layer that have different overlap ratios (complete overlap and ⅓ overlap); and iii) trilayer graphene with a circular pore on each graphene layer that has a ⅓ overlap ratio with respect to the other two layers. The carbon atoms at the pore edge were saturated by —H, —OH, ═O, and —O—.

Effect of the number of graphene layers on the electron structure of graphene. To study the effect of the number of layers, the electron structure of bilayer and trilayer graphene with circular nanopores at the same overlap ratio (⅓) were compared. Both graphene structures shifted the Dirac points away from their original position (Dirac points of a pristine, nonporous graphene are located on G, M, and K) to the regions between G-M and K-G, and split the Dirac points, resulting in an open bandgap structure and the breaking of the Fermi surface (the Dirac trap effect). The bandgap value of trilayer graphene with circular nanopores is ~0.33 Ev, smaller than that of bilayer porous graphene, suggesting a weak electron confinement ability of trilayer nanoporous graphene. In addition, the calculated projection density of states of trilayer nanoporous graphene shows that the intensity of the density of states near zero density of states is weaker than that of its bilayer counterpart, suggesting a weak interaction intensity between phonons and electrons (phonon drag effect). As a result, |S| of trilayer graphene with circular nanopores is lower than that of its bilayer counterpart.

Effect of pore overlap ratio on the electron structure of graphene. The electron structures of bilayer porous graphene with different overlap ratios were computed. A splitting of the Dirac points was observed in all the bilayer porous graphene, and bilayer porous graphene with an overlap ratio of ⅓ has the largest bandgap value (0.34 Ev). This result suggests that bilayer graphene with completely overlapped pores has a weak ability in electron confinement. Furthermore, there was no significant van Hoff singularity point nearing the zero density of states in bilayer graphene with completely overlapped pores, suggesting a weak phonon drag effect.

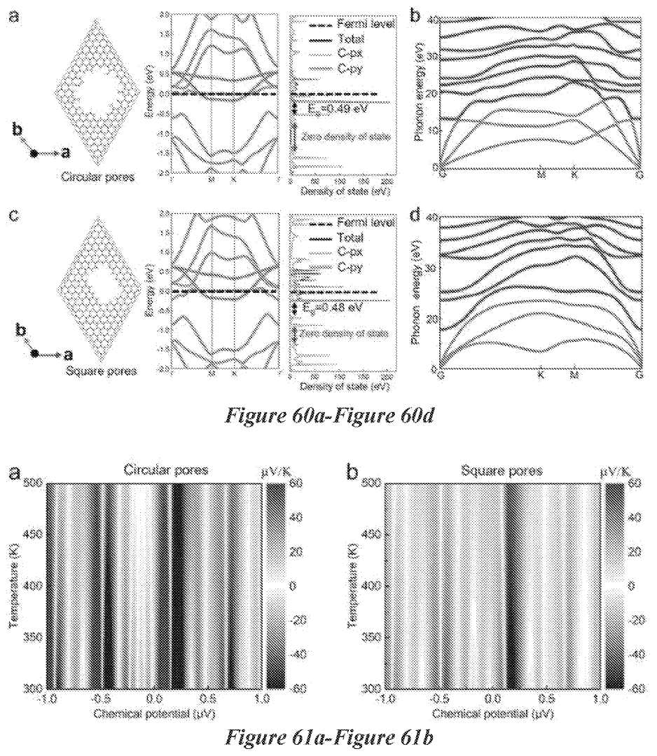

Effect of pore shape on the Seebeck coefficient of graphene. To reveal the effect of pore shape on |S| of graphene, the electron structure of graphene with circular and square nanopores was calculated. To exclude the interference of a staggered porous structure, monolayer porous graphene was simulated. As shown in FIG. 60, monolayer graphene with either circular or square pores shows a similar distribution of density of states, suggesting a similar electron structure in these two types of monolayer graphene. However, it was found that the first phonon curve of monolayer graphene with circular nanopores was located at a lower frequency compared with monolayer graphene with square nanopores. In addition, the inflection point of the phonon curve of monolayer graphene with square pores appears at the M point, whereas the acoustic fulcrum point of monolayer graphene with circular pores is located in K and K→G. In monolayer graphene with circular pores, the inflection point of the low frequency and high frequency acoustic branch phonons form a parabolic phonon pocket, which greatly enhances the Seebeck effect of monolayer graphene with circular pores. These results lead to a conclusion that a difference in the phonon bands, rather than the electron bands, gives rise to different |S| of graphene with different pore shapes.

Note S12. Effect of EM interference on graphene. Upon EM radiation, the formed temperature gradient and the associated electrical potential drive the movement of electrons from the high temperature end to the low temperature end. In addition to the temperature gradient, the surrounding EM field may deviate from the movement of electrons from the direction of the temperature gradient in the graphene. As a result, it may decrease the effective electric potential. To quantify the effect of EM interference, the electrical potential of ordered nanoporous graphene generated by EM radiation was compared with that generated by applying an equivalent temperature gradient. As shown in FIG. 63a, the ratio of electric potential generated by EM radiation and that generated by applying a temperature gradient is 86.7-96.3%, indicating that the impact of EM field interference is not severe in ordered porous graphene. In contrast, this ratio is 38.5-45.1% in nonporous graphene (FIG. 63b), suggesting the presence of a remarkable EM field interference in nonporous graphene. These experimental observations are supported by the finite-element simulation shown in FIG. 65a-FIG. 65b.

It was hypothesize that the EM interference intensity is caused by three factors: i) EM field direction, ii) low frequency polarization behavior, and iii) ordered nanopore structure.

Effect of EM field direction. To address the effect of the EM field direction, finite-element simulations of the electric potential of the nonporous graphene upon EM radiation in a fixed direction were performed. Inspection of FIG. 65c reveals that the EM field perpendicular to the temperature gradient gives rise to the most severe EM interference.

Effect of low frequency polarization behavior. In general, the types of EM dissipation include polarization relaxation loss and conductive loss. In nonporous graphene, the EM dissipation is dominated by conductive loss caused by the non-directional movement of carriers, during which the resistance or collision of the moving carriers is dissipated into heat. However, in ordered porous graphene, the dominating EM dissipation type is the polarization relaxation loss, which relies on the dipole relaxation to dissipate EM energy into heat, rather than conductive loss. The presence of nanopores reduces the non-directional movement of carriers and thus efficiently decreases the polarization relaxation loss.

Effect of the ordered nanoporous structure. Ordered porous graphene includes carbon atom regions among nanopores, which are equivalent to graphene nanoribbons. It was hypothesize that the electrons can directionally transport in the regions among the nanopores, which decreases the random movement of electrons and thus conductive loss, as shown in FIG. 66.

### Note S13. Electric Energy Output by Ordered Nanoporous Graphene

Internal resistance of ordered nanoporous graphene. Here the EM wave radiation-induced electric energy output by ordered nanoporous graphene with a loaded resistance ranging from 0-150Ω was measured. As shown in FIG. 67a, with the same loaded resistance, the output voltage (V_{L}) reaches a maximum at 180 s of EM radiation. Based on L, the output power was calculated as a function of the resistance, as shown in FIG. 67b. The maximum output power was found to be ~1.51 Mw with a resistance of 60Ω after an EM radiation of 180 s. The graphene-based device has an internal resistance of 60Ω (10Ω for each graphene stripe).

Electric power output as a function of time. Based on the results shown in the previous section (maximum V_{L} at 180 s of EM radiation), ΔT was measured as a function of time during 180 s of EM radiation. It was found that ΔT increases in the first 180 s of EM radiation and decreases to zero within 180 s upon the removal of the EM radiation, as shown in FIG. 5d. The time-dependent power output can be calculated as:

Wₒᵤₜ=Pₒᵤₜ×t (S12)

where t is the time, and Wₒᵤₜ and Pₒᵤₜ are the output work and output power, respectively. According to Equation (S12), the output work of graphene is calculated to be 2.3 Mj within 360 s.

Output work of graphene-based devices at elevated temperatures. Considering the fact that the temperature of the electronic device can increase during usage (Zhang, M. et al. Mater. Sci. Eng. R 145, 100627 (2021)), here it was sought to investigate the effect of the temperature on Wₒᵤₜ of the graphene-based devices. As shown in FIG. 68-FIG. 69, Wₒᵤₜ of the graphene-based devices remains almost constant over a wide temperature range from 10 to 70 °C.

Note S14. Analysis of the flexibility of graphene-based devices. Here the flexibility of the graphene-based devices during electricity output was studied. After bending the device, the maximum output power (Pₘₐₓ) of graphene-based devices was measured. As shown in FIG. 70, no significant reduction in Pₘₐₓ was observed after bending the device 500 times at different bending angles. Further characterization has shown that the σ of the device remains stable over a wide range of bending angles and bending times (FIG. 71), revealing an excellent flexibility of the graphene-based devices. The intrinsic flexibility of graphene-based devices outperforms inorganic materials such as SnSe, Ag₂Te, and Bi₂Te₃ and conventional EM dissipation material-based devices (Chen, Z. G. et al. Prog. Mater. Sci. 97, 283 (2018); Hu, H. P. et al. J. Mater. Sci. 10 Technol. 91, 241 (2021); Scheele, M. et al. Adv. Funct. Mater. 19, 3476 (2009)).

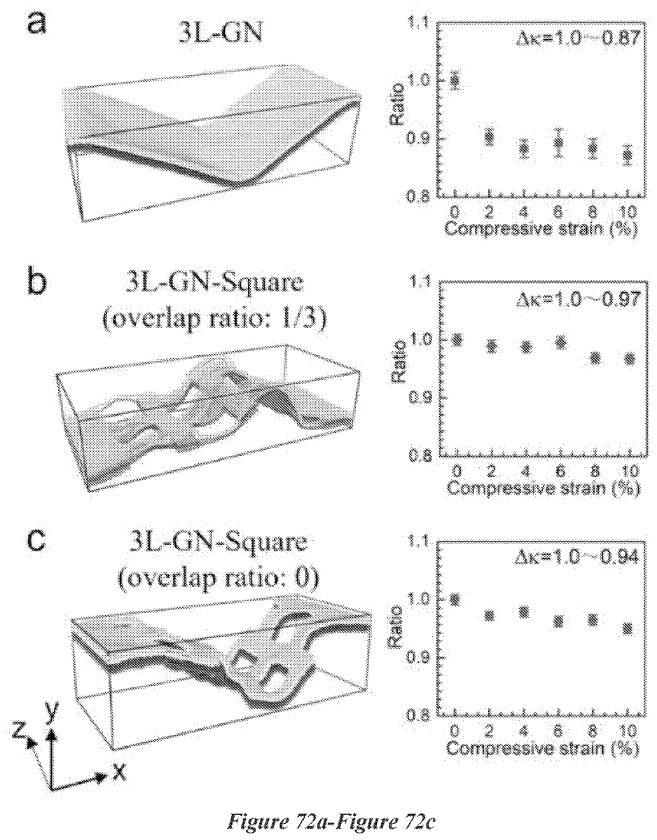

Note S15. Molecular dynamics simulation of the thermal conductivity of graphene-based devices after bending. Here it was sought to investigate the effect of the bending on the κ_{T} of the graphene-based device. In the modelling, a compressive strain was imposed on the graphene-based devices in the heat flux direction, which caused the graphene surface to wrinkle. FIG. 72 shows the κ_{T} of the four-layer nanoporous graphene nanosheet with either complete overlapping or partial overlapping, with a shifting distance S₂₋₄ of 80 Å (which exhibits the lowest κ_{T}). In addition, the κ_{T} of a four-layer nonporous graphene nanosheet under a compressive strain was calculated. It was found that the κ_{T} of both porous and nonporous graphene nanosheets decreases upon applying a compressive strain. Past research has reported that the bending-induced reduction in κ_{T} of graphene is attributed to the severe Umklapp phonon scattering occurring at the locations of the crests and troughs of the wrinkled graphene (Li, X. B. et al. Phys. Rev. B 81, 245318 (2010)). In addition, it has been reported that at these highly curved locations, strong phonon localization effects lead to a significant suppression in the phonon lifetime and thus reduce the κ_{T} of graphene (Cui, L. et al. J. Phys. Chem. C 120, 23807 (2016)).

Furthermore, it was observed that the reduction of κ_{T} of the completely overlapped porous graphene is less than that of partially overlapped porous graphene. It was found that, upon a 10% compressive strain, the wrinkle height of completely overlapped porous graphene (66.56 Å) is larger than that of partially overlapped porous graphene (58.17 Å). This larger wrinkle height in the perfectly overlapped graphene is due to its high in-plane stiffness, which is caused by its larger effective thickness characterized by the distance d₁₋₄ in Table 4. This analysis leads us to conclude that the compression induces the formation of wrinkles on the graphene, resulting in enhanced phonon localization and scattering and thus a reduction in x-r.

### Example 2—Electromagnetic Wave Harvester and Electricity Generator

Communication. 5G (the 5^{th} generation of mobile technologies) is an evolution from the previous generations of mobile technology (e.g., 2G, 3G, and 4G). 3G, 4G, and 5G networks product radio-frequency electromagnetic fields which are used to transmit information. A summary of the band frequencies of 3G, 4G, and 5G networks is shown in Table 8. The work herein focuses on the 3G-5G electromagnetic wave frequency region.

TABLE 8
Band frequencies of 3G, 4G, and 5G networks.

| | 3G | 4G | 5G |
|---|---|---|---|
| Band | (GHz) | (GHz) | (GHZ) |
| 1 | 1.71-1.78 | 1.88-1.90 | 3.30-3.40 |
| 2 | 1.88-1.90 | 2.32-2.37 | 3.40-3.60 |
| 3 | 2.01-2.02 | 2.57-2.63 | 4.80-5.00 |

Electromagnetic (EM) Pollution. Despite extensive studies into the health effects of mobile phones and base stations over the last decades, there is no indication of an increased health risk when exposed to electromagnetic fields below ionizing levels. However, there are still some potential adverse effects such as interference and overheating.

Described herein are compositions, devices, and systems that can harvest such excess or unwanted electromagnetic waves and directly convert it into electricity.

Nanomaterial design—electricity from EM energy. The strategy for the design of the materials described herein is based on concepts (I) and (II) below. Additional material properties that can be beneficial are that it is low-cost, lightweight, and flexible.

### (1) EM Radiation Absorption Step:

W=D·E²·f·η (1)

η=εᵣ·tan δ_{E}=εᵣ·ε″/ε′ (2)
D: EM absorber dimension (surface area);
E: EM field strength
f: EM wave frequency;
η: EM dissipation energy;
εᵣ: relative complex permittivity;
tan δ_{E}: the dielectric tangent loss (ε″/ε′)

### (II)

ZT=σS²T/κ_{T} (3)
ZT: dimensionless thermoelectric figure of merit;
S: Seebeck coefficient;
σ: Electrical conductivity;
T: Absolute temperature;
κ_{T}: Thermal conductivity.

Graphene based composites have been used as EM absorbing materials due to their desirable EM dissipation energy (η) value. However, graphene is a poor thermoelectric material owing to its high thermal conductivity (κ_{T}) and low Seebeck value (S), and thus a low ZT value.

Graphene can be viewed as monolayer graphite. Graphene comprises carbon atoms arranged in a honeycomb network. Graphene has a high conductivity (e.g., up to 10⁶ S/cm), high thermal conductivity (~5000 W/mK), and excellent mechanical properties. Graphene can also be a zero-bandgap semiconductor.

There are various physical methods that have been investigated for tuning the electron structure of graphene, such as i) rotating graphene (Cao et al. Nature, 2019, 80, 556), and ii) physical field tuning (Yazyev et al. Nat Mater 2010, 9, 806). Methods based on graphene rotation mainly focus on superconductivity. Methods based on physical field tuning use electric fields to tune the properties of graphene. Both techniques have resulted in a bandgap of only about 0.1 eV.

There are also various chemical methods that have been investigated for tuning the electron structure of graphene, such as i) defect engineering (e.g., doping, lattice vacancy) (Yazyev et al. Nat Mater 2010, 9, 806), and ii) structural engineering (Kosynkin et al. Nature, 2009, 458, U872). Methods based on defect engineering, including doping with S, P, etc., have resulted in a bandgap up to 2.0 eV, but to date have provided poor control of the position and type of defects. Methods based on structural engineering include fabrication of nanoribbons and have provided a bandgap up to 1.0-2.0 eV, but the nanoribbons are hard to synthesize and it is further hard to precisely control the nanoribbon edge atomic structure.

There have also been past studies on porous graphene (Strauss et al. Adv. Mater. 2018, 1, 1704449; Wang et al. Nanoscale. Mater. 2014, 13, 6577; Kim et al. Nano. Res. Mater. 2020, 13, 1403). While they have provided a bandgap of 0-3.0 eV, they have provided poor control of the pore structure.

The materials herein are designed to provide ordered porous graphene. Porous graphene can open the bandgap and turn semiconductive, which attributes to the Seebeck value (S) and consequently the ZT value. Accordingly, ordered porous graphene can balance thermal conductivity (κ_{T}) and electric conductivity (σ) by controlling the density of the pores as well as the pore size.

Upon radiating pieces of the porous ordered graphene with EM waves with a frequency of 2.45 GHz using a homemade EM emitting cavity with a 100 W magnetron, the porous ordered graphene materials were able to directly generate electricity.

### Example 3—Direct Current Generation by Recycling Omnipresent Electromagnetic Waves

Wearable electronics, which integrate a power source, sensors, data processing and storage core, actuators and displays in a small, lightweight device, are worn on the body to or integrated with everyday wear items, such as clothing, footwear, or accessories. Availability of power is one of the most important limiting factors in modern wearable electronics, and development of a strategy for efficient power conversion and energy harvesting is highly desirable. Concurrently, the breakthrough in information and communication technology has led to an astronomical rise in electronic device usage, which relies on transmitting signals via electromagnetic (EM) waves (for example, emerging 5th Generation wireless communication).

This increase in the use of electronic devices has resulted in an increased release of EM wave into the surrounding environment causing EM pollution, which is ranked the fourth source of environmental pollution next to air, water, and noise. Therefore, harvesting the ubiquitous and unwanted EM waves from high power, wireless electronic devices such as microwave ovens, network servers, and wireless ports and converting it to useful direct current (DC) electricity to power or charge wearable and flexible electronics is an attractive concept. Herein, material design strategies to harvest and convert ambient EM energy into DC electricity are described.

EM absorption—thermoelectric synergy. A multifunctional graphene based-material design possesses the following features: (a) high EM absorption (i.e., converting EM wave to thermal energy), (b) excellent thermoelectric effect (i.e., converting thermal energy to electricity), and (c) light weight and stretchable. Unlike the commonly used inorganic thermoelectric materials (for example, Bi₂Te₃ and SnSe), graphene has a potential for efficient low temperature (<100 °C) heat-to-electricity conversion. Rationally designed highly ordered and well-defined nanopores on single and multilayer graphene sheets can: (1) harvest the freely available EM wave from ambient environment, (2) convert the EM wave energy to thermal energy, and (3) convert the thermal energy to useful DC electricity. To achieve this two-stage conversion, the carbon-carbon covalent bonds are manipulated by introducing ordered nanopores on graphene. Nanopores are created on the graphene to introduce the defects at the pore edge, which can serve as the dipoles to the convert external EM field to joule heat. Furthermore, the existed defects can locate the carriers and result in numerous impendent Femi-energy surfaces. As a result, the carriers only transport in their Femi surface, resulting in an open-bandgap electronic structure that improves the Seebeck coefficient. Meanwhile, molecular dynamic simulations shows that the edge defects enhance the phonon scattering and lead to an ultralow thermal conductivity. Specially, in the porous graphene nanosheets, the main thermal conduction channels are the nanoribbons between two neighboring nanopores. Due to the enhanced Seebeck coefficient and ultralow thermal conductivity, graphene with porous structures possesses the desirable conversion ability from the thermal energy to the useful DC electricity. Results have demonstrated that a porous graphene-based device can output a power density of ~0.3 W/m² by harvesting the EM waves emitted from a 100 W microwave.

### Example 4—A General Chemical Approach for the Synthesis of Nanoporous Graphene Superlattices

Abstract. Two-dimensional (2D) superlattices, formed by stacking sublattices of 2D materials, have emerged as a powerful platform for tailoring and enhancing material properties beyond their intrinsic characteristics. However, conventional synthesis methods are limited to pristine 2D material sublattices, posing a significant practical challenge when it comes to stacking chemically modified sublattices. This limitation hinders the synthesis and application of highly functional 2D superlattices. Herein, a chemical synthesis method is reported that overcomes this challenge by creating a unique 2D graphene superlattice, stacking graphene sublattices with monodisperse, nanometer-sized, square-shaped pores and strategically doped elements (such as H, B, N, O, P, S, Se, and Te) at the pore edges. The resulting graphene superlattice structure exhibits remarkable correlations between quantum phases at both the electron and phonon levels, leading to a diverse range of properties and functionalities that surpass those observed in pristine graphene, including low-frequency dielectric relaxation, ultralow thermal conductivity, high Seebeck coefficient, low infrared emissivity, and photoluminescence. The exceptional performance of this graphene superlattice is demonstrated across various applications, such as electromagnetic shielding, energy harvesting, optoelectronics, infrared stealth, and thermoelectrics in the low-to-intermediate temperature range. This methodology enables the creation of superlattices using various conventional 2D materials, expanding the materials' range with tailored properties and diverse applications, while also highlighting their significant utility compared to pristine counterparts.

Introduction. Two-dimensional (2D) superlattices, composed of stacked sublattices from 2D materials, have emerged as a robust platform for engineering materials with unique and tailored properties not presented in intrinsic materials (Zhou J et al. Nature 2022, 609, 46-51; Kim H et al. Nature 2022, 606, 494-500). The structural and compositional heterogeneities in 2D superlattices result in strongly correlated electronic and phonon phenomena, encompassing diverse quantum phases (Chen D et al. Nat. Phys. 2022, 18, 1171-1176). A notable example is the graphene Moiré superlattice, achieved by stacking graphene layers with precise control of twist angles or lattice misalignment degrees (Septianto R et al. Nat. Commun. 2023, 14, 2670), leading to phenomena such as metal-insulator transition, ferromagnetism, anomalous quantum Hall effect, nematicity, and tunable Wigner crystal and Mott insulating states (Weston A et al. Nat. Nanotechnol. 2022, 17, 390; Pantaleon P A et al. Nat. Rev. Phys. 2023, S, 304-315; Turkel S et al. Science 2022, 376, 193-199: Zhang S et al. Nat. Mater. 2022, 21, 621). Current research on 2D superlattices predominantly focuses on the growth and stacking of pristine 2D material sublattices, by periodically stacking different sublattices or through misaligned stacking of identical sublattices, using techniques like molecular beam epitaxy, chemical vapor deposition, or atomic layer deposition (Liu C et al. Nat. Mater. 2022, 21, 1263; Huang T Y et al. Nature 2022, 605, 63; Shen C et al. Nat. Mater. 2023, 22, 316; Merida J D et al. Nat. Commun. 2023, 14, 2396; Zhang Y et al. Nat. Nanotechnol. 2023, 18, 501). However, the synthesis of 2D superlattice structures composed of chemically modified 2D material sublattices, such as those incorporating periodic vacancies or pores, presents a significant challenge (Chio S H et al. Nat. Commun. 2022, 13, 1484). In particular, the exploration of 2D superlattice structures in nanoporous graphene, a prominent member of chemically modified 2D materials with unique functionalities and potential applications (Xu F et al. Sci. Adv. 2022, 8, eabm7489; Cui J et al. Nano Leit. 2021, 21, 2156-2164), remains largely unexplored.

In this study, a chemical approach is presented for the fabrication of a family of 2D superlattice structures by stacking graphene with monodisperse, nanometer-sized, square-shaped pores as sublattices to introduce additional degrees of freedom for tailoring the electronic and phonon structure of the superlattice. By employing in-situ growth and etching of cubic-shaped metal oxide nanoparticles on the graphene surface, a high density of monodisperse square nanopores was achieved. Compositional periodicity is also generated with selective doping of the pore edges with specific elements. Theoretical analysis indicates that the 2D superlattice structure induces a reconstruction of the electronic and phonon structures of graphene, leading to a flattened electronic band, the emergence of a phonon bandgap, and a significant electron-phonon coupling. As a result, the graphene superlattice exhibits unique properties, such as low-frequency dielectric relaxation, low thermal conductivity, low infrared emissivity, enhanced Seebeck effect, and photoluminescence effect, making it an attractive material for various applications including electromagnetic (EM) wave modulation, energy harvesting, thermal management, optoelectronics, and thermoelectrics. The synthesis strategies presented in this study offer a foundation for the development of superlattices by stacking nanoporous 2D materials, paving the way for the design of 2D superlattices with tunable properties and unprecedented functionalities compared to pristine counterparts.

### Results

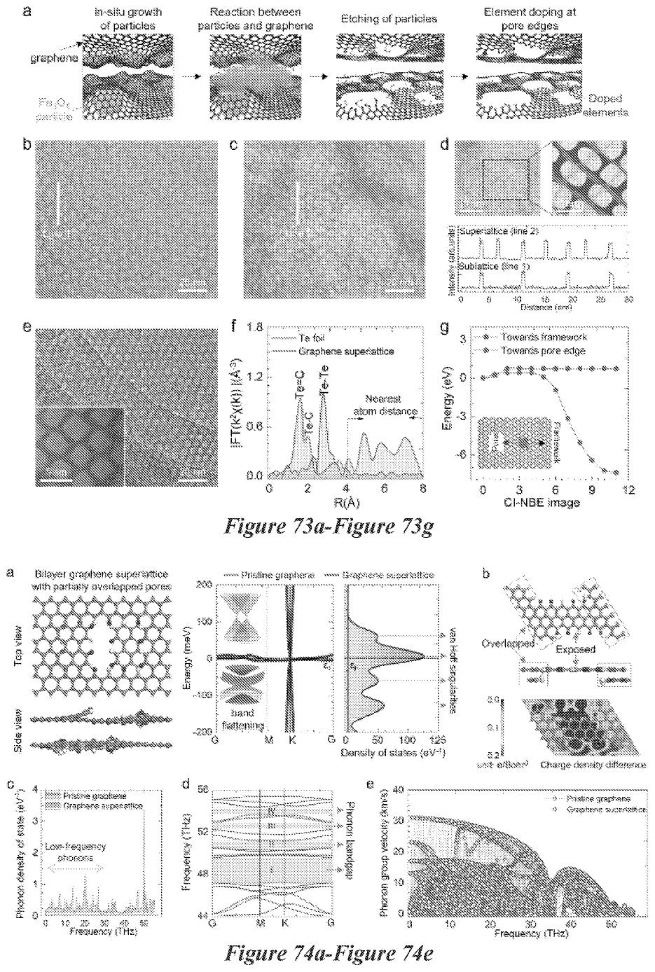

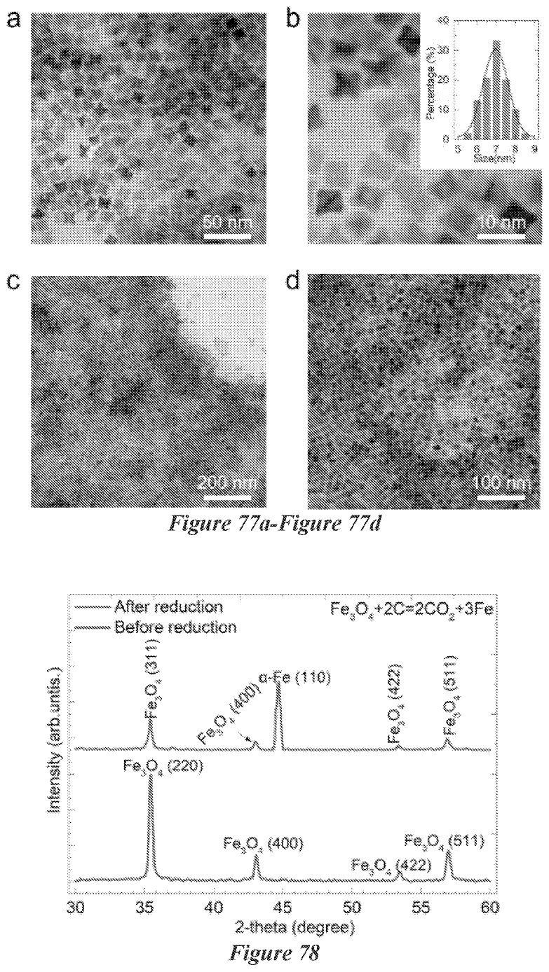

Synthesis of porous graphene superlattices. Graphene sublattices were created through the creation of a high density of monodisperse, square-shaped, nanometer-sized pores on graphene. The process involves three steps, as illustrated in FIG. 73a: (i) in-situ growth of cubic iron oxide nanoparticles (Fe₃O₄) template on the graphene surfaces (FIG. 77a-FIG. 77d); (ii) in-situ etching the carbon atoms via the reduction reaction between graphene and Fe₃O₄ nanoparticles; and (iii) removal of Fe₃O₄ nanoparticle templates by hydrochloric acid (see Methods). X-ray diffraction (XRD) confirmed the phase evolution of carbon upon reduction (FIG. 78). Representative transmission electron micrographs in FIG. 73a demonstrate the resulting monolayer graphene possessing monodisperse, square nanopores with an average size of 7.1±0.8 nm, same as the size of cubic Fe₃O₄ nanoparticles.

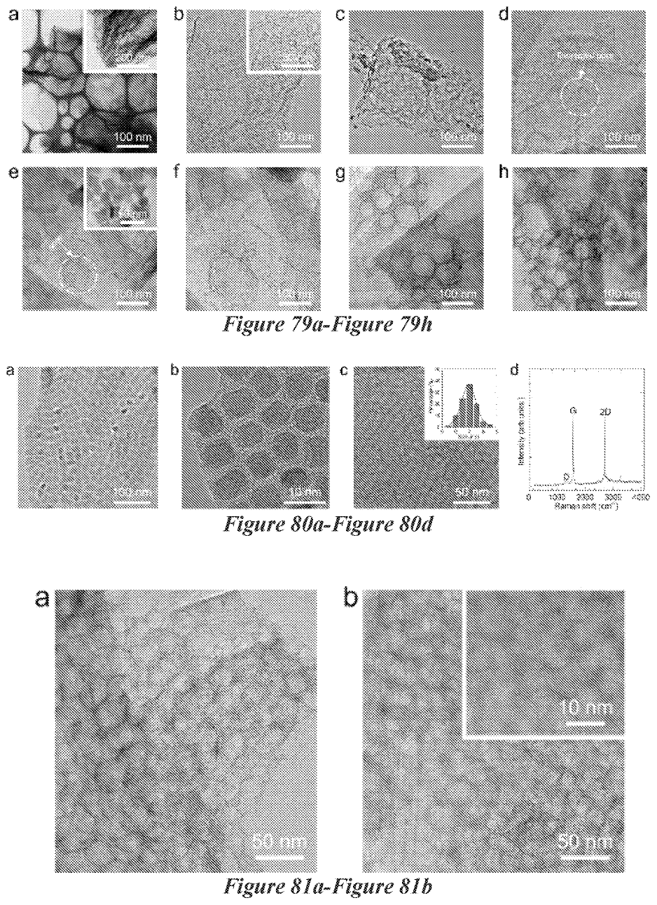

The method for stacking graphene sublattices was expanded to introduce nanopores on bilayer graphene, where the pores in one layer partially overlap with those in the other layer (FIG. 73c). This misaligned stacking of two porous graphene sublattices creates a distinct arrangement of carbon atoms with a periodicity of 3.2±0.7 nm (inset of FIG. 73d). To examine the influence of misaligned sublattice stacking, bilayer graphene with completely overlapped nanopores was also synthesized (Methods, FIG. 73e and FIG. 79a-FIG. 79h). Achieving high flatness of graphene, a high density of monodisperse, nanometer-sized Fe₃O₄ particles, and optimizing the carbon reduction reaction duration are important for creating periodic structural heterogeneity. Distortion or polydispersity in the nanopores is attributed to suboptimal conditions (FIG. 80a-FIG. 80d). Although square nanopores were also created on triple or multiple layers of graphene, the arrangement of carbon atoms lacked a well-defined periodicity (FIG. 81a-FIG. 81b). Herein, bilayer graphene with partially overlapped square nanopores is referred to as graphene superlattice.

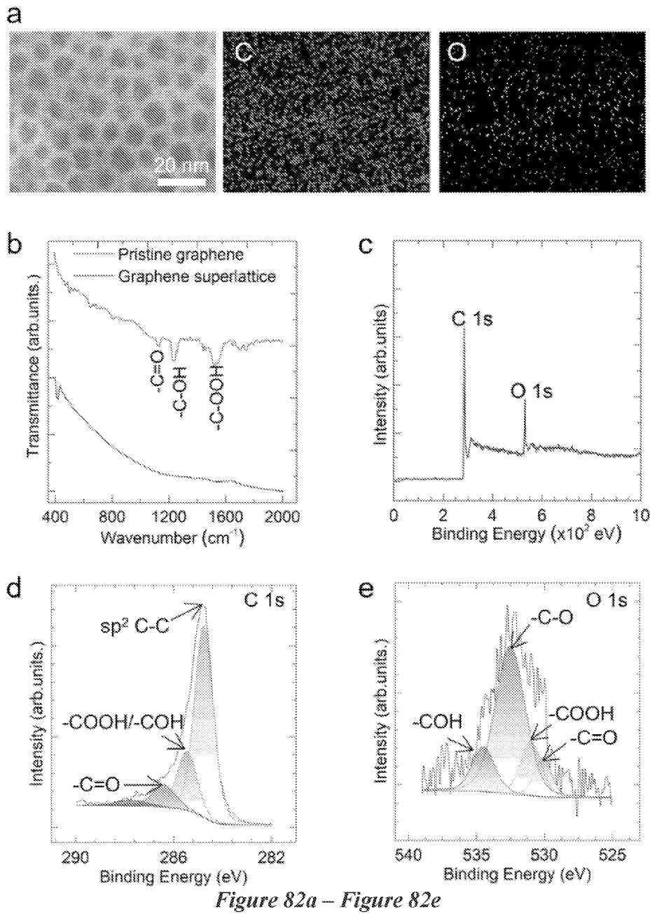

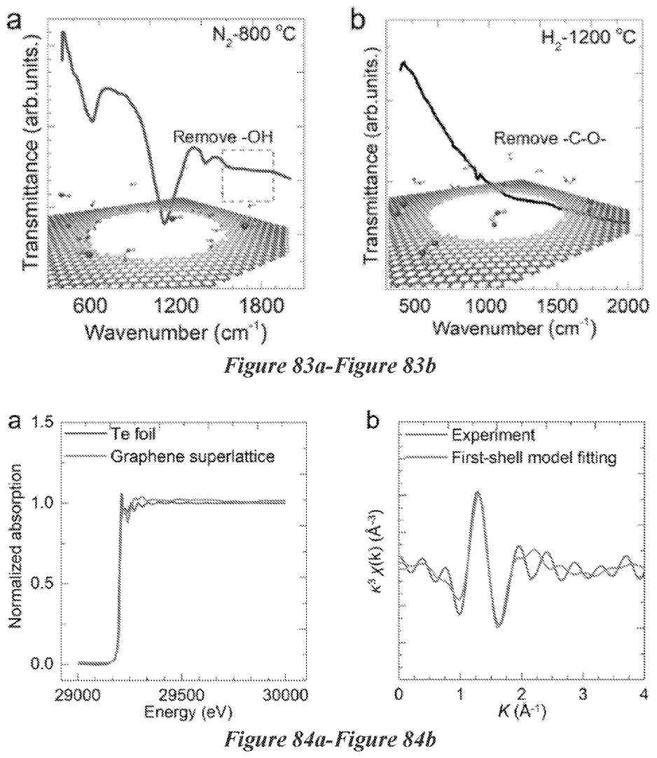

To achieve compositional heterogeneity, the type of functional groups at the pore edges were precisely tuned through element doping. The pore edges of the obtained graphene superlattice possessed uncontrolled carbon (C)-oxygen (O) bonds, including —CO— and —COOH, as determined by Fourier transform infrared spectroscopy (FT-IR), X-ray photoelectron energy spectroscopy (XPS) and transmission electron microscopy (TEM) element mapping (FIG. 82a-FIG. 82e). To prepare hydrogen (H)-doped and O-doped nanoporous graphene, the graphene was annealed in the presence of a hydrogen gas atmosphere at 1,200 °C and 800 °C, respectively, to transform all the edge bonds into —C—H and —C=0 bonds (FIG. 83a-FIG. 83b). Further doping of a range of elements, including tellurium (Te), selenium (Se), nitrogen (N), phosphorus (P), sulfur (S), and boron (B), was achieved by a secondary thermal treatment to replace the —C—H bonds at the pore edges of H-doped porous graphene.

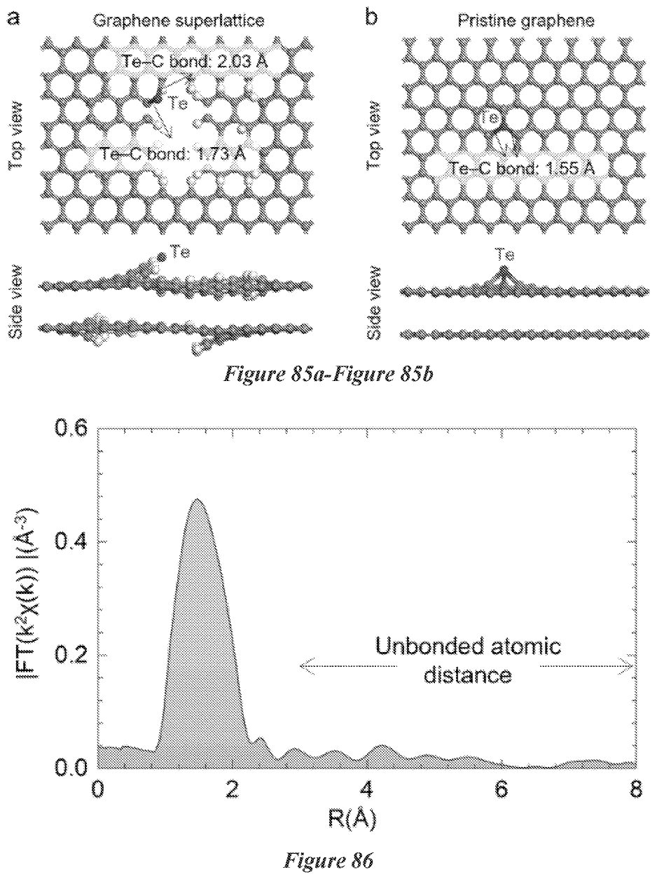

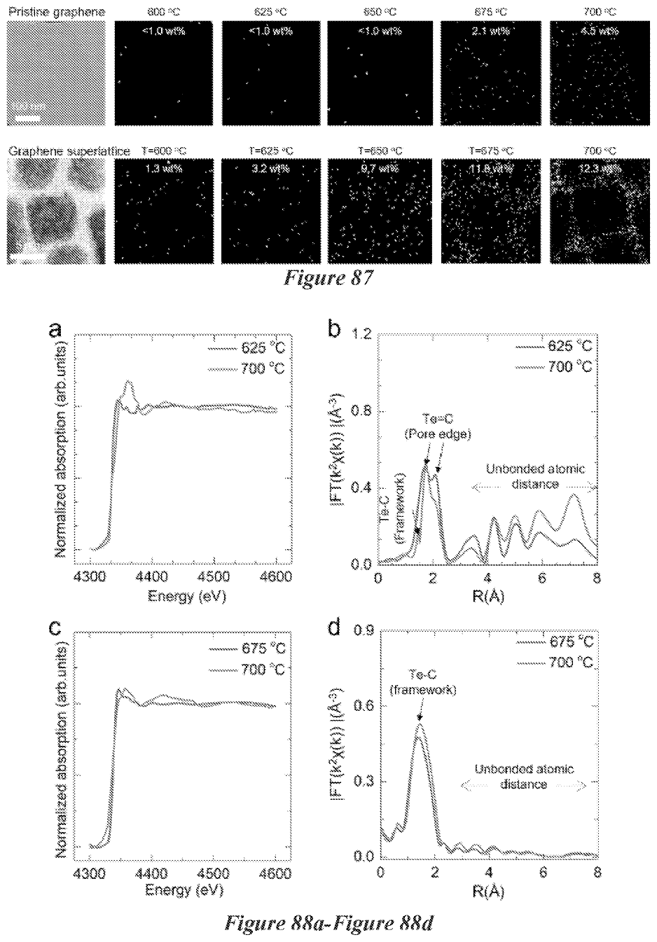

Te-doped porous graphene superlattices were employed as an example to analyze the state and distribution of doped elements on graphene surface. The extended X-ray absorption fine structure (EXAFS) analysis (FIG. 73f and FIG. 84a-FIG. 84b) showed two types of Te bonds located at the pore edges with lengths of 2.07 Å and 1.69 Å, in agreement with density functional theory (DFT) calculations (FIG. 85a-FIG. 85b). The appearance of consecutive peaks ranging from 3 Å to 8 Å, beyond the typical length of covalent or ionic bonds, suggests the formation of dangling Te bonds at the pore edges. DFT calculations using the climbing image nudged elastic band method revealed that Te atom diffusion towards the pore edge has a lower energy barrier (0.42 eV) and stronger bonding (−7.41 eV) compared to diffusion towards the framework, indicating preferential element doping at the pore edges at relatively low temperatures (FIG. 73g and Note 1), in accordance with EXAFS analysis and temperature-dependent TEM via characterizing the Te doping on pristine graphene and graphene superlattices annealed at temperature from 600-700 °C (FIG. 87 and FIG. 88a-FIG. 88d and Note 2).

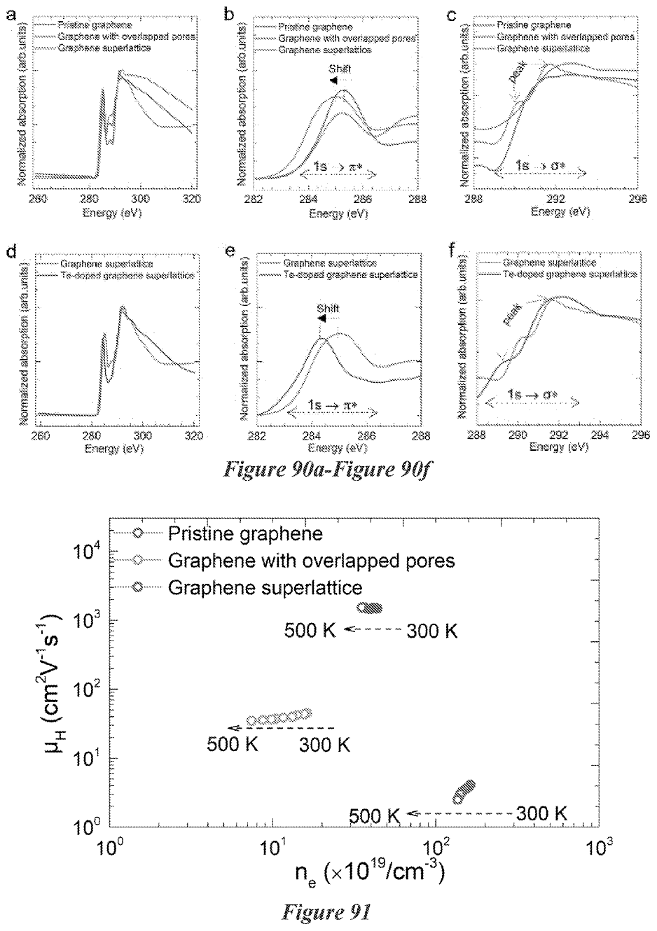

Electronic and phonon structure of porous graphene superlattice. DFT calculations were employed to compare the electronic structures of pristine bilayer graphene with graphene superlattices. FIG. 74a illustrates that graphene superlattices exhibit a remarkable flattening of bands near the Fermi level, characterized by negligible band dispersion (less than 1 meV). This flat-band structure arises from the weak dispersion relation of kinetic energy resulting from the periodic electronic reconstruction caused by atomic stress between the overlapped and exposed carbon regions, leading to the emergence of a new 1s→σ* transition peak in X-ray absorption of the C K-edge (FIG. 90a-FIG. 90f and Note 3). This electronic reconstruction leads to the formation of electron domain walls that confine Fermi electrons on either side, resulting in an equipotential Fermi surface and energy barriers with neighboring surfaces (Ghorashi S A et al. Phys. Rev. Lett. 2023, 130, 196201). The electron trapping effect leads to a closer proximity of valence electrons in graphene superlattice to the Fermi level, resulting in the formation of multiple van Hoff singularities (Hu H et al. Nat. Nanotechnol. 2022, 17, 940), as demonstrated by the distribution of electronic density of states in FIG. 74b.

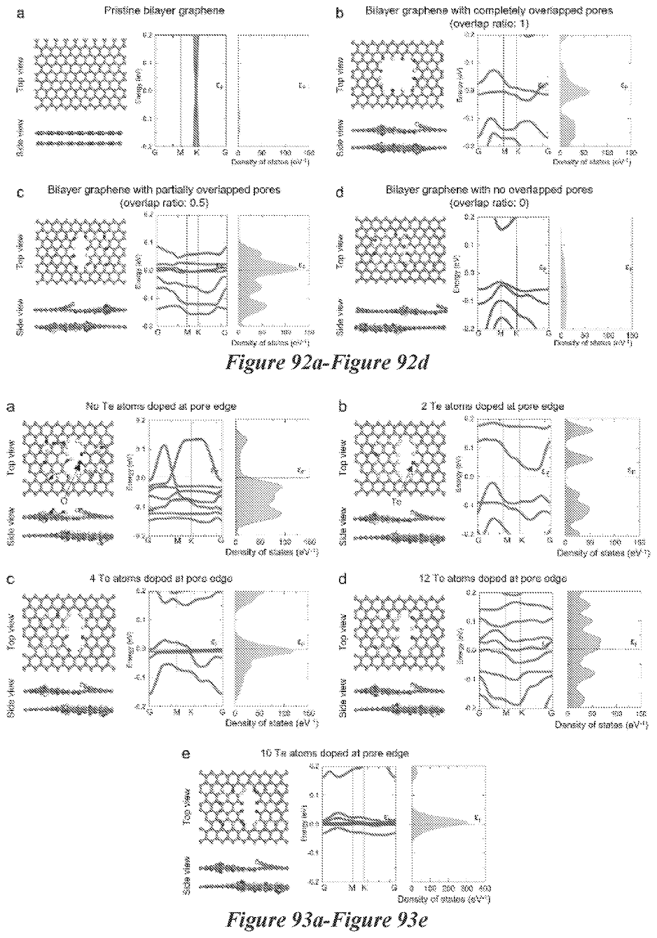

Dopants in graphene superlattices results in an elevated electronic density of states on both sides of the Fermi level, a notable enhancement of electron-electron interaction, and an intensified spin-orbit coupling (Chen W et al. ACS Nano 2022, 16, 6646; Bie C et al. Adv. Mater. 2021, 33, 2003521), leading to a weakening of the dispersion relation between electrons and kinetic energy, resulting in an electron system with infinite mass and an increased Coulomb interaction between electrons, thereby contributing to the enhanced band flattening. This computational analysis is supported by Hall carrier concentration measurements, revealing an approximate 400% increase in carrier concentration and a significant 99.8% decrease in carrier mobility in graphene superlattices compared to pristine graphene (FIG. 91). Computational study reveals that electronic band flattening is influenced by various factors, such as structural periodicity, types and ratios of the dopants, and pore geometries (FIG. 92a-FIG. 96c and Note 4). Bilayer graphene with partially overlapped circular nanopores or totally overlapped square nanopores lacks a flat-band structure due to the absence of a well-defined periodicity electron domain, attributing to the significant stress between the exposed and overlapped carbon atoms, which disrupts the formation of electron domain walls in these graphene structures.

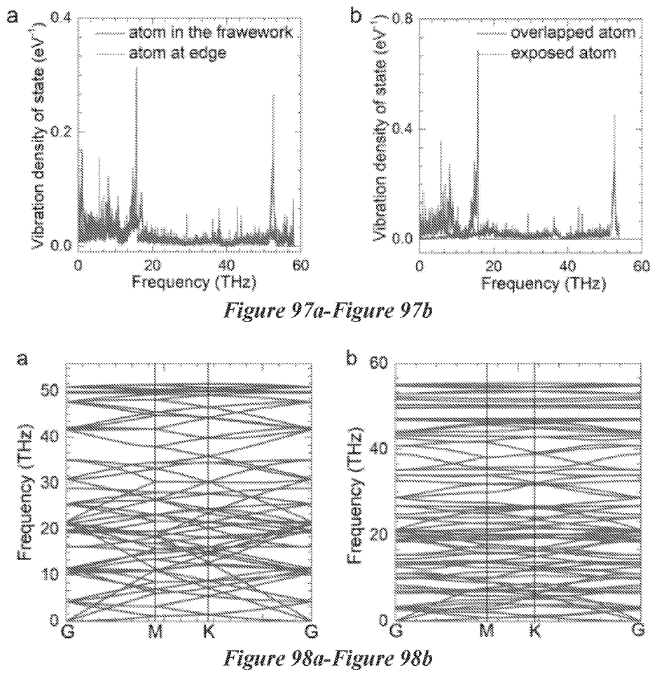

The effect of superlattice structure on the graphene phonon structure was also studied. Due to the harmonic oscillation of the atomic lattice (Choi Y W et al. Phys. Rev. Lett. 2021, 127, 167001), pristine graphene exhibits predominantly atom-propagated phonons with a frequency of 50 THz (FIG. 74c). In contrast, the periodic overlap of carbon atoms in bilayer graphene superlattices suppresses harmonic vibrations, leading to distinct phonon modes in the overlapped and exposed regions. Te dopants at pore edges possess same phonon vibrational modes that can give rise to clusters of new phonons (Wei K et al. Nat. Commun. 2020, 11, 3876; Sadeghi M et al. Nature 2023, 617, 282), as evident by the vibrational density of states (FIG. 97a-FIG. 97b and Note 5). The transmission of phonon clusters in graphene superlattices exhibits substantial coherent interference and elastic scattering (Lian B et al. Phys. Rev. Lett. 2019, 122, 257002), resulting in phonon cluster energy weakening and the emergence of a series of continuous standing waves in the low-frequency range of 10-30 THz, while the original high-frequency phonons disappear.

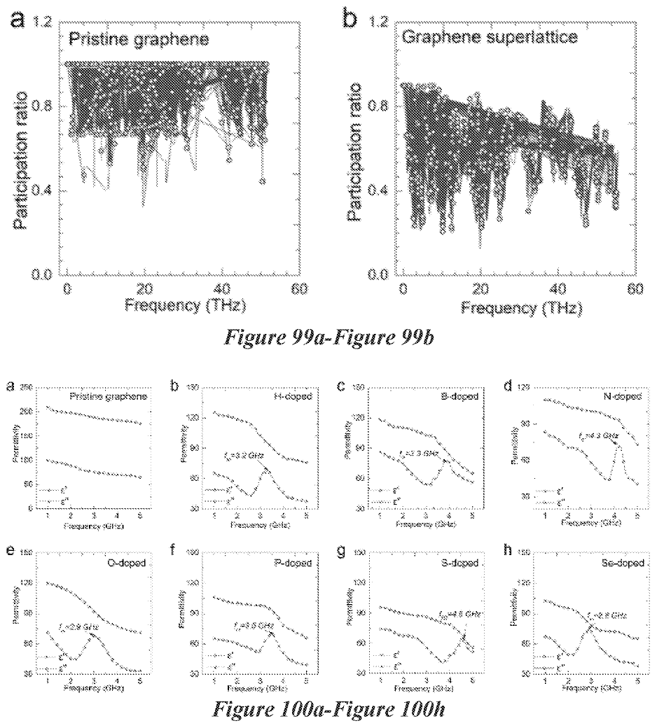

The absence of high-frequency phonons induces volume contraction of the first Brillouin zone, causing folding and compression of the phonon acoustic branches and resulting in phonon bandgaps in the high-frequency range (Bodapati A et al. Phys. Rev. B. 2006, 24, 74), as compared to the pristine graphene (FIG. 74d and FIG. 98a-FIG. 98b). Calculations indicate that atomic participation ratios of graphene superlattices are 30-50% lower than those of pristine graphene (FIG. 99a-FIG. 99b), confirming that a decrease in the proportion of atoms participating in the same phonon mode directly leads to a reduction in phonon energy and cluster velocities (FIG. 74e). The resulting localization of phonons and the electron trapping effect leads to strong electron-phonon coupling, wherein electrons absorb phonons, undergo motion, and scatter to excite new phonons (Nathawat J et al. Nat. Commun. 2023, 14, 1507). This continuous cycle gives rise to a prominent phonon drag effect, which significantly affects the trajectories and transport properties of electrons in graphene superlattice (Gadelha A et al. Nature 2021, 590, 405). In summary, the graphene superlattice exhibits remarkable quantum phase correlations at both the electron and phonon levels, resulting in a diverse range of functionalities that surpass those observed in pristine graphene.

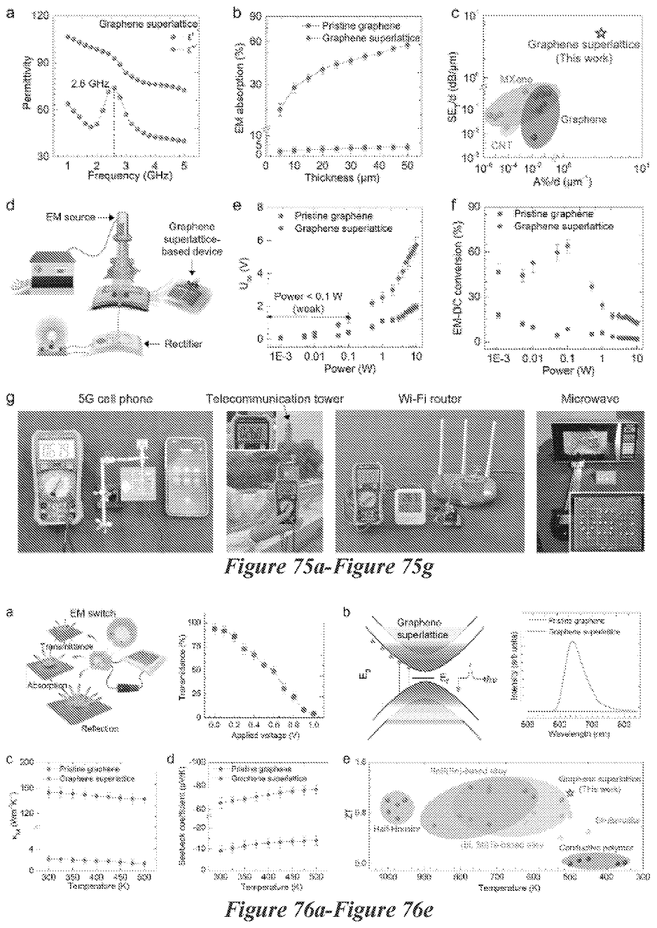

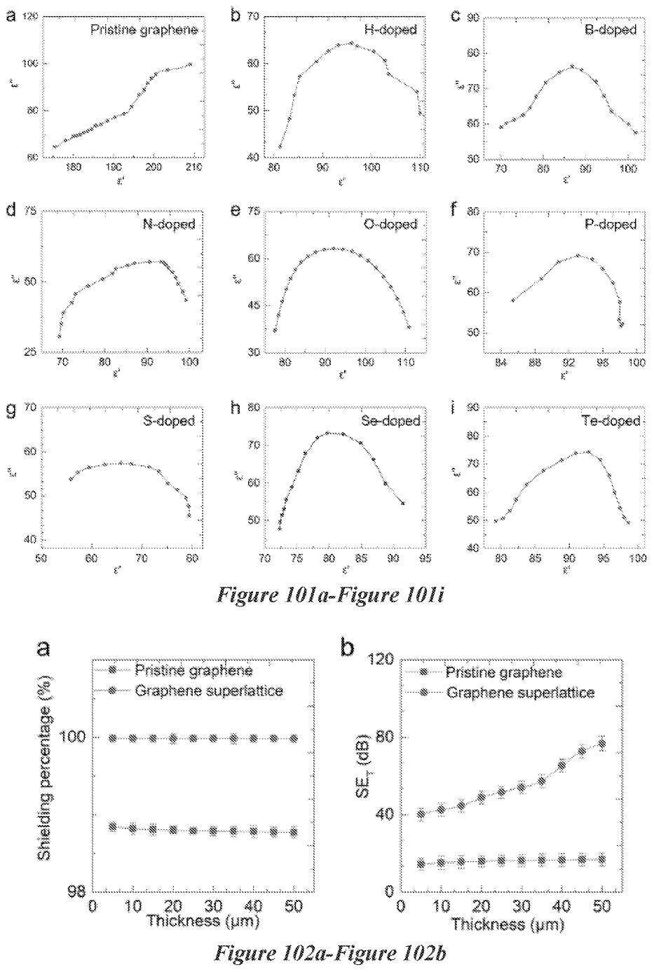

Dielectric behavior and electromagnetic wave-electricity output of porous graphene superlattice. The burgeoning advancements in wireless communications, particularly the fifth generation of mobile cellular network (5G), have raised concerns over the underutilization of EM waves and disruptive signal interference (Lv H et al. Prog. Mater. Sci. 2022, 127, 100946; Iqbal A et al. Science 2020, 369, 446; Han M et al. Nat. Nanotechnol. 2023, 18, 373). Existing EM materials have limitations in their effectiveness, particularly with thicknesses of tens of micrometers. Graphene superlattices were investigated to efficiently regulate EM waves and harness spatial EM energy. FIG. 75a and FIG. 100a-FIG. 100h reveal a remarkable dielectric dispersion behavior in the low-frequency 2-5 GHz region, which corresponds to the current wireless communication band (Lv H et al. Nat. Commun. 2021, 12, 834), in element-doped graphene superlattice. This behavior is characterized by a sharp decrease in real permittivity (ε′) and a dielectric resonance peak in imaginary permittivity (ε″), resulting in a substantial increase in EM wave absorption, effectively dissipating the EM waves as joule heat and minimizing EM wave reflection and secondary interference (Wu Y et al. Prog. Mater. Sci. 2023, 135, 101088). This can be attributed to the dielectric polarization relaxation, as demonstrated by the Cole-Cole curve (FIG. 101a-FIG. 101i and Note 6), which arises from the periodic electron domain walls (Xia Y et al. Adv. 1Funct. Mater. 2022, 32, 2204591).

This dispersive behavior leads to an absorption efficiency of graphene superlattice in the 2-5 GHz region, within the thickness range of 5-50 μm, that surpasses that of pristine graphene by two orders of magnitude (FIG. 75b). Even at a thickness of only 50 μm, the absorption can exceed 60%. Due to its exceptional EM absorption coefficient, the average EM shielding effectiveness of graphene superlattice can reach 99.99% (corresponding to an EM shielding effectiveness SE_{T}>40 dB), effectively addressing secondary reflection-induced EM interference (FIG. 102a-FIG. 102b). The EM absorption capabilities of graphene superlattice in the micrometer thickness range surpass those of all existing EM materials (Table 9). Direct comparison of EM shielding ability revealed that the EM shielding effectiveness and EM absorption efficiency per material thickness of graphene superlattice were two to four orders of magnitude higher than conventional 2D materials, including MXene and other chemically modified graphene, as shown in FIG. 75c (Liu J et al. Adv. Maier. 2017, 29, 1702367, Rajavel K et al. A(,SAppi. Mater. Interfaces, 2020, 12, 49737; Yun T et al. ACS Nano 2021, 15, 10058; Shen B et al. Carbon 2016, 102, 154; Song W L et al. J. Mater. Chem. C 2014, 2, 5057, Li C B et al. ACS Appl. Mater. Interfaces 2020, 12, 30686; Shen B et al. Ac. Fun. Mater. 2014, 24, 4542; Wei Q et al. Adv. Mater. 2020, 34, 1907411; Kumar P et al. Carbon 2015, 94, 494; Mirkhani S A et al. ACS App. Mater. Interface, 2021, 13, 15827; Kashani H et al. Matter 2019, 4, 1077; Liu X et al. J. Mater. Chem. C 2021, 9, 214; Bi S et al. Appl. Surf. Sci. 2017, 412, 529; Wang Z G et al. Compos. Sci. Technol. 2020, 194, 108190; Wang C et al. Carbon 2020, 167, 31).

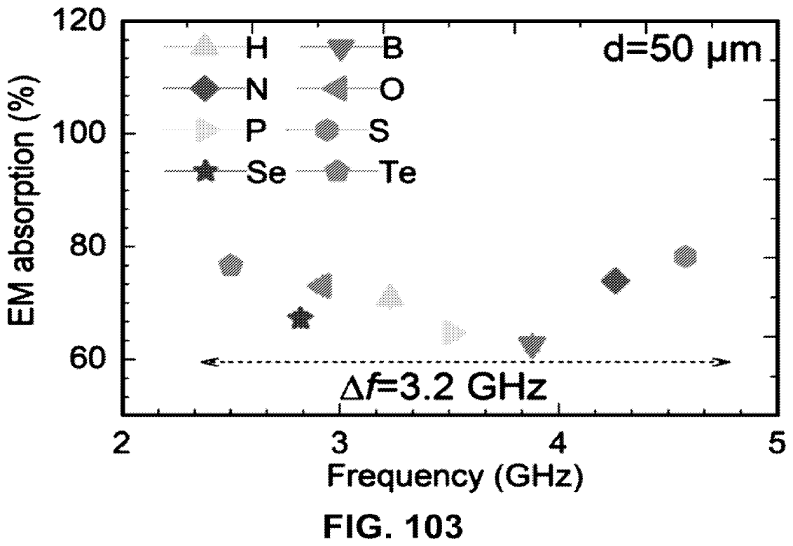

The ability to tune the EM absorption efficiency by adjusting the amounts of doped elements and shift the maximum EM absorption frequency by selecting the doped element type was demonstrated (FIG. 103). This graphene superlattice selectively absorbs EM waves at a specific wavelength while allowing transmission of other bands, minimizing signal loss and offering potential integration into miniaturized circuits for efficient EM absorption.

TABLE 9
Polarization frequency, maximum EM absorption efficiency,
and thickness of conventional dielectric materials.

| | Polarization | | | |
|---|---|---|---|---|
| | relaxation | Aₘₐₓ | Thickness | |
| Materials | (GHz) | (%) | (μm) | Reference |
| Reduced graphene | >12 | <10 | 1,500 | Wen B et al. Adv. Mater. 2014, 26, |
| oxide (rGO) | | | | 3484 |
| I-doped graphene | >18 | <1 | 12.5 | Wang Y J et al. Carbon 2017, 122, 74 |
| S-doped graphene | >18 | ~12.5 | 140 | Shahzad F et al. SJ. Mater. Chem. C |
| | | | | 2015, 3, 9802 |
| N-doped graphene | >18 | <1 | 3 | Lin S F et al. J. Mater. Sci. 2019, 54, |
| | | | | 7165 |
| Lattice defect rGO | ~11 | <5 | 1,000 | Kuang B Y et al. Carbon 2018, 127, |
| | | | | 209 |
| Graphene oxide | >18 | <5 | 11.8 | Shen B et al. Adv. Funct. Mater. 2014, |
| (GO) | | | | 24, 4542 |
| Graphene | >18 | ~10 | 1,500 | Yin X M et al. Chem. Eng. J. 2020, 387, |
| microtube | | | | 124025 |
| Graphene aerogel | >18 | ~12 | 2,500 | Li C B et al. ACS Appl. Mater. |
| | | | | Interfaces 2020, 12, 30686 |
| Graphene | >12 | <5 | 1,500 | Cao M S et al. J. Mater. Chem. C 2018, |
| nanohybrids | | | | 6, 4586 |
| Graphene foam | >18 | <10 | 3,000 | Li J C et al. Chem. Eng. J. 2021, 415, |
| | | | | 129054 |
| Multiwall carbon | >18 | <5 | 2,000 | Guan Q F et al. Nano Lett. 2021, 27, |
| nanotubes | | | | 2532 |
| Carbon fibers | >18 | <10 | 2,000 | Liang J Y et al. Compos. Part A-Appl. S |
| | | | | 2019, 121, 289 |
| Ti₃C₂Tₓ | >18 | <1 | 2.5 | Shahzad F et al. Science 2016, 353, |
| | | | | 1137 |
| Ti₃CNTₓ | >18 | <1 | 40 | Iqbal A et al. Science 2020, 369, 446 |
| Micropatternable | >18 | <1 | 3.3 | Lipton J et al. Matter 2020, 3, 546 |
| MXene film | | | | |
| Ti₂CTₓ aerogel | >18 | <5 | 1,000 | Han M K et al. Adv. Opt. Mater. 2019, |
| | | | | 7, 1900267 |
| V₂CTₓ | >18 | <1 | 3,300 | Han M K et al. Cell Rep. Phys. Sci. |
| | | | | 2022, 10, 101073 |
| Mo₂Ti₂C₃Tₓ | >18 | <5 | 5 | Han M K et al. ACS Nano 2020, 14, |
| | | | | 5008 |
| Ti₃C₂Tₓ film | >18 | <1 | ~1 | Yun T et al. Adv Mat 2020, 32, |
| | | | | 1906769 |
| Porous T₃C₂Tₓ | >18 | <10 | 1,900 | Lu Z Q et al. Compos. Part B-Eng. |
| | | | | 2021, 277, 108853 |
| Ti₃C₂ | >18 | <10 | 1,850 | Tan X et al. ACS Nano 2022, 6, 9254 |
| MXene/graphene | | | | |
| Ti₃C₂Tₓ/CNTs | >18 | <10 | 38 | Cao W T et al. Nano-Micro Lett. 2019, |
| | | | | 11,72 |
| Ti₃C₂Tₓ/BN | >18 | <1 | 1,000 | Shang Y et al. Compos. Sci. Technol. |
| | | | | 2021, 214, 108974 |
| Porous | >18 | <1 | 1,500 | Zhang Y et al. Nano Res. 2022, 15, |
| Ti₃C₂Tₓ/rGO | | | | 4916 |
| Ti₃C₂Tₓ/C | >18 | <15 | 2,000 | Wang L et al. Compos. Part A-Appl. S. |
| | | | | 2019, 123, 293 |

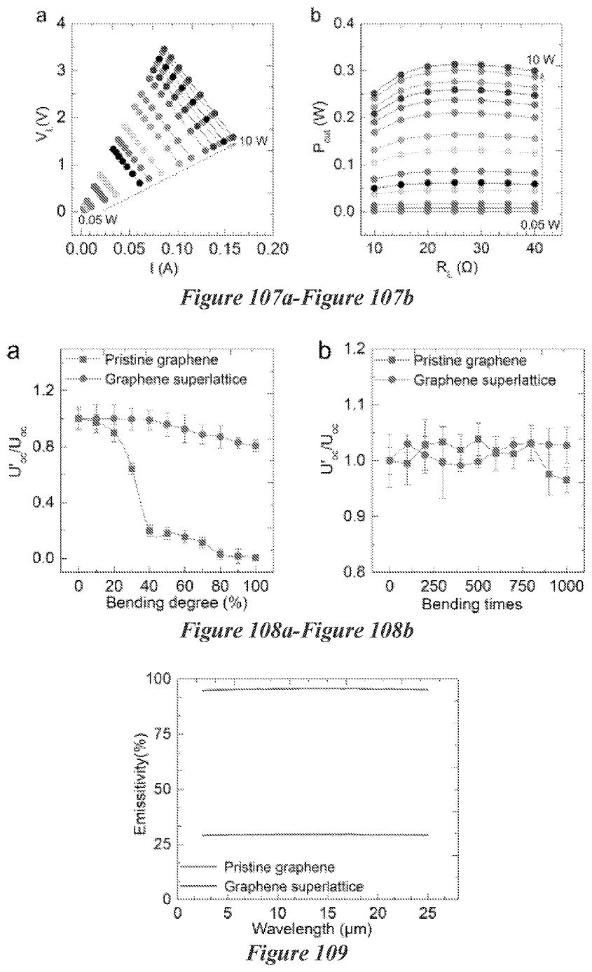

To harness spatial EM energy, the potential of graphene superlattices to convert ambient EM waves into direct current (DC) electricity was explored (FIG. 75d, FIG. 104, FIG. 105, and Note 7 for device design and fabrication). As shown in FIG. 75e, the measured open circuit voltage (U_{oc}) of graphene superlattice increased from 0.1 V to 6.4 V with an increase in EM wave emission power from 1 mW to 10 W, respectively. The graphene superlattice-based device demonstrated a consistent U_{oc} of ~30 mV at a 10 m distance from a 10 W EM source (white the pristine graphene device dropped below 0.01 mV at only 4 m; FIG. 106), a maximum power output of 0.31 W with a load resistance of 24Ω when exposed to a 10 W source (FIG. 107a-FIG. 107b), and stable electricity output even after 1,000 bending cycles or in different bending states (FIG. 108a-FIG. 108b). Furthermore, the overall efficiency of EM-DC conversion was calculated to be ~64% at an EM emission power of 100 mW, as shown in FIG. 75f. Notably, the device was able to efficiently harvest and convert EM waves from a 5G cell phone, a wireless fidelity (Wi-Fi) router, a telecommunication tower, and a microwave to DC electricity that can be used to power electronic devices such as light-emitting diodes (LEDs) and digital hygro-thermometers, as shown in FIG. 75g.

Expanded applications of porous graphene superlattice. Unique properties and potential applications of graphene superlattice beyond those of pristine graphene and conventional chemically modified graphene were investigated. First, graphene superlattices exhibit multiple consecutive van Hoff singularities appear near the Fermi level (FIG. 74a). A graphene superlattice-based smart EM wave window, which can selectively transmit, absorb, and shield EM waves by applying a voltage as low as 1.0 V (FIG. 76a), was developed. Second, in graphene superlattice, an increase in the energy level splitting and potential differences across the electron domain wall leads to the separation of electrons and holes, causing a remarkable photoluminescence effect within the visible light wavelength range (400-700 nm) in graphene superlattice, not being observed in pristine graphene (FIG. 76b). These findings highlight the high sensitivity of carrier transport in graphene superlattice with small bandgaps to external electric fields, making them promising candidates for applications in EM switch and optoelectronics. Third, in graphene superlattice, the presence of substantial coherent interference and phonon elastic scattering results in a significant reduction in thermal conductivity. FIG. 76c demonstrates that the thermal conductivity of graphene superlattice is two orders of magnitude lower than that of pristine graphene. This remarkably low thermal conductivity provides excellent thermal insulation and low infrared emissivity (~0.3 at near-infrared band), making graphene superlattice a candidate for infrared stealth coatings (FIG. 109). Moreover, the synergistic effects of electron trap and phonon drag enhance the Seebeck coefficient of graphene superlattice by 700-800% compared to pristine graphene in the temperature range of 300-500 K (FIG. 76d). The combination of ultralow thermal conductivity and enhanced Seebeck coefficient demonstrate exceptional thermoelectric performance. The maximum figure of merit value of thermoelectric (ZT) reached 1.11 even at temperatures as low as 500 K, which is four orders of magnitude higher than ZT of pristine graphene and comparable to state-of-the-art inorganic thermoelectric materials (FIG. 76e) (He W et al. Science 2019, 365, 1418; Zhou et al. Nat. Commun. 2019, 10, 270; Luo Z Z et al. Energy Environ. Sci. 2022, 15, 368; Moshwan R et al. Nano Energy 2019, 65, 104056; Ren G K et al. Nat. Commun. 2019, 10, 2814; Luo Y B et al. J. Am. Chem. Soc. 2020, 142, 15187; Yang S Q et al. Adv. Mater. 2021, 10, 2007681; Sarkar D et al. Agnew Chem. Int. Ed. 2021, 60, 10350; Jiang Q L et al. Adv. Mater. 2020, 32, 2002752; Zheng Z H et al. Nano Energy 2021, 81, 105683; Yan X M et al. Nano Energy 2021, 84, 105879; Luo Y B et al. J. Am. Chem. Soc. 2020, 142, 15187; Xu X et al. Energy Environ. Sci. 2020, 12, 5135; Anno Y et al. 2D Matler. 2017, 4, 0255019; Stanley A et al. Energy Environ. Sci. 2023, 16, 2023; Liu Z H et al. Nat. Commun. 2022, 13, 1120; Yu L Q et al. Nat. Commun. 2022, 13, 6449; Zhu T J et al. Adv. Energy Mater. 2015, 19, 1500588; Liu Z H et al. Adv. Funct. Mater. 2019, 29, 1905044; Jeong H et al. J. Europ. Ceram. Soc. 2021, 41, 4175; Li X F et al. Research 2020, 2, 4630948; Li W J et al. Chem. Mater. 2019, 31, 862; Liu Z Y et al. J. Europ. Ceram. Soc. 2023, 43, 1985; Fan X et al. Ceram. Int. 2022, 48, 15136).

Discussion A nanoporous bilayer graphene superlattice with partially overlapping pores was chemically synthesized, revealing remarkable correlations between electron and phonon quantum phases and enabling diverse applications beyond pristine graphene, including ultrathin EM absorption, EM energy harvesting and conversion, thermoelectric performance at low-to-intermediate temperatures, photoluminescence, and optoelectronic devices. This study provides a chemical principle for the design and synthesis of a unique family of 2D superlattices, expanding the understanding of these structures and paving the way for the development of cutting-edge technologies. Future research efforts will focus on precise control of the lattice mismatching in nanoporous graphene sublattices to gain insights into their influence on the unique properties and functionalities of the superlattice. The methodology can be extended to the creation of 2D superlattices using other conventional 2D materials, further broadening the range of materials with tailored properties and diverse applications.

### Method

Materials. Iron acetylacetonate, oleic acid, oleyl amine, ammonia (28 wt % in water), hydrogen peroxide (30 wt % in water), sodium chloride, sodium molybdate dehydrate, thiourea, ferrous chloride, cobalt acetate, ethylene glycol, zinc acetate, lanthanum oxide, cobalt nitrate, tetraethyl orthosilicate, sodium hydroxide, oxalic acid, strontium carbonate, cobalt oxalates, bismuth nitrate pentahydrate, diboron trioxide, 1-butyl-3-methlyimidazolium hexafluorophosphate (BmimPF₆), silver nitrate, stannous chloride, sulfur powder, ethylenediaminetetraacetic acid disodium, copper nitrate, hexadecyltrimethylammonium bromide, formaldehyde, mercury oxide, mercury, cyclohexane, isopropanol, iron pentacarbonyl, 1,3-dimethylimidazoline-2-selenone, hydrochloric acid (38 wt % in water), tellurium power, selenium powder, potassium hydroxide, sulfuric acid, sulfide powder and parylene-c monomer were purchased from Sigma-Aldrich. Raw graphene and multiwall carbon nanotubes were obtained from XF-NANO Tech. Co. All chemical reagents are analytical pure reagents and were used without further purification. Polydimethylsiloxane (PDMS) film was purchased from Shanghai Muke Technol. Co. Deionized water used in all the experiments was purified using a Simplicity C9210 Milli-Q water purification system.

Synthesis of graphene superlattice. Initially, a mixture of iron acetylacetonate (1.4 g), raw bilayer graphene (10 mg) synthesized via chemical vapor deposition (CVD), oleic acid (10 mL), and oleyl amine (10 mL) was prepared and stirred for 30 min. The mixture was then heated under a nitrogen flow at a temperature range of 110-120 °C with vigorous stirring for 2 h.

Subsequently, the temperature was increased to 220 °C at a heating rate of 5 °C/min and held for 30 min, followed by heating to 300 °C for an additional 30 min at a rate of 2 °C/min. After cooling to room temperature, the graphene coated with cubic Fe₃O₄ nanoparticles was collected by centrifugation after dispersion in cyclohexane and isopropanol. The obtained graphene coated with cubic Fe₃O₄ nanoparticles was subjected to a heat treatment at 300 °C for 60 min under a continuous nitrogen flow to remove organic solvents. Subsequently, the temperature was gradually increased to 650 °C at a rate of 5 °C/min and maintained for 0.5 h to induce the formation of square-shaped nanometer-sized pores on the bilayer graphene surface. After cooling, the graphene was dispersed in a hydrochloric acid solution with a pH of 3-4 to remove the coated Fe₃O₄ nanoparticles, resulting in the formation of squared nanopores. By employing raw graphene with different layer numbers, porous graphene with various layer numbers can be fabricated.

Synthesis of bilayer graphene with completely overlapped nanopores. The bilayer graphene with completely overlapped nanopores was synthesized using a thermal decomposition method using cubic sodium chloride nanoparticles as a template. Firstly, the sodium chloride nanoparticles were prepared by freeze-drying a nearly saturated sodium chloride solution. Then, a mixture of 0.2 g of iron oleate (prepared through the reduction of iron (III) chloride hexahydrate and sodium oleate) and 2 g of sodium chloride nanoparticles was calcined at 500 °C for 2 h under a nitrogen gas flow. After cooling to room temperature, the resulting precipitates were dispersed in deionized water to remove the sodium chloride nanoparticles. Subsequently, the materials were immersed in a hydrochloric acid solution and subjected to ultrasonication for 36 h to eliminate the iron oxide nanoparticles. The products were washed with deionized water to eliminate residual ions and separated through suction filtration. Finally, the bilayer graphene with completely overlapped nanopores was obtained by drying in a vacuum oven for 12 h and subsequently annealed at 1,500 °C for 2 h under a flowing nitrogen gas environment.

Selective element doping at pore edges of graphene superlattice. To achieve selective doping of elements at the pore edges of the graphene superlattice, a stepwise annealing process was employed. The graphene superlattice was subjected to annealing at 600 °C, 800 °C, and 1,200 °C for 1 h to progressively decompose the —OH, —CO, and —COOH groups at the pore edges, respectively. The first two annealing steps were carried out under a nitrogen gas flow, while the final step was conducted in a mixture gas comprising 5 vol % hydrogen and 95 vol % nitrogen. Selective doping of O and H at the pore edges of the bilayer porous graphene was achieved after the second (800 °C) and third step (1,200 °C) of annealing, respectively. Furthermore, the selective doping of other elements such as B, N, P, S, Te, and Se at the pore edges of graphene was achieved through thermal decomposition at various temperatures (Table 10).

TABLE 10
Annealing treatment conditions for element doping.

| | Mass (mg) or standard | | | | |
|---|---|---|---|---|---|
| | cubic Centimeters per | | Temperature | Time | |
| Precursor | minute (sccm) | | (°C) | (b) | Atmosphere |
| B₂O₃ | 50 | mg | 1,150 | 1 | Ar |
| NH₃ | 20 | sccm | 1,050 | 2 | NH₃/Ar (1:5) |
| BminPF₆ | 45 | mg | 550 | 0.75 | Af |
| S powder | 80 | mg | 500 | 0.5 | Ar |
| Te powder | 100 | mg | 650 | 0.5 | Ar |
| Se powder | 100 | mg | 650 | 0.5 | Ar |

Structural characterization of porous graphene. Graphene superlattice phase identification was conducted using a Bruker D8 ADVANCE XRD equipped with Cu Ka radiation (wavelength of 0.15406 nm). The morphology of the nanoparticles and porous graphene was investigated using a Joel JEM 2100 F transmission electron microscope (TEM) with a 200 kV field emission. X-ray photoelectron spectroscopy (XPS) analyses were carried out using an Escalab 250Xi spectrometer. The graphitization quality was evaluated using a Jobin Yvon HR 800 confocal Raman spectroscope. Synchrotron X-ray absorption near-edge structure (XANES) analysis was performed at Beamline 33BM-C in the XOR Division of the Advanced Photon Sources. Extended X-ray absorption measurements were conducted at beamline 7-BM of the National Synchrotron Light Source II, Brookhaven National Laboratory. Chemical bonding analysis of graphene was carried out using a Nicolet iS50 Fourier Transform Infrared Spectrometer (FT-IR).

Evaluation of EM shielding and absorption of graphene. The EM frequency-dependent scattering parameters (i.e., Sut and Si) and permittivity of graphene were measured via the single coaxial-line method using an Agilent PNA N5224A vector network analyzer. The corresponding absorption efficiency (A %) and shielding effectiveness (SE_{T}) can be calculated as (Zhang Y et al. Adv. Mater. 2023, 35, 2211642; Wan S J et al. Nat. Mater. 2021, 20, 624):

A %=(1−|S₁₁|²−|S₂₁|²)×100% (1)

SE_{T}=−10 log|S₂₁|² (2)

It is noted here that the uncertainty in the permittivity and S-parameter measurements is about 10-15% due to variations originating from the smoothness of sample surfaces.

Characterization of thermal conductivity, electric conductivity, photoluminescence, Seebeck coefficient and infrared emissivity of graphene superlattice. The temperature-dependent electric conductivity and Seebeck coefficient of graphene were measured using an ULVAC-RIKO ZEM-3 instrument under a helium atmosphere with a heating rate of 5 °C/min.

Graphene was hot-pressed into a pellet with dimensions of approximately 8 mm length and 3 mm width. Thermal conductivity (κ_{T}) was calculated as:

κ_{T}=DCₚλ (3)

where D is the density, Cₚ is the specific heat value, and A is the thermal diffusivity. Thermal conductivity was measured using a Netzsch LFA-467 laser flash system with a Pyroceram disk as the reference material. Specific heat values were obtained using a Pyroceram 9606 system. Hall carrier concentration was determined using a physical property measurement system. It should be noted that the uncertainty in the electrical output value is approximately 15-20% due to measurement errors in electric and thermal conductivity, as well as the Seebeck coefficient. The temperature error is around 1 K. Photoluminescence performance was recorded at room temperature using a LifeSpec II fluorescence lifetime spectrometer equipped with a diode laser emitting at a wavelength of 365 nm. Infrared emissivity was measured using a PerkinElmer Spotlight 200i FT-IR spectrometer along with an IR integrating sphere.

Note 1: First-principles density functional theory (DFT) simulation of element diffusion and bonding in graphene superlattice. In this study, first-principles calculations based on DFT within the Vienna Ab initio Simulation Package (VASP) were employed to investigate the diffusion energy barrier of tellurium (Te) atoms on the surface of a graphene superlattice (Wadey J D et al. Chem. Phys. Lett. 2016, 648, 161: He Y Y et al. Comput. Mater. Sci. 2017, 168, 17). To model the system, a supercell consisting of 263 carbon (C) atoms and one Te atom was constructed. Furthermore, two partially overlapped square-shaped pores, each with a diameter of 1.0 nm, were created by selectively removing carbon atoms from the layers of pristine bilayer graphene. The overlap ratio of the pores between the layers, defined by the ratio of the pore area covered by a neighboring graphene layer to the total pore area, was set to 0.5. To ensure structural stability, the edges of the pores were saturated with hydrogen (H) atoms. The exchange and correlation interactions between the electrons were described using the Perdew-Burke-Ernzerhof (PBE) function within the generalized gradient approximation (Qin W et al. Nanomaterials 2021, 11, 3397). Additionally, van der Waals interactions were accounted for by incorporating the semi-empirical long-range dispersion correction proposed by Grimme, known as the DFT-D2 method. The plane-wave cutoff energy was set to 520 eV to achieve accurate and converged results. Total energies and force components were converged to 1×10⁵ eV and 1×10⁻² eV/A, respectively. The reciprocal space was sampled using a Monkhorst-pack k-point mesh with a point density of 2×2×1.

FIG. 73g represents two selected diffusion paths, along which the diffusion energy barriers were determined using the climbing image nudged elastic band (CI-NEB) method implemented in the VASP transition state tools (Terrett R et al. Sustain. Energy Fuels. 2022, 6, 2276; Peng T et al. Chin. Phys. B 2014, 23, 106801). The results indicate that the diffusion of Te atoms towards the pore edge exhibits a lower energy barrier of 0.42 eV compared to diffusion towards the framework (0.76 eV). Furthermore, the bonding between Te and C atoms at the pore edge and in the framework were analyzed. The Te—C bonding at the pore edge exhibited a significantly low negative binding energy of −7.41 eV, indicating a favorable interaction between Te and C atoms at the pore edges. In contrast, bonding of Te to C atoms in the framework yielded a positive binding energy of 0.72 eV. These findings suggest that achieving preferential element doping at the pore edges requires relatively low temperatures compared to doping within the framework (Yao Y G et al. Nat. Nanotechnol. 2019, 14, 851). In summary, the first-principles DFT calculations provide insights into the diffusion energy barriers and bonding behaviors of Te atoms in a graphene superlattice, which provide the potential for selective doping strategies and highlight the significance of pore edge effects in graphene superlattice structures.

Note 2: Experimental evidence for element doping at the pore edges of graphene superlattice. In order to validate the first-principles DFT simulation results regarding the doping of Te atoms at the pore edge of a graphene superlattice, both pristine graphene and graphene superlattice were subjected to element doping in the temperature range of 600-700 °C. The distribution of Te atoms was analyzed using transmission electron microscope (TEM) element mapping, as depicted in FIG. 88a-FIG. 88d. The observations revealed significant Te signals in the graphene superlattice throughout the entire temperature range of 600-700 °C, while successful doping of pristine graphene was only achieved at temperatures above 675 °C.

Moreover, TEM mapping images indicated a predominant distribution of doped Te atoms at or near the pore edge in the graphene superlattice at lower temperatures (600-650 °C), while at higher temperatures (675-700 °C), Te doping was observed throughout the entire framework of graphene superlattice. However, due to the limitations of TEM element mapping, further fine structure analysis is necessary to precisely determine the location of the elements, whether they reside directly at the pore edges or in close proximity to them.

To conduct the fine-structure analysis, two Te-doped graphene superlattice samples were characterized using extended X-ray absorption fine structure (EXAFS) spectra of Te K-edge. One sample was obtained at 625 °C, with Te atoms located at or near the pore edge, while the other sample was obtained at 700 °C, with Te atoms distributed throughout the entire graphene superlattice. FIG. 88a and FIG. 88b present the EXAFS spectra of Te K-edge and the corresponding Fourier transform spectra for these samples. For comparison, FIG. 88c and FIG. 88d display the EXAFS spectra and Fourier transforms obtained from Te-doped pristine graphene at 675 °C and 700 °C, respectively. The analysis of these spectra reveals that Te atoms are fully incorporated into the graphene framework in the case of Te-doped graphene superlattices. Two prominent peaks observed at approximately 1.69 Å and 2.07 Å in both Te-doped graphene superlattices obtained at 625 °C and 700 °C correspond to the Te and C bonds (Te═C and Te—C bonds), with coordination numbers of approximately 2.0 based on Te K-edge fitting (Fornasini P et al. J. Phys-Condenes Mat. 2021, 33, 295404; Caranazza S et al. J. Phys-Condenes Mat. 2016, 28, 325401). Additionally, a series of consecutive peaks ranging from 3 Å to 8 Å, exceeding the typical length of a chemical bond (Sushkevich V et al. Chem Sci. 2020, 11, 5299; Firet N et al. J. Mater. Chem. A 2019, 7, 2507), are also observed. These distinct features are not observed in Te-doped pristine graphene (FIG. 88d).

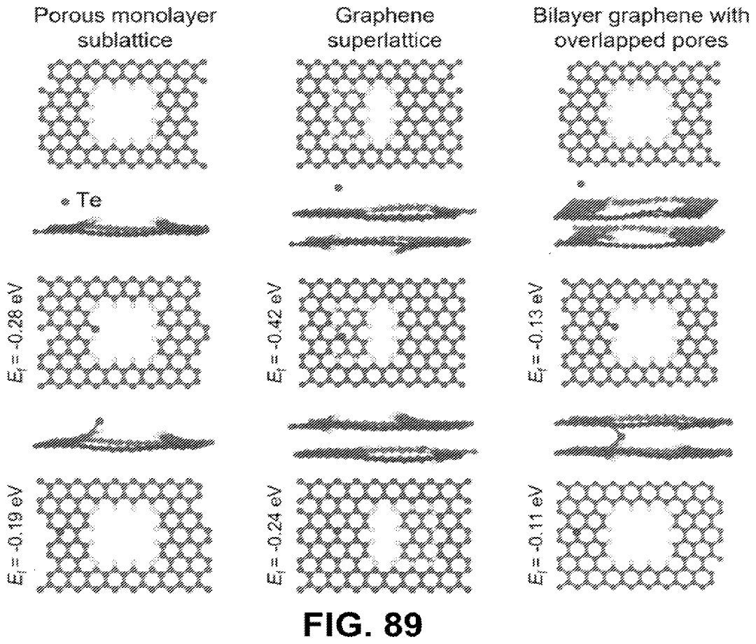

Furthermore, the Te-doped graphene superlattice obtained at 700 °C exhibits an additional Te—C bond with a shorter bond length of 1.50 Å and a higher coordination number of 2.9. The longer bond length of Te—C with lower coordination numbers in graphene superlattice at 625 °C (FIG. 89) may be attributed to the presence of Te—C dangling bonds at the pore edge. Conversely, the shorter Te—C bond length with higher coordination numbers in graphene superlattice at 700 °C suggests that Te is doped into the graphene superlattice framework, as referenced to the Te-doped pristine graphene. These findings from the EXAFS analysis align with the observations from the TEM mapping images. In conclusion, it can be inferred that bonding Te atoms at the pore edge in the graphene superlattice requires a relatively lower temperature.

Note 3: Experimental evidence for electron domain wall in graphene superlattice. To gain insights into the mechanism underlying the presence of the electron domain wall, an analysis of the crystal structure of the graphene superlattice was performed using near-edge X-ray absorption fine structure (NEXAFS) characterization of the carbon atom K-edge. For comparison, pristine graphene and porous bilayer graphene with overlapped pores were also measured. The results, shown in FIG. 90a-FIG. 90c, reveal distinct features in the C K-edge spectrum of the graphene superlattice. The presence of a G peak at 285.6 eV in the C K-edge spectrum of the graphene superlattice, lower than that of pristine graphene and porous bilayer graphene, indicates partial reconstruction of sp² C—C bonding in the graphene lattice due to the partial overlapping of carbon atoms (Minasian S G et al. Chem. Sci. 2014, 5, 351; Povia et al. ACS Catal. 2018, 8, 7000). This feature demonstrates a strong polarization dependence and suggests the formation of an electron domain wall.

Additionally, two peaks at 291.7 eV and 290.3 eV in the graphene superlattice spectrum are attributed to the 1s→σ* transition, indicating the presence of two types of disorders (Zhong J et al. Adv. Mater. 2014, 26, 7786; Hsu C H et al. Small 2023, 19, 2203811). These disorders arise from in-plane strain and non-graphitized carbon-based bonds at the edges. Interestingly, the absence of a peak caused by lattice strain in both pristine graphene and porous bilayer graphene with overlapped pores suggests that lattice strain has been overlooked (Svintsiskiy D A et al. Appl. Surf Sci. 2018, 435, 1273). The combination of in-plane lattice strain and polarized C—C bonds in the graphene lattice collectively induces the formation of the electron domain wall. Furthermore, it was observed that the G peak in the C K-edge spectrum of Te-doped graphene superlattice is further shifted to the left, and the intensity of the two disorder peaks is increased compared to the graphene superlattice. This indicates an enhanced in-plane strain and an increased intensity of polarized C—C bonding in the graphene lattice (Wu B et al. Angew. Int. Ed. Chem. 2023, 13, e202219188). Overall, these findings provide experimental evidence for the presence of an electron domain wall in the graphene superlattice and shed light on its underlying structural characteristics.

Note 4: First-principles DFT simulation of electronic structure of graphene superlattice. Here, first-principles DFT was used to simulate the band structure of graphene. The simulation process involved several steps, including crystal model design and optimization, building of a static self-consistent field, and calculation of the density of states (Bersha A et al. J. Chem. 2019, 2, 5126071; Reda M et al. Catal. Today 2018, 312, 118). All calculations were performed using VASP-6.1.0 with the PBE function under the generalized gradient approximation. The DFT framework with D3 dispersion correction was combined with the projector augmented wave, and a plane wave cutoff energy of 500 eV was set (Deng Q et al. ACS Omega 2019, 4, 142020). The K-mesh for calculating the band structures of the samples was generated using vaspkit-1.2.3 with a line-mode consisting of 20 points. To prevent artificial interactions between periodic images, a 20 Å-thick vacuum layer was introduced perpendicular to the graphene sheet. The structures were relaxed until the residual forces on the atoms decreased to below 0.05 eV/A. Phonon structures of graphene were calculated using the finite displacement method combined with phononpy-2.11 (Raju N et al. Phys. Rev. B. 2019, 99, 235417).

In this study, various factors were considered, such as pore overlap ratio, doping amount and types, as well as other in-plane defect engineering methods, to comprehensively analyze their effects on the electronic band structure of graphene.

(i) Effect of nanopore overlap ratio. To investigate the impact of the pore overlap ratio on the electronic structure, calculations were performed on doped porous graphene systems with square-shaped nanopores with a diameter of 1.0 nm overlapping at different ratios: complete overlap (1), partial overlap (0.5), and no overlap (0). In these systems, the carbon atoms at the pore edge of the nanopore were saturated with an equal number of Te atoms. Pristine bilayer graphene was also included in the calculations for comparison. The electronic properties of graphene are primarily influenced by the behavior of the conduction and valence bands near the Fermi level. Therefore, these bands were analyzed due to their important role in determining the electronic characteristics of graphene. As shown in FIG. 92a-FIG. 92d, pristine graphene exhibits distinct conduction and valence bands with a cone-shaped structure that converges at the Dirac point. This cone-like dispersion signifies a strong linear relationship between electron energy and kinetic energy. However, there is no significant electronic density of states observed near the Fermi level.

When fully overlapped pores are introduced to bilayer graphene (the overlap ratio is 1), the Dirac point splits, resulting in the emergence of an open bandgap with a magnitude of 0.25 eV. Importantly, the band splitting does not significantly affect the electronic density of states near the Fermi level. With partial overlapping of the nanopores in bilayer graphene (the overlap ratio is 0.5), the band exhibits a remarkable flattening near the Fermi level, characterized by negligible band dispersion (less than 1 meV). This flat band structure arises from the weak dispersion relation of kinetic energy due to the periodic electronic reconstruction caused by atomic stress between the overlapped and exposed carbon regions (Mao J H et al. Nature 2020, 215, 584; Roy B et al. Phys. Rev. B. 2019, 99, 121407). This reconstruction leads to the formation of electron domain walls that confine Fermi electrons on either side, resulting in an equipotential Fermi surface and energy barriers with neighboring surfaces. The electron trapping effect leads to a closer proximity of valence electrons in the graphene superlattice to the Fermi level, resulting in the formation of multiple van Hoff singularities (Roy B et al. Phys. Rev. B. 2019, 99, 121407; Wu S et al. Nat. Mater. 2021, 20, 488), as demonstrated by the electron density distribution (FIG. 92a-FIG. 92d). When the nanopore is not overlapped (the overlap ratio is 0), the band shows a noticeable degree of dispersion (greater than 50 meV) compared to partially overlapping nanopores in bilayer graphene. However, it remains significantly weaker than the dispersion observed in pristine graphene and porous graphene with fully overlapped nanopores. It can be explained that in the case of completely non-overlapping nanopores, the graphene structure exhibits an increased area of exposed regions, in the form of monolayer graphene. This enlarged area provides a platform for the release of interfacial strain that is generated between the overlapped regions of bilayer graphene and the exposed regions.

Consequently, the electron domain wall at the interface is weakened, leading to a reduced ability to trap electrons. This weakening of the electron domain wall has a direct impact on the dispersion of the bands and limits their proximity to the Fermi level. As a result, lower electronic density of states near the Fermi level and non-negligible band dispersion are observed.

(ii) Effect of doping element concentration. In the case of doped graphene with partially overlapped nanopores (the overlap ratio is 0.5), further investigations were conducted to examine the influence of varying amounts of Te doping on the pore edges. Specifically, the carbon atoms at the edge of one pore were saturated with 2-10 Te atoms, while the remaining atoms were bonded with H. In the case of the graphene superlattice without Te doping, the pore edge was saturated with —OH, —COOH, and —OH bonds, which aligns with the graphene superlattice without edged doping.

As depicted in FIG. 93a-FIG. 93e, the band gradually turns to a flat shape as the Te atom content at the edges increases. When the number of Te atoms at the pore edge exceeds 8, the band dispersion becomes negligible (less than 1.0 meV). This observation indicates that high levels of Te doping at the pore edge effectively suppress the dispersion relationship between electron energy and kinetic energy, thereby contributing to the electron trapping effect (Wolf T M R et al. Phys. Rev. Lett. 2019, 123, 096802). Additionally, an increase in Te content leads to an upward shift of the valence band, resulting in the formation of one or multiple van Hoff singularities and a significant increase in the electronic density of states near the Fermi level. As the Te content further increases, the band dispersion becomes negligible, and the electron confinement becomes stronger, preventing the electrons from shifting further upward and confining them near the Fermi surface. Instead, the valence band located below the uppermost band continues to shift upward, leading to their overlapping and resulting in the merging of Fermi electrons with one strong van Hoff singularity near the Fermi level (exceeding 300 eV⁻¹).

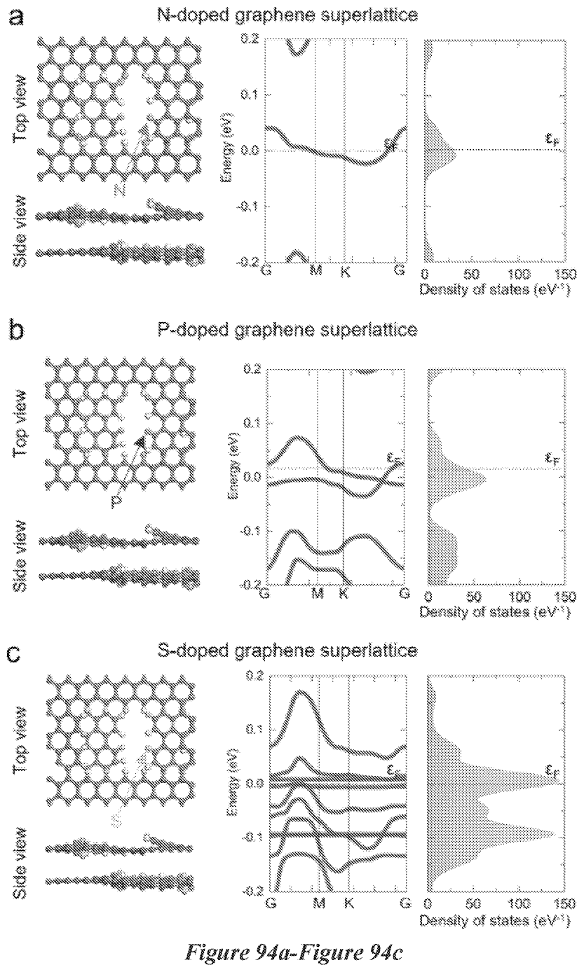

(iii) Effect of doping element types. In the case of bilayer graphene with partially overlapped nanopores (overlap ratio of 0.5), additional investigations were conducted to analyze the impact of different doping element types at the pore edges. Specifically, the carbon atoms at one pore edge were saturated with eight representative atoms of nitrogen (N), phosphorus (P), or sulfur (S), while the remaining atoms were bonded with H. The results depicted in FIG. 94a-FIG. 94c demonstrate distinct effects of substituting the dopant element. When N is used as the dopant, a remarkable band dispersion exceeding 50 meV is observed. However, there is a low electronic density of states near the Fermi level, indicating a weak electron trapping effect and a lack of significant upward shift in the valence band. As N was replaced with heavier elements such as P and S, the band dispersion gradually decreases with increasing atomic number. Additionally, the electronic density of states near the Fermi level experiences a notable increase. In the case of S substitution, two continuous van Hoff singularities emerge near the Fermi level with peak intensities surpassing 140 eV⁻¹. These intensities are approximately six times higher than that of N-doped graphene and three times higher than that of P-doped graphene, indicating a substantial upward shift in the valence band and pronounced merging of bands (Ehlen N et al. ACS Nano 2020, 14, 1055).

The observed changes can be attributed to the energy difference between the bonding orbitals of the dopant atom (e.g., N for 2p, S and P for 3p) and the 2p orbital of the edge carbon.

As the atomic number increases, this energy difference gradually enhances polarization. The enhanced polarization, facilitated by the orbital-spin coupling, leads to band splitting near the Fermi level and promotes an upward shift in the valence band (Fedor K P et al. Phys. Rev. Lett. 2021, 103, 155150; Liu J P et al. Nat. Rev. Phys. 2021, 3, 367). Consequently, it increases the number of valence bands near the Fermi level, promotes the formation of multiple van Hoff singularities, and intensifies their strengths (Garcia J H et al. Chem. Soc. Rev. 2018, 47, 3359). The increased electronic density of states contributes to band flattening and enhances the electron trapping effect. However, when the energy difference exceeds a certain threshold, such as in the case of the 6p orbital of Te and the 2p orbital of C, the covalent bonds between the dopant atoms and the edge carbon can transform into coordination bonds (Zhou X et al. Appl. Surf Sci. 2018, 450, 354). This transformation weakens the strength of orbital-spin coupling due to weak overlapping of orbital wave functions (Goudarzi M et al. Opto-Electron. Rev. 2019, 27, 130). Consequently, the intensities of the peaks and the electron trapping effect is somewhat diminished.

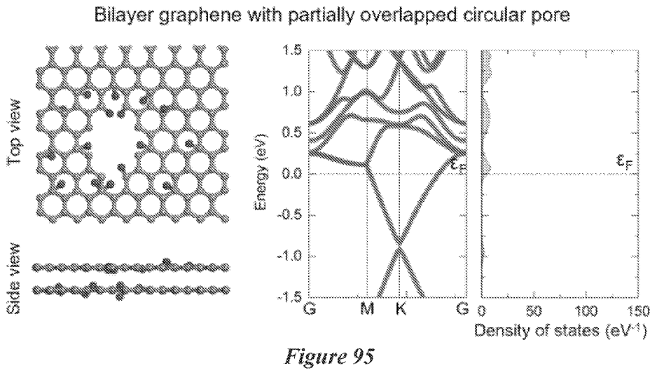

(iv) Effect of nanopore shape. Further investigations were conducted to explore the influence of nanopore shape on bilayer graphene by considering partially overlapping circular nanopores. The overlap ratio was set at 0.5, and the edges of the pores were saturated with 8 Te atoms, following the same configuration as the Te-doped graphene superlattice mentioned earlier. As shown in FIG. 95, the presence of circular nanopores leads to the splitting of the Dirac point, resulting in the emergence of a narrow band gap of approximately 0.1 eV. The underlying reason behind this behavior may lie in the structural characteristics of bilayer graphene with partially overlapping circular nanopores. It exhibits periodicity, overlapping, and exposed carbon atoms. However, the exposed region forms a curved nanoribbon with wider ends and a narrower waist, which introduces strain into the system. The generation of such strain disrupts the stress difference at the interface between the exposed and overlapped carbon atoms, making it challenging to effectively construct electron domain walls. Without electron domain walls, the confinement of electrons is hindered, and the generation of significant energy splitting is impeded. Consequently, there is a lack of strong electron coupling, leading to a weak band dispersion (Pawlak R et al. J. Am. Chem. Soc. 2020, 142, 12568). In contrast to the flat band structure in graphene with square nanopores, the presence of circular nanopores in bilayer graphene with partial overlap does not result in a flat band structure. Instead, it exhibits a narrow band gap without significant electronic density of states near the Fermi level.

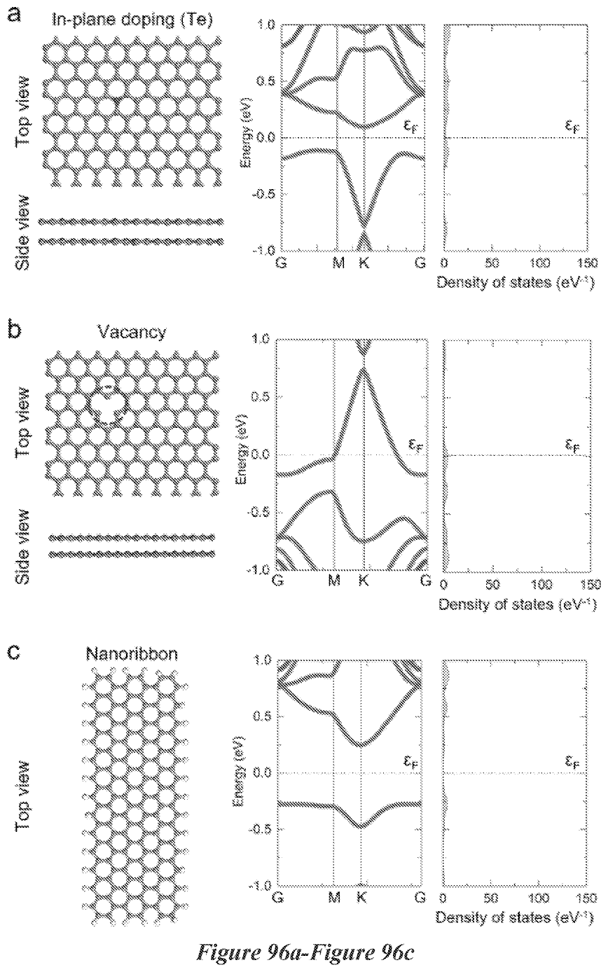

(v) Effect of in-plane defect engineering. Defect engineering is a widely used technique for manipulating the band structure of graphene, allowing precise control over its electronic properties. This approach involves introducing defects such as vacancies and specific element doping. Additionally, the electronic structure of graphene can be customized by creating graphene nanoribbons with controlled dimensions. Here, three types of defected graphene were examined: Te-doped pristine graphene, graphene with vacancy defects (e.g., a removed carbon atom), and an armchair graphene nanoribbon measuring 2.0 nm in length and 0.5 nm in width. The edges of the graphene nanoribbon were saturated with H atoms. As depicted in FIG. 96a-FIG. 96c, all three types of graphene demonstrate distinct dispersion behavior in their band structures, accompanied by varying degrees of Dirac point splitting, ultimately leading to the formation of bandgaps. Furthermore, there is no significant electronic density of states observed near the Fermi level. These observations can be attributed to the absence of periodic electron domain walls within the graphene layers, resulting in a negligible electron coupling effect (Singal M et al. Mater. Chem. Phys. 2021, 273, 125093; Deji R et al. Mater. Today Pro. 2022, 54, 771).

Note 5: Molecular dynamics simulation of the phonon coupling of graphene superlattice. To evaluate the degree of phonon coupling in the graphene superlattice and assess the compatibility of the newly generated low-frequency phonons, molecular dynamics simulations were conducted using the open-source code large-scale atomic/molecular massively parallel simulator (LAMMPS) (Gale J D et al. J. Chem. Soc. 1997, 93, 629; Brenner D W et al. Phys. Rev. B 1990, 42, 9458; Stuart S J et al. J. Chem. Phys. 2000, 112, 6472). The computational model was designed to align with experimental data, and square pores with an overlap ratio of 0.5 was chosen for the graphene superlattice system. The square nanopores in the simulation had a diameter of 7.0 nm, and the width between nanopores on each atomic layer was set to 1.0 nm. The simulation process involved initial energy minimization, followed by relaxation under the constant pressure and temperature (NPT) ensemble at 300 K for 50 ps, with a time step of 1 fs. Subsequently, the simulation continued at 300 K for an additional 100 ps under the constant volume and temperature (NVT) ensemble. During the last 50 ps of the simulation, the velocities of the carbon atoms of interest were sampled every 5 fs to calculate the vibrational density of states (Kim W et al. Inter. J. Heat Mass Transfer. 2021, 165, 1982; Luckyanova M N et al. Sci. Adv. 2018, 4, 12; Bodapati A et al. Phys. Rev. B 2006, 74, 24).

To accurately model the interactions between the exposed and overlapped carbon atoms in the graphene superlattice, the adaptive intermolecular reactive empirical bond order (AIREBO) potential was employed (Wang Y et al. Appl. Phys. Lett. 2021, 1, 101). The classification of carbon atoms within the system was based on their proximity to the pore, where carbon atoms within a distance smaller than 10 Å were identified as pore edge carbon atoms, while carbon atoms beyond this distance were considered as carbon atoms within the framework. The vibrational density of states, denoted as P(ω), was calculated as (Guo Z X et al. Appl. Phys. Lett. 2010, 95, 16):

$$P ( ω ) = \frac{1}{\sqrt{2 π}} {\int }_{0}^{∞} {e}^{i ω t} 〈 {\sum }_{j = 1}^{n} {v}_{j} ( t ) {v}_{j} ( 0 ) 〉 d ω \qquad ( S1 )$$

where ω and vⱼ(t) represent the angular frequency and velocity of carbon atom j at time t, respectively. The ensemble average in Equation Si was approximated by a time average computed over a period of 50 ps once the system reached equilibrium. The coupling degree between any two calculated vibrational density of states (P(ω)) can be determined by (Evans W J et al. Appl. Phys. Lett. 2010, 20, 96):

Phonon coupling=(∫\sqrt{P₁(ω)P₂(ω)}dω)²/(∫P₁(ω)dω∫P₂(ω)dω) (S2)

The results depicted in FIG. 97a-FIG. 97b demonstrate that the phonon coupling between the carbon atoms at the pore edge and in the framework is relatively weak, with a value as low as 0.71. Similarly, the coupling degree between the overlapped carbon atom and the exposed carbon atom is even lower, reaching a value as low as 0.51. These findings indicate poor compatibility among the newly generated phonons, resulting in increased scattering between them. Consequently, the phonon thermal conductivity is significantly reduced, leading to a decrease in the overall thermal conductivity.

Note 6: Experimental evidence for the dielectric dispersion at lower-frequency region. The permittivity of graphene as a function of EM frequency is shown in FIG. 100a-FIG. 100h. In the case of pristine bilayer graphene, both the real part (ε′) and the imaginary part (ε″) of the permittivity decrease as the frequency increases from 1 GHz to 5 GHz. However, for element-doped graphene superlattice, a distinct behavior is observed. Specifically, there is a sharp decrease in ε′ and a remarkable resonance peak in ε″ within the same frequency range. The presence of a resonance peak in ε″ indicates a frequency-dependent response, which can be attributed to the phenomenon of polarization relaxation (Wu Y et al. Nano. Res. 2023, 16, 7801; Tao J Q et al. Adv. Funct. Mater. 2023, 33, 2211996). According to the classical Debye theory, polarization relaxation gives rise to a semicircular relationship between ε′ and ε″ known as the Cole-Cole semicircle. The relative complex permittivity can be expressed as (Cheng T T et al. Carbon 2023, 206, 181; Liu Y L et al. Chem. Eng. J. 2023, 461, 141867):

$${ε}_{r} = {ε}_{∞} + \frac{{ε}_{s} - {ε}_{∞}}{1 + i 2 π f τ} = {ε}^{′} - j {ε}^{″} \qquad ( S3 )$$

where εₛ represents the static permittivity, ε_{∞} is the relative dielectric permittivity at the high-frequency limit, f is the frequency, i is the imaginary unit, and τ is the dipole relaxation time. By separating the real and imaginary parts, obtains (Xiang Z N et al. Chem. Eng. J. 2023, 451, 138742; Wu D et al. Nano Res. 2023, 16, 1859):

$${ε}^{′} = {ε}_{∞} + \frac{{ε}_{s} - {ε}_{∞}}{1 + {( 2 π f )}^{2} {τ}^{2}} \qquad ( S4 )$$

$${ε}^{″} = {ε}_{∞} + \frac{2 π f τ ( {ε}_{s} - {ε}_{∞} )}{1 + {( 2 π f )}^{2} {τ}^{2}} \qquad ( S5 )$$

$${( {ε}^{′} - {ε}_{∞} )}^{2} + {( {ε}^{″} )}^{2} = {( {ε}_{s} - {ε}_{∞} )}^{2} \qquad ( S6 )$$

Based on Equation S6, which describes the relationship between ε′ and ε″, each Cole-Cole semicircle corresponds to a Debye relaxation process. In the case of doped graphene superlattices, the presence of Cole-Cole semicircles (FIG. 99a-FIG. 99b) indicates the occurrence of dipole relaxation polarization behavior in the low-frequency range, primarily attributed to the presence of electron domain walls (Liu Y J et al. Adv. Fuct. Mater. 2023, 33, 2211352; Liu M et al. Small 2023, 19, 2300363). It is important to note that achieving low-frequency polarization relaxation remains a significant challenge for current dielectric materials, as illustrated in Table 9.

Note 7: Design of graphene superlattice-based device for EM-electricity conversion. The graphene superlattice-based device used in this study involves two main steps for harvesting EM energy and converting it into direct current (DC) electricity. First, the graphene superlattice-based device captures and converts EM energy into oscillating alternating current (AC) electricity. This operation is based on the principles of EM induction and radiation (Dragoman M et al. Nano materials 2023, 13, 595; Aboualalaa M et al. IEEE Trans Inst. Measurement 2023, 72, 2001313; Lee Y C et al. IEEE Access 2023, 11, 11143). When an EM wave interacts with the graphene superlattice-based device, the alternating electric and magnetic fields induce an oscillating current in the graphene superlattice. Second, a rectifier is employed to convert the oscillating AC into DC (Liu X et al. Appl. Comput. Electromagnetics Soc. J. 2023, 67, 73). The rectifier utilizes the non-linear characteristic of a diode, allowing current to flow in only one direction and effectively rectifying the oscillating current (Rahmani H et al. IEEE J. Microwaves 2023, 3, 237).

The design of the graphene superlattice-based device involves two main components:
(i) Graphene superlattice-based device. The optimal geometric shape suitable for multiple lower-frequency bands is determined using Computer Simulation Technology Microwave Studio software. The specific thickness (20 μm) and electrical conductivity (1,064 S/cm) of the graphene superlattice film are taken into consideration. FIG. 104 illustrates the detailed geometric shapes and specific dimensions of the graphene superlattice-based device. To fabricate the graphene superlattice-based device, the graphene superlattice film is attached to a polydimethylsiloxane (PDMS) substrate with a thickness of 200 μm. Laser direct molding is then employed to shape the graphene superlattice film into the simulated geometric shapes, achieving the desired structure.
(ii) Rectifier. The rectifier comprises three parallel rectification branches to accommodate multiple low-frequency bands. Each branch includes a series connection of a diode, a DC-pass filter, a diode front-end transmission line, and an impedance matching network. The detailed geometric shapes and specific dimensions of the rectifier are calculated using the Advanced Design System software, as shown in FIG. 105. The rectifier is manufactured by first attaching a 35 μm-thick Cu foil onto a dielectric substrate called Deriod 5880, which has dimensions of 54 mm in length, 42 mm in width, and 0.79 mm in thickness. The dielectric substrate has a relative permittivity of 2.2 and a tangent loss of approximately 0.0009. The Cu foil is then shaped into the desired current mode using high-frequency circular pressing technology.

By combining the graphene superlattice-based device for capturing and converting EM waves and the rectifier for rectifying the oscillating current, the integrated graphene superlattice-based device enables the efficient conversion of EM energy into stable DC electricity.

Harvesting and converting EM waves from a cell phone into DC electricity. During a phone call, the EM signal near an iPhone 12 experiences a significant enhancement for improved reception. The graphene superlattice-based device efficiently harvests the excess EM signals and converts them into DC electricity. The multimeter measures the output voltage of the graphene superlattice-based device.

Harvesting EM waves from a telecommunication tower and converting them into DC electricity. A graphene superlattice-based device positioned 500 meters away from a telecommunications tower effectively captures and harvests weak EM signals, converting them into DC electricity. The multimeter measures the output voltage of the graphene superlattice-based device.

Converting EM waves from a microwave oven into DC electricity to light up LEDs. When the Panasonic home microwave oven (Model: NN-GT353 M) operates at a power consumption of 800 W for 20 seconds, it generates EM wave leakage that radiates into the surrounding air. The graphene superlattice-based device efficiently captures these leaked EM waves and converts them into DC electricity, which is used to power a pattern of LEDs. The pattern consists of 26 LEDs connected in parallel, with each LED having a power consumption of 60 mW.

Converting and storing EM waves from a Wi-Fi Router as DC electricity to power a digital hygro-thermometer. By positioning a graphene superlattice-based device in proximity to a home Wi-Fi router, which emits EM energy with a power output of approximately 50 mW, the device harvests and converts the EM waves into DC electricity. The captured DC electricity can then be stored and utilized to power a Dretect digital hygro-thermometer with a power consumption of 100 mW after just one minute of storage. The multimeter measures the charging voltage of the hygro-thermometer.

### Exemplary Aspects

In view of the described materials and methods of making and use thereof, herein below are described certain more particularly described aspects of the inventions. The particularly recited aspects should not, however, be interpreted to have any limiting effect on any different claims containing different or more general teachings described herein or that the “particular” aspects are somehow limited in some way other than the inherent meanings of the language and formulas literally used therein.

Example 1: A material for converting electromagnetic radiation directly into electricity, wherein the material absorbs electromagnetic radiation, converts the absorbed electromagnetic radiation into thermal energy, and subsequently converts the thermal energy into electric energy via a thermoelectric effect.

Example 2: The material of any examples herein, particularly example 1, wherein the material comprises one or more porous layers, wherein each porous layer comprises a two-dimensional material layer permeated by a plurality of pores.

Example 3: A material comprising one or more porous layers, wherein each porous layer comprises a two-dimensional material layer permeated by a plurality of pores.

Example 4: The material of any examples herein, particularly example 2 or example 3, wherein each two-dimensional material layer is a continuous phase with said layer.

Example 5: The material of any examples herein, particularly examples 2-4, wherein each two-dimensional material layer further comprises a dopant.

Example 6: The material of any examples herein, particularly examples 2-5, wherein the two-dimensional material comprises a graphitic material.

Example 7: The material of any examples herein, particularly examples 2-6, wherein the two-dimensional material comprises graphene.

Example 8: The material of any examples herein, particularly examples 2-7, wherein the plurality of pores are arranged in an ordered array.

Example 9: The material of any examples herein, particularly examples 2-8, wherein the plurality of pores each have a cross-sectional shape that is circular, square, or hexagonal.

Example 10: The material of any examples herein, particularly examples 2-9, wherein the plurality of pores each have a cross-sectional shape that is circular.

Example 11: The material of any examples herein, particularly examples 2-10, wherein the plurality of pores have an average pore size of from 0.5 nanometers (nm) to 25 nm.

Example 12: The material of any examples herein, particularly examples 2-11, wherein the plurality of pores have an average pore size of from 1 nm to 10 nm.

Example 13: The material of any examples herein, particularly examples 2-12, wherein the total number of layers is from 1 to 20.

Example 14: The material of any examples herein, particularly examples 2-13, wherein, when the material includes 2 or more layers, the plurality of pores in a given layer are offset relative to the plurality of pores in a neighboring layer.

Example 15: The material of any examples herein, particularly examples 2-14, wherein, when the material includes 2 or more layers, the plurality of pores in a given layer have an overlap ratio of from 0 to 1 relative to the plurality of pores in a neighboring layer.

Example 16: The material of any examples herein, particularly examples 1-15, wherein the material has an EM dissipation factor of from 50 to 400 at a frequency of from 1 to 5 GHz.

Example 17: The material of any examples herein, particularly examples 1-16, wherein the material has an EM dissipation factor of 90 or more, 100 or more, 120 or more, or 150 or more.

Example 18: The material of any examples herein, particularly examples 1-17, wherein the material has a thermal conductivity of 10 Wm⁻¹K⁻¹ or less at a temperature of from 300-500 K.

Example 19: The material of any examples herein, particularly examples 1-18, wherein the material has a thermal conductivity of 5 Wm⁻¹K⁻¹ or less, 3 Wm⁻¹K⁻¹ or less, or 1 Wm⁻¹K⁻¹ or less at a temperature of 300-500 K.

Example 20: The material of any examples herein, particularly examples 1-19, wherein the material has an electrical conductivity of from 100 to 7000 S/cm at a temperature of 300-500 K.

Example 21: The material of any examples herein, particularly examples 1-20, wherein the material has an electrical conductivity of 6000 S/cm or less, 4000 S/cm or less, 3000 S/cm or less at a temperature of 300-500 K.

Example 22: The material of any examples herein, particularly examples 1-21, wherein the material has a Seebeck coefficient with an absolute value of from 5 to 200 μV/K at a temperature of from 300-500K.

Example 23: The material of any examples herein, particularly examples 1-22, wherein the material has a Seebeck coefficient with an absolute value of 10 μV/K or more, 25 μV/K or more, 50 μV/K or more, 75 μV/K or more at a temperature of from 300-500K.

Example 24: The material of any examples herein, particularly examples 1-22, wherein, when the material is exposed to electromagnetic radiation at one or more frequencies of from 1 to 5 GHz for an amount of time of from 1 second to 10 minutes, then the material outputs a power of 0.1 μW to 1 μW.

Example 25: The material of any examples herein, particularly examples 1-23, wherein, when the material is exposed to electromagnetic radiation at one or more frequencies of from 1 to 5 GHz for an amount of time of from 1 second to 10 minutes, then the material outputs a power of from 0.1 μW to 1 μW.

Example 26: The material of any examples herein, particularly examples 1-23, wherein, when the material is exposed to electromagnetic radiation at one or more frequencies of from 1 to 5 GHz for an amount of time of from 1 second to 10 minutes, then the material outputs a power of 0.1 μW to 10 μW.

Example 27: The material of any examples herein, particularly example 26, wherein the material outputs a power of 0.5 μW or more, 1 μW or more, or 2 μW or more.

Example 28: The material of any examples herein, particularly examples 1-25, wherein the material outputs a power of 0.1 W or more.

Example 29: The material of any examples herein, particularly examples 1-28, wherein, when the material is exposed to electromagnetic radiation at one or more frequencies of from 1 to 5 GHz for an amount of time of from 1 second to 10 minutes, then the material outputs a power density of from 10 W/m³ to 1×10⁶ W/m³.

Example 30: The material of any examples herein, particularly examples 1-29, wherein, when the material is exposed to electromagnetic radiation at one or more frequencies of from 1 to 5 GHz for an amount of time of from 1 second to 10 minutes, then the material outputs a power density of 10 to 500 W/m³.

Example 31: The material of any examples herein, particularly examples 1-30, wherein, when the material is exposed to electromagnetic radiation at one or more frequencies of from 1 to 5 GHz for an amount of time of from 1 second to 10 minutes, then the material generates a temperature increase of from 10 °C to 200 °C.

Example 32: The material of any examples herein, particularly example 31, wherein the material generates a temperature increase of 20 °C or more, 40 °C or more, 50 °C or more, or 60 °C or more.

Example 33: The material of any examples herein, particularly examples 1-32, wherein the material is flexible, low cost, lightweight, or a combination thereof.

Example 34: A device comprising the material of any examples herein, particularly examples 1-33.

Example 35: An article of manufacture comprising the device of any examples herein, particularly example 34.

Example 36: The article of any examples herein, particularly example 35, wherein the device is a power supply for the article.

Example 37: The article of any examples herein, particularly example 35 or example 36, wherein the article is a wearable electronic device.

Example 38: A method of making the material of any examples herein, particularly examples 2-33, the methods comprising: depositing a plurality of particles on the two-dimensional material layer, thereby forming an initial material; annealing the initial material to form an intermediate material; and removing the plurality of particles from the intermediate material, thereby forming the material.

Example 39: The method of any examples herein, particularly example 38, wherein the plurality of particles comprise a metal oxide.

Example 40: The method of any examples herein, particularly example 38 or example 39, wherein the plurality of particles comprise Fe₃O₄, ZnO, CuO, or a combination thereof.

Example 41: The method of any examples herein, particularly examples 38-40, wherein the plurality of particles comprise Fe₃O₄.

Example 42: The method of any examples herein, particularly examples 38-41, wherein the plurality of particles have an average particle size of from 0.5 nanometers (nm) to 25 nm.

Example 43: The method of any examples herein, particularly examples 38-42, wherein the plurality of particles have an average particle size of from 1 nm to 10 nm.

Example 44: The method of any examples herein, particularly examples 38-43, wherein the plurality of particles have a shape that is spherical, tetrahedral, cubic, hexagonal, or irregular.

Example 45: The method of any examples herein, particularly examples 38-44, wherein the initial material is annealed at a temperature of from 500 °C to 2000 °C.

Example 46: The method of any examples herein, particularly examples 38-45, wherein the initial material is annealed at a temperature of from 600 °C to 1200 °C.

Example 47: The method of any examples herein, particularly examples 38-46, wherein the initial material is annealed for an amount of time of from 10 minutes to 72 hours.

Example 48: The method of any examples herein, particularly examples 38-47, wherein removing the plurality of particles comprises etching, such as chemical etching.

Example 49: The method of any examples herein, particularly examples 38-48, wherein removing the plurality of particles comprises exposing the plurality of particles to an etchant, such as an acid (e.g., hydrochloric acid, sulfuric acid, nitric acid, or a combination thereof).

Example 50: The method of any examples herein, particularly examples 38-49, wherein the method further comprises doping the material, for example by annealing the material in the presence of a dopant.

Example 51: A method for converting electromagnetic radiation directly into electricity, the method comprising exposing the material of any examples herein, particularly examples 1-33 to electromagnetic radiation, such that the material absorbs at least a portion of the electromagnetic radiation, converts the absorbed electromagnetic radiation into thermal energy, and subsequently converts the thermal energy into electric energy via a thermoelectric effect.

Other advantages which are obvious and which are inherent to the invention will be evident to one skilled in the art. It will be understood that certain features and sub-combinations are of utility and may be employed without reference to other features and sub-combinations. This is contemplated by and is within the scope of the claims. Since many possible embodiments may be made of the invention without departing from the scope thereof, it is to be understood that all matter herein set forth or shown in the accompanying drawings is to be interpreted as illustrative and not in a limiting sense.

The devices and methods of the appended claims are not limited in scope by the specific devices and methods described herein, which are intended as illustrations of a few aspects of the claims and any devices and methods that are functionally equivalent are intended to fall within the scope of the claims. Various modifications of the devices and methods in addition to those shown and described herein are intended to fall within the scope of the appended claims. Further, while only certain representative method steps disclosed herein are specifically described, other combinations of the method steps also are intended to fall within the scope of the appended claims, even if not specifically recited. Thus, a combination of steps, elements, components, or constituents may be explicitly mentioned herein or less, however, other combinations of steps, elements, components, and constituents are included, even though not explicitly stated.

1. A material for converting electromagnetic radiation directly into electricity, wherein the material comprises one or more porous layers, wherein each porous layer comprises a continuous phase permeated by a plurality of pores, the continuous phase being a two-dimensional material layer, wherein the material absorbs electromagnetic radiation, converts the absorbed electromagnetic radiation into thermal energy, and subsequently converts the thermal energy into electric energy via a thermoelectric effect.

2. (canceled)

3. (canceled)

4. (canceled)

5. The material of claim 1, wherein each two-dimensional material layer further comprises a dopant.

6. The material of claim 1, wherein the two-dimensional material comprises a graphitic material.

7. The material of claim 1, wherein the two-dimensional material comprises graphene.

8. The material of claim 1, wherein the plurality of pores are arranged in an ordered array.

9. The material of claim 1, wherein the plurality of pores each have a cross-sectional shape that is circular, square, or hexagonal.

10. (canceled)

11. The material of claim 1, wherein the plurality of pores have an average pore size of from 0.5 nanometers (nm) to 25 nm.

12. (canceled)

13. The material of claim 1, wherein the total number of layers is from 1 to 20.

14. The material of claim 1, wherein, when the material includes 2 or more layers, the plurality of pores in a given layer are offset relative to the plurality of pores in a neighboring layer.

15. The material of claim 1, wherein, when the material includes 2 or more layers, the plurality of pores in a given layer have an overlap ratio of from 0 to 1 relative to the plurality of pores in a neighboring layer.

16. The material of claim 1, wherein the material has an EM dissipation factor of from 50 to 400 at a frequency of from 1 to 5 GHz.

17. (canceled)

18. The material of claim 1, wherein the material has a thermal conductivity of 10 Wm⁻¹K⁻¹ or less at a temperature of from 300-500 K.

19. (canceled)

20. The material of claim 1, wherein the material has an electrical conductivity of from 100 to 7000 S/cm at a temperature of 300-500 K.

21. (canceled)

22. The material of claim 1, wherein the material has a Seebeck coefficient with an absolute value of from 5 to 200 μV/K at a temperature of from 300-500K.

23. (canceled)

24. The material of claim 1, wherein, when the material is exposed to electromagnetic radiation at one or more frequencies of from 1 to 5 GHz for an amount of time of from 1 second to 10 minutes, then the material outputs a power of 0.1 μW to 1 W.

25. The material of claim 1, wherein, when the material is exposed to electromagnetic radiation at one or more frequencies of from 1 to 5 GHz for an amount of time of from 1 second to 10 minutes, then the material outputs a power of from 0.1 W to 1 W.

26. The material of claim 1, wherein, when the material is exposed to electromagnetic radiation at one or more frequencies of from 1 to 5 GHz for an amount of time of from 1 second to 10 minutes, then the material outputs a power of 0.1 μW to 10 μW.

27. (canceled)

28. (canceled)

29. The material of claim 1, wherein, when the material is exposed to electromagnetic radiation at one or more frequencies of from 1 to 5 GHz for an amount of time of from 1 second to 10 minutes, then the material outputs a power density of from 10 W/m³ to 1×10⁶ W/m³.

30.-37. (canceled)

38. A method of making the material of claim 1, the methods comprising:
depositing a plurality of particles on the two-dimensional material layer, thereby forming an initial material;
annealing the initial material to form an intermediate material; and
removing the plurality of particles from the intermediate material, thereby forming the material.

39.-50. (canceled)

51. A method for converting electromagnetic radiation directly into electricity, the method comprising exposing the material of claim 1 to electromagnetic radiation, such that the material absorbs at least a portion of the electromagnetic radiation, converts the absorbed electromagnetic radiation into thermal energy, and subsequently converts the thermal energy into electric energy via a thermoelectric effect.
